(19) United States
(12) Patent Application Publication
(10) Pub. No.: US 2024/0201599 A1
(43) Pub. Date: Jun. 20, 2024

(54) METHOD FOR INSPECTING RESIST COMPOSITION, METHOD FOR PRODUCING RESIST COMPOSITION, AND RESIST COMPOSITION

(71) Applicant: FUJIFILM Corporation, Tokyo (JP)

(72) Inventors: Michihiro Shirakawa, Haibara-gun (JP); Satomi Takahashi, Haibara-gun (JP); Tetsuya Shimizu, Haibara-gun (JP); Kei Yamamoto, Haibara-gun (JP); Naohiro Tango, Haibara-gun (JP)

(73) Assignee: FUJIFILM Corporation, Tokyo (JP)

(21) Appl. No.: 18/439,390

(22) Filed: Feb. 12, 2024

Related U.S. Application Data
(63) Continuation of application No. PCT/JP2022/027964, filed on Jul. 19, 2022.

(30) Foreign Application Priority Data
Aug. 13, 2021 (JP) 2021-132049

(51) Int. Cl. G03F 7/32

(52) U.S. Cl. CPC G03F 7/325

(57) ABSTRACT

Provided is a method for inspecting a resist composition, the method being able to easily determine a resist composition whose LWR performance after storage for a predetermined period of time is good. Also provided are a method for producing a resist composition and a resist composition. The method for inspecting a resist composition is a method for inspecting a resist composition with which a resist pattern can be formed by performing an exposure treatment and a development treatment using a first developer. The method has a step A1 of forming a resist film on a substrate using the resist composition, a step B1 of exposing the resist film, a step C1 of bringing a second developer that dissolves the resist film at a higher rate than the first developer into contact with the resist film, a step X1 of acquiring specific measurement data, and a step Y1 of determining whether the measurement data falls within a preset allowable range. Alternatively, the method has a step A2 of forming a resist film on a substrate using the resist composition, a step C2 of bringing a second developer into contact with the resist film, a step X2 of acquiring specific measurement data, and a step Y2 of determining whether the measurement data falls within a preset allowable range.

### CROSS-REFERENCE TO RELATED APPLICATIONS

This application is a Continuation of PCT International Application No. PCT/JP2022/027964 filed on Jul. 19, 2022, which claims priority under 35 U.S.C. § 119(a) to Japanese Patent Application No. 2021-132049 filed on Aug. 13, 2021. The above applications are hereby expressly incorporated by reference, in their entirety, into the present application.

### BACKGROUND OF THE INVENTION

### 1. Field of the Invention

The present invention relates to a method for inspecting a resist composition, a method for producing a resist composition, and a resist composition.

### 2. Description of the Related Art

In a process for producing a semiconductor device such as an integrated circuit (IC) or a large scale integrated circuit (LSI), lithography micromachining using an actinic ray-sensitive or radiation-sensitive composition (hereinafter also referred to as a “resist composition”) has been conventionally performed. In recent years, with increasing integration of integrated circuits, formation of ultrafine patterns in submicron regions or quarter-micron regions has been required.

Accordingly, for miniaturization of semiconductor devices, the wavelengths of exposure light sources have been shortened and the numerical apertures (NAs) of projector lenses have been increased, and exposure devices using a KrF excimer laser having a wavelength of 248 nm or an ArF excimer laser having a wavelength of 193 nm as a light source have been developed. In addition, pattern forming methods using extreme ultraviolet rays (EUV light) or an electron beam (EB) as a light source have also recently been studied.

For example, JP2015-036786A discloses a method of forming a negative pattern using a developer containing an organic solvent.

### SUMMARY OF THE INVENTION

Resist compositions desirably do not differ much in performance between lots. Therefore, in the related art, every time a resist composition is prepared, an exposure treatment and a development treatment have been carried out using the resist composition to perform inspection of quality such as pattern size.

The present inventors have studied a method for inspecting the quality of a resist composition and found that in these days where the pattern size has become smaller and smaller, when a resist composition is used to form a pattern after being stored for a predetermined period of time, the pattern formed may have low line width roughness (LWR) performance even if the resist composition meets the standard in a conventional inspection method.

In view of the above circumstances, an object of the present invention is to provide a method for inspecting a resist composition, the method being able to easily determine a resist composition whose LWR performance after storage for a predetermined period of time is good.

Another object of the present invention is to provide a method for producing a resist composition and a resist composition.

The present inventors have found that the above objects can be achieved by the following configurations.

[1] A method for inspecting a resist composition with which a resist pattern can be formed by performing an exposure treatment and a development treatment using a first developer, the method including a step A1 of forming a resist film on a substrate using the resist composition, a step B1 of exposing the resist film formed in the step A1, a step C1 of bringing a second developer different from the first developer into contact with the resist film exposed in the step B1, a step X1 of acquiring at least one measurement data selected from the group consisting of a line width of a resist pattern formed in the step C1, a number of defects of the resist pattern formed in the step C1, and a rate at which the exposed resist film is dissolved by the second developer, the rate being measured in the step C1, and a step Y1 of determining whether the measurement data acquired in the step X1 falls within a preset allowable range, wherein the rate at which the resist film formed using the resist composition is dissolved by the second developer is higher than a rate at which the resist film formed using the resist composition is dissolved by the first developer.

[2] The method for inspecting a resist composition according to [1], wherein the first developer includes butyl acetate and a hydrocarbon solvent.

[3] The method for inspecting a resist composition according to [2], wherein the hydrocarbon solvent is undecane.

[4] The method for inspecting a resist composition according to any one of [1] to [3], wherein the second developer includes substantially only butyl acetate.

[5] The method for inspecting a resist composition according to any one of [1] to [4], wherein in the step B1, the resist film is exposed using at least one selected from the group consisting of EUV exposure, KrF exposure, ArF exposure, and EB exposure.

[6] The method for inspecting a resist composition according to any one of [1] to [5], wherein a ratio of the rate at which the resist film formed using the resist composition is dissolved by the second developer to the rate at which the resist film formed using the resist composition is dissolved by the first developer is more than 1.0 and 100 or less.

[7] A method for inspecting a resist composition with which a resist pattern can be formed by performing an exposure treatment and a development treatment using a first developer, the method including a step A2 of forming a resist film on a substrate using the resist composition, a step C2 of bringing a second developer different from the first developer into contact with the resist film formed in the step A2, a step X2 of acquiring at least one measurement data selected from the group consisting of a number of defects on a surface of the substrate from which the resist film has been removed as a result of the step C2 and a rate at which the resist film is dissolved by the second developer, the rate being measured in the step C2, and a step Y2 of determining whether the measurement data acquired in the step X2 falls within a preset allowable range, wherein the rate at which the resist film formed using the resist composition is dissolved by the second developer is higher than a rate at which the resist film formed using the resist composition is dissolved by the first developer.

[8] The method for inspecting a resist composition according to [7], wherein the first developer includes butyl acetate and a hydrocarbon solvent.

[9] The method for inspecting a resist composition according to [8], wherein the hydrocarbon solvent is undecane.

[10] The method for inspecting a resist composition according to any one of [7] to [9], wherein the second developer includes substantially only butyl acetate.

[11] The method for inspecting a resist composition according to any one of [7] to [10], wherein a ratio of the rate at which the resist film formed using the resist composition is dissolved by the second developer to the rate at which the resist film formed using the resist composition is dissolved by the first developer is more than 1.0 and 100 or less.

[12] The method for inspecting a resist composition according to any one of [1] to [11], wherein the resist composition is a resist composition with which a resist pattern can be formed through an exposure treatment including EUV exposure and a development treatment using the first developer.

[13] The method for inspecting a resist composition according to any one of [1] to [12], wherein the resist composition includes a resin having a repeating unit having an aromatic hydrocarbon group.

[14] A method for producing a resist composition, the method including a composition preparation step of preparing a resist composition, and an inspection step of inspecting the resist composition prepared in the composition preparation step in accordance with the method according to any one of [1] to [13].

[15] A resist composition produced by a production method having an inspection step of performing inspection by the method according to any one of [1] to [13].

The present invention can provide a method for inspecting a resist composition, the method being able to easily determine a resist composition whose LWR performance after storage for a predetermined period of time is good.

The present invention can also provide a method for producing a resist composition and a resist composition.

### DESCRIPTION OF THE PREFERRED EMBODIMENTS

Hereinafter, the present invention will be described in detail.

It should be appreciated that although the following description of constituent features may be made in the context of a representative embodiment of the present invention, the present invention is not limited to the embodiment.

Regarding expressions of groups (atomic groups) in the present specification, an expression not specified as substituted or unsubstituted encompasses a group having no substituents and also a group having a substituent without departing from the spirit of the present invention. For example, an “alkyl group” encompasses not only an alkyl group having no substituents (an unsubstituted alkyl group) but also an alkyl group having a substituent (a substituted alkyl group). The term “organic group” in the present specification refers to a group including at least one carbon atom.

The substituent is preferably a monovalent substituent unless otherwise specified.

The term “actinic ray” or “radiation” in the present specification means, for example, an emission line spectrum of a mercury lamp, far ultraviolet rays represented by excimer lasers, extreme ultraviolet rays (EUV light), X-rays, or an electron beam (EB). The term “light” in the present specification means an actinic ray or a radiation.

The term “exposure” in the present specification includes, unless otherwise specified, not only exposure with, for example, an emission line spectrum of a mercury lamp, far ultraviolet rays represented by excimer lasers, extreme ultraviolet rays, X-rays, or EUV light but also patterning with a corpuscular beam such as an electron beam or an ion beam.

In the present specification, the term “to” is used to mean that numerical values given before and after “to” are included as lower and upper limit values.

The bonding direction of a divalent group given in the present specification is not limited unless otherwise specified. For example, in a compound represented by a formula “X—Y—Z” where Y is —COO—, Y may be —CO—O— or —O—CO—. This compound may be represented as “X—CO—O—Z” or “X—O—CO—Z”.

In the present specification, (meth)acrylate represents acrylate and methacrylate, and (meth)acrylic represents acrylic and methacrylic.

In the present specification, a weight-average molecular weight (Mw), a number-average molecular weight (Mn), and a dispersity (also referred to as a molecular weight distribution) (Mw/Mn) of a resin are defined as polystyrene equivalent values determined using a gel permeation chromatography (GPC) apparatus (HLC-8120GPC manufactured by Tosoh Corporation) by GPC measurement (solvent: tetrahydrofuran, flow rate (sample injection volume): 10 μL, column: TSK gel Multipore HXL-M manufactured by Tosoh Corporation, column temperature: 40° C., flow rate: 1.0 mL/min, detector: differential refractive index detector.

In the present specification, an acid dissociation constant (pKa) represents pKa in an aqueous solution, specifically, a value determined using a software package 1 below by calculation of the Hammett substituent constant and values based on a database of known literature values. All pKa values given in the present specification are values determined by calculation using this software package.

Software package 1: Advanced Chemistry Development (ACD/Labs) Software V8.14 for Solaris (1994-2007 ACD/Labs)

Alternatively, pKa can also be determined by the molecular orbital method. One specific example of this method is to determine pKa by calculating H⁺ dissociation free energy in an aqueous solution on the basis of a thermodynamic cycle. The H⁺ dissociation free energy can be calculated by, for example, the density functional theory (DFT). However, this is not the only method, and various other methods have been reported in literatures, etc. There are multiple software programs capable of implementing DFT, such as Gaussian16.

As described above, pKa in the present specification refers to a value determined using the software package 1 by calculation of the Hammett substituent constant and values based on a database of known literature values, but when pKa cannot be calculated by this method, a value obtained using Gaussian16 on the basis of the density functional theory (DFT) is employed.

As described above, pKa in the present specification refers to “pKa in an aqueous solution”, but when pKa in an aqueous solution cannot be calculated, “pKa in a dimethylsulfoxide (DMSO) solution” is employed.

In the present specification, examples of halogen atoms include a fluorine atom, a chlorine atom, a bromine atom, and an iodine atom.

In the present specification, solids mean all components other than solvents. Solids in liquid form are also calculated as solids.

In the present specification, for example, when it is described that “a composition A includes substantially only a component B”, it means that the content of the component B is 95 mass % or more relative to the total mass of the composition A. In the present specification, for example, when it is described that “a composition A substantially does not include a component C”, it means that the content of the component C is 5 mass % or less relative to the total mass of the composition A.

### Method for Inspecting Resist Composition

Hereinafter, a method for inspecting a resist composition according to the present invention will be described with reference to specific embodiments.

### First Embodiment

A method for inspecting a resist composition according to a first embodiment of the present invention is a method for inspecting a resist composition with which a resist pattern can be formed by performing an exposure treatment and a development treatment using a first developer and has the following steps.

Step A1: a step of forming a resist film on a substrate using the resist composition.

Step B1: a step of exposing the resist film formed in the step A1.

Step C1: a step of bringing a second developer different from the first developer into contact with the resist film exposed in the step B1.

Step X1: a step of acquiring at least one measurement data selected from the group consisting of a line width of a resist pattern formed in the step C1, the number of defects of the resist pattern formed in the step C1, and a rate at which the exposed resist film is dissolved by the second developer, the rate being measured in the step C1.

Step Y1: a step of determining whether the measurement data acquired in the step X1 falls within a preset allowable range.

In the method for inspecting a resist composition according to this embodiment, the rate at which the resist film formed using the resist composition is dissolved by the second developer is higher than a rate at which the resist film formed using the resist composition is dissolved by the first developer.

One feature of the inspection method according to this embodiment is that while the quality inspection of a resist composition is typically performed using a developer (first developer) actually used in forming a resist pattern using the resist composition, the quality inspection is performed using another developer (second developer) that dissolves a resist film at a higher rate than the first developer.

By inspecting a resist composition in this manner using the second developer that dissolves a resist film at a higher rate than the first developer actually used, a slight change in quality of the resist composition after a predetermined period of time from the production can be detected. More specifically, a variation in LWR performance of a resist pattern formed using the resist composition can be detected.

While the detailed reason why a decrease in performance of the resist composition after a predetermined period of time, which cannot be detected by the inspection using the first developer, can be detected by using the second developer is unclear, the present inventors presume that by using the developer that dissolves a resist film at higher rate than the developer actually used, a slight change in the resist composition properties, which causes the decrease in performance of the resist composition after a predetermined period of time, is amplified and detected as a distinct difference.

Thus, according to the inspection method, the effect that the LWR performance of a resist composition that has been stored for a predetermined period of time can be easily determined (hereinafter also referred to as “the effect of the present invention”) is produced.

Hereinafter, various materials used in the inspection method according to this embodiment will be described.

### Various Materials

### Resist Composition

As a resist composition to be inspected by the inspection method according to this embodiment, a known resist composition resist composition with which a resist pattern can be formed by performing an exposure treatment and a development treatment using a first developer can be used.

Here, the phrase “a resist pattern can be formed by performing an exposure treatment and a development treatment using a first developer” regarding a resist composition means that a resist pattern can be formed by performing an exposure treatment in which a resist film formed using the resist composition is subjected to pattern exposure and then performing a development treatment in which the exposed resist film is developed using the first developer.

An example of a method of forming a resist pattern using the resist composition is a pattern forming method having steps 1 to 3 described later.

The resist composition will be described in detail later.

### First Developer

As the first developer, a developer suitable for the resist composition used in the inspection method according to this embodiment is selected. The first developer is not particularly limited as long as it can dissolve a resist film formed using the resist composition, and can be selected from known developers.

The expression “a resist film formed using the resist composition” or just “a resist film” in the present specification includes both an unexposed film not subjected to an exposure treatment after being formed using the resist composition and a film subjected to an exposure treatment after being formed using the resist composition. That is, the first developer may be a negative-type developer which forms a resist pattern by removing an unexposed portion of a resist film or a positive-type developer which forms a resist pattern by removing an exposed portion of a resist film.

The first developer is, for example, an alkali developer or an organic solvent developer, preferably an organic solvent developer.

The alkali developer is preferably an alkaline aqueous solution including an alkali. The alkaline aqueous solution may be of any type and is, for example, an alkaline aqueous solution including at least one selected from the group consisting of quaternary ammonium salts typified by tetramethylammonium hydroxide, inorganic alkalis, primary amines, secondary amines, tertiary amines, alcohol amines, and cyclic amines. In particular, the alkali developer is preferably an aqueous solution of a quaternary ammonium salt typified by tetramethylammonium hydroxide (TMAH). An appropriate amount of an alcohol, a surfactant, or the like may be added to the alkali developer.

The alkali developer often has an alkali concentration of 0.1 to 20 mass %. The alkali developer often has a pH of 10.0 to 15.0.

The organic solvent developer is a developer including an organic solvent.

The vapor pressure of the organic solvent included in the organic solvent developer (in the case of a mixed solvent, the vapor pressure of the whole mixed solvent) at 20° C. is preferably 5 kPa or less, more preferably 3 kPa or less, still more preferably 2 kPa or less. When the vapor pressure of the organic solvent is 5 kPa or less, evaporation of the developer on the substrate or in a development cup is suppressed, and the temperature uniformity in a wafer plane is improved, resulting in better dimensional uniformity in the wafer plane.

The organic solvent used in the organic solvent developer may be a known organic solvent, such as an ester solvent, a ketone solvent, an alcohol solvent, an amide solvent, an ether solvent, or a hydrocarbon solvent.

The ester solvent is, for example, an ester solvent having 3 to 12 carbon atoms, preferably an ester solvent having 4 to 10 carbon atoms.

The ester solvent may have an alkyl group. The alkyl group may be linear, branched, or cyclic, and is preferably linear.

The heteroatom contained in the ester solvent is preferably an oxygen atom, and the heteroatom contained is more preferably the oxygen atom alone. The ester solvent may have one or more —COO— moieties, and preferably has only one —COO— moiety.

More specific examples of the ester solvent include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxy propionate, 3-methoxybutyl acetate, 3-methyl-3-methoxybutyl acetate, methyl formate, ethyl formate, butyl formate, propyl formate, ethyl lactate, butyl lactate, propyl lactate, butyl butanoate, methyl 2-hydroxyisobutyrate, isoamyl acetate, isobutyl isobutyrate, and butyl propionate. In particular, butyl acetate, isobutyl acetate, or isoamyl acetate is preferred, and butyl acetate is more preferred.

Examples of the ketone solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetyl carbinol, acetophenone, methyl naphthyl ketone, isophorone, and propylene carbonate.

The hydrocarbon solvent is, for example, an aliphatic hydrocarbon solvent or an aromatic hydrocarbon solvent. The number of carbon atoms of the hydrocarbon solvent is preferably 3 to 20, more preferably 8 to 12, still more preferably 9 to 11.

The aliphatic hydrocarbon solvent may be a saturated aliphatic hydrocarbon solvent or an unsaturated aliphatic hydrocarbon solvent, and is preferably a saturated aliphatic hydrocarbon solvent. The aliphatic hydrocarbon solvent may be linear, branched, or cyclic, and is preferably linear. The aromatic hydrocarbon solvent may be monocyclic or polycyclic.

The hydrocarbon solvent is preferably a saturated aliphatic hydrocarbon solvent, more preferably octane, nonane, decane, undecane, or dodecane, still more preferably nonane, decane, or undecane.

As the alcohol solvent, the amide solvent, the ether solvent, and the hydrocarbon solvent, solvents disclosed in paragraphs [0715] to [0718] of US2016/0070167A, the contents of which are incorporated herein, can be used.

The first developer is preferably an organic solvent developer, more preferably includes at least one selected from the group consisting of an ester solvent and a hydrocarbon solvent, and is still more preferably a mixed solvent including an ester solvent and a hydrocarbon solvent.

In particular, the ester solvent is preferably butyl acetate. That is, the first developer particularly preferably includes butyl acetate and a hydrocarbon solvent.

The hydrocarbon solvent used in combination with the ester solvent is, for example, any of the above preferred saturated aliphatic hydrocarbon solvents in terms of adjustment of the solubility of the resist film, preferably nonane, decane, or undecane, more preferably undecane.

The first developer may include one of the above organic solvents alone or a combination of two or more thereof. When the first developer includes two or more organic solvents, the content of each organic solvent is not particularly limited and may be appropriately determined because it depends on the solvent solubility of the resist film.

When the first developer includes an ester solvent and a hydrocarbon solvent, the content of the ester solvent is preferably 10 to 95 mass %, more preferably 25 to 93 mass %, still more preferably 40 to 91 mass %, relative to the total mass of the first developer. The content of the hydrocarbon solvent is preferably 5 to 90 mass %, more preferably 7 to 75 mass %, still more preferably 9 to 60 mass %, relative to the total mass of the first developer.

The content of the organic solvent (in the case of a mixture of a plurality of kinds, the total content) in the first developer is preferably 80 mass % or more, more preferably 90 mass % or more, relative to the total mass of the first developer. In particular, the first developer still more preferably includes substantially only the organic solvent, and the content of the organic solvent is particularly preferably 98 mass % or more relative to the total mass of the first developer. The upper limit is not particularly limited and may be 100 mass %.

The first developer may include water but preferably includes substantially no water. The content of water is more preferably 2 mass % or less relative to the total mass of the first developer, and the first developer still more preferably includes no water.

The rate at which the resist film formed using the resist composition is dissolved by the first developer (hereinafter also referred to as the “first dissolution rate”) is preferably 0.1 nm/s or more, more preferably 0.5 nm/s or more, still more preferably 1.0 nm/s or more, from the viewpoint of suppressing the residue occurrence due to insufficient development. The upper limit is not particularly limited but is preferably 1,000 nm/s or less, more preferably 500 nm/s or less, from the viewpoint of suppressing film loss of a pattern.

The rate at which the resist film is dissolved by the first developer (and the second developer described later) can be determined by dividing the amount of change in resist film thickness by the time required for development.

The dissolution rate in the case where the resist film remains after treatment for a predetermined developing time can be determined by measuring the film thicknesses before and after development to determine the amount of change in film thickness and dividing the amount by the predetermined developing time. The film thicknesses before and after development can be measured using, for example, optical interferometry or ellipsometry.

The dissolution rate in the case where the resist film does not remain after treatment for a predetermined developing time can be determined by dividing the initial film thickness by the time required for development. The time required for development can be determined by, for example, measuring in real time the change in parameter obtained by spectral interferometry or the quartz crystal microbalance technique (QCM technique) and analyzing the behavior of the change. A specific example of a method of calculating the first dissolution rate by determining the time required for development using the QCM technique will be described in EXAMPLES given later.

The formation of the resist film for measuring the first dissolution rate and the exposure of the resist film, which is performed as necessary, may be performed respectively in accordance with the step 1 and the step 2 described later.

The first developer is, for example, an alkali developer or an organic solvent developer.

### Substrate

The substrate is not particularly limited as long as it is a substrate as used in manufacturing an integrated circuit element, and is, for example, a silicon wafer or a silicon wafer coated with silicon dioxide, preferably a silicon wafer.

### Step A1

In the inspection method according to this embodiment, the step A1 of forming a resist film on a substrate using the resist composition is first performed.

The method of forming a resist film on a substrate using the resist composition is, for example, applying the resist composition onto the substrate to form a coating film. Other examples of the method of forming a coating film include a coating method using a coater cup, a coating method using an organic development unit, and a spin coating method using a spinner. The number of rotations in performing spin coating using a spinner is preferably 500 to 3000 rpm.

After the resist composition is applied onto the substrate to form a coating film, the coating film is preferably dried.

The method of drying is, for example, drying by heating. The heating can be performed using means provided in an ordinary exposure device and/or an ordinary development device, and may be performed using heating means such as a hot plate. The heating temperature is preferably 80° C. to 150° C., more preferably 80° C. to 140° C., still more preferably 80° C. to 130° C. The heating time is preferably 30 to 1000 seconds, more preferably 60 to 800 seconds, still more preferably 60 to 600 seconds. For example, the heating is preferably performed at 100° C. for 60 seconds.

The thickness of the resist film is not particularly limited, but is preferably 10 to 1000 nm, more preferably 10 to 120 nm. When the resist film is subjected to pattern formation by EUV exposure or EB exposure, the thickness of the resist film is still more preferably 10 to 100 nm, particularly preferably 15 to 70 nm. When the resist film is subjected to pattern formation by ArF liquid immersion exposure or KrF liquid immersion exposure, the thickness of the resist film is still more preferably 15 to 90 nm.

The thickness of the resist film can be adjusted by, for example, controlling the composition and viscosity of the resist composition and conditions such as the temperature of the resist composition to be applied and the rotational speed of the spin coater.

### Step B1

In the inspection method according to this embodiment, after the step A1, the step B1 of exposing the resist film formed in the step A1 is performed.

The radiation used for the exposure in the step B1 is, for example, infrared light, visible light, ultraviolet light, far ultraviolet light, extreme ultraviolet light, X-rays, or EB, preferably far ultraviolet light, extreme ultraviolet light, or EB. The wavelength of far ultraviolet light or extreme ultraviolet light is preferably 250 nm or less, more preferably 220 nm or less, still more preferably 1 to 200 nm.

In the step B1, the resist film is preferably exposed using at least one selected from the group consisting of EUV exposure (wavelength: 13.5 nm), KrF exposure (wavelength: 248 nm), ArF exposure (wavelength: 193 nm), and EB exposure, and EUV exposure is more preferred.

When a line width of a resist pattern formed in the step C1 or the number of defects of the resist pattern formed in the step C1 is acquired as measurement data in the step X1 described later, pattern exposure in which the resist film is irradiated with any of the above radiations through a predetermined mask can be performed in the step B1. Instead of using a mask, the pattern exposure may be performed by patterning using a corpuscular beam such as an EB or an ion beam.

The mask used in the pattern exposure is appropriately selected depending on the resist pattern formed in the step C1. For example, in the case of EUV exposure, a mask having a line-and-space pattern with a line width of 8 to 100 nm and a pitch of 16 to 200 nm is preferred. In the case of ArF exposure, a mask having a line-and-space pattern with a line width of 30 to 150 nm and a pitch of 76 to 300 nm is preferred. In the case of KrF exposure, a mask having a line-and-space pattern with a line width of 50 to 150 nm and a pitch of 180 to 300 nm is preferred.

The exposed resist film is preferably subjected to baking (PEB).

The heating temperature is preferably 80° C. to 150° C., more preferably 80° C. to 140° C.

The heating time is preferably 10 to 1000 seconds, more preferably 10 to 180 seconds.

The heating can be performed using means provided in an ordinary exposure device and/or an ordinary development device, and may be performed using a hot plate or the like.

### Step C1

The step C1 is a step of bringing a second developer different from the first developer into contact with the resist film formed in the step A1 and exposed in the step B1. Hereinafter, the second developer used in the step C1 and the procedure of the step C1 will be described.

### Second Developer

In the step C1, a developer that is capable of dissolving the resist film formed using the resist composition and that dissolves the resist film at a higher rate than the first developer is used as the second developer.

The second developer is not particularly limited as long as it can dissolve the resist film formed using the resist composition used in the inspection method according to this embodiment and dissolves the resist film at a higher rate than the first developer, and can be selected from known developers.

Specific examples of the second developer, including preferred examples thereof, are the same as the developers listed as the first developer.

In particular, the second developer preferably includes an ester solvent. The ester solvent included in the second developer is preferably butyl acetate, isobutyl acetate, or isoamyl acetate, more preferably butyl acetate.

The content of the ester solvent in the second developer is preferably 80 mass % or more, more preferably 90 mass % or more, relative to the total mass of the second developer. In particular, the second developer still more preferably includes substantially only the ester solvent, particularly preferably includes substantially only at least one solvent selected from the group consisting of butyl acetate, isobutyl acetate, and isoamyl acetate, most preferably includes substantially only butyl acetate.

The upper limit of the content of the ester solvent included in the second developer is not particularly limited and may be 100 mass %.

The rate at which the resist film formed using the resist composition is dissolved by the second developer (hereinafter also referred to as the “second dissolution rate”) is preferably 0.1 nm/s or more, more preferably 0.5 nm/s or more, still more preferably 1.0 nm/s or more. The upper limit is not particularly limited, but is preferably 1,000 nm/s or less, more preferably 500 nm/s or less.

The ratio of the second dissolution rate to the first dissolution rate is not particularly limited as long as it is more than 1.0, but is preferably more than 1.0 and 100 or less, more preferably more than 1.0 and 50 or less, still more preferably 2.0 to 20.0.

The second dissolution rate can be measured according to the method of measuring the first dissolution rate described above.

### Procedure of Step C1

The method of bringing the second developer into contact with the resist film exposed in the step B1 is not particularly limited.

Examples of the method of bringing into contact include immersing the resist-film-carrying substrate in a tank filled with the second developer for a certain period of time, forming a puddle of the second developer on the surface of the resist film by the action of surface tension and leaving them to stand for a certain period of time to achieve removal, spraying the second developer onto the surface of the resist film, and continuously ejecting the second developer, while scanning a jetting nozzle at a constant rate, onto the resist-film-carrying substrate rotating at a constant rate. The removal by the above method can be performed with a development unit.

Other examples of the method of bringing into contact include a method using a coater cup, a method using a development unit, and spin coating using a spinner. The number of rotations in performing spin coating using a spinner is preferably 500 to 3000 rpm. The feed rate of the second developer is preferably 0.2 to 10.0 mL/s, and the feed time is preferably 3 to 300 seconds.

The temperature of the second developer is not particularly limited, and is preferably 0° C. to 50° C., more preferably 15° C. to 35° C.

The time of contact of the second developer with the resist film, in terms of higher inspection accuracy, is, for example, 800 seconds or less, preferably 300 seconds or less, more preferably 60 seconds or less. The lower limit is, for example, 5 seconds or more.

After the contact treatment is performed, the resist-film-carrying substrate is preferably dried.

The method of drying is, for example, drying by heating. The heating can be performed using means provided in an ordinary exposure device and/or an ordinary development device, and may be performed using a hot plate or the like. The heating temperature is preferably 80° C. to 200° C., more preferably 80° C. to 140° C., still more preferably 80° C. to 130° C. The heating time is preferably 30 to 1000 seconds, more preferably 60 to 800 seconds, still more preferably 60 to 600 seconds. For example, the heating is preferably performed at 100° C. for 60 seconds.

### Step X1

In the step X1, at least one measurement data selected from the group consisting of a line width of a resist pattern formed in the step C1, a rate at which the exposed resist film is dissolved by the second developer, the rate being measured in the step C1, and the number of defects of the resist pattern formed in the step C1 is acquired.

Hereinafter, the step X1 will be described as a “step X1a”, which is a step of acquiring, as measurement data, a line width of a resist pattern formed in the step C1, a “step X1b”, which is a step of acquiring, as measurement data, the number of defects of the resist pattern formed in the step C1, and a “step X1c”, which is a step of acquiring, as measurement data, a rate at which the exposed resist film is dissolved by the second developer, the rate being measured in the step C1.

### Step X1a

The step X1a is a step of measuring a line width of a resist pattern formed through the steps A1, B1, and C1 and acquiring the line width as measurement data.

The line width of the resist pattern in the step X1a can be determined by measuring line widths at randomly selected 160 points through observation of the surface of the resist pattern using a critical dimension scanning electron microscope (SEM, e.g., “CG-4100” manufactured by Hitachi High-Technologies Corporation) and calculating the arithmetic average of the measured values.

When the step X1a is performed, it is preferable to perform pattern exposure using a mask in the step B1. The mask used in the pattern exposure preferably, but not necessarily, has a line-and-space pattern, and is appropriately selected from known masks having a line width and a pitch corresponding to the exposure light applied in the step B1.

### Step X1b

The step X1b is a step of measuring the number of defects of the resist pattern formed through the steps A1, B1, and C1 and acquiring the number as measurement data. Specifically, the number of defects, such as a bridge-like defect (bridge defect) where portions of the resist pattern formed are connected to each other, can be counted using a defect inspection apparatus (e.g., defect inspection apparatus KLA2925 manufactured by KLA-Tencor Corporation).

When the step X1b, as with the step X1a, is performed, it is preferable to perform pattern exposure using a mask in the step B1. The mask used in the pattern exposure is as described above.

### Step X1c

The step X1c is a step of measuring a rate at which the exposed resist film is dissolved by the second developer, the rate being measured in the step C1, and acquiring the rate as measurement data.

More specifically, the resist film exposed in the step B1 (the exposed portion of the resist film) is measured for a film thickness (FT1) before the step C1 and a film thickness (FT2) after the step C1, and a minimum resist film dissolution rate (Rmin) is calculated using the following formula, whereby the measurement data can be acquired.

Formula: R min=(FT1−FT2)/contact time (nm/s) in step C1

The thicknesses of the resist film before and after the step C1 can be measured with an optical coherence-type film thickness meter (e.g., “VM-3200 (product name) manufactured by SCREEN Semiconductor Solutions Co., Ltd.”).

### Step Y1

In the step Y1, whether the measurement data acquired in the step X1 falls within a preset allowable range is determined.

The allowable range is preset before the step Y1 on the basis of the type of the measurement data acquired in the step X1, the desired performance of the resist composition, etc. Using this allowable range, when the measurement data acquired in the step X1 falls within the allowable range, it is determined as “acceptable”, and when the measurement data does not fall within the allowable range, it is determined as “unacceptable”.

The method of setting the allowable range used in the step Y1 is not particularly limited as long as it does not depart from the spirit of the present invention. The allowable range may be, for example, a relative numerical range set on the basis of predetermined reference data or an absolute numerical range.

The reference data is, for example, reference data derived from measurement data of a previously produced resist composition. More specifically, the measurement data of a previous production lot in the case where multiple lots of resist compositions are produced can be used as the reference data.

Here, “the same lot” means the same production lot.

Hereinafter, a previous production lot in which measurement data used as the reference data in the step Y1 is measured is also referred to as the “reference lot”.

The reference lot is, for example, the initially produced lot (initial lot), the lot produced immediately before the step Y1 is performed (immediately preceding lot), or the lot whose measurement data is the best (best lot) among previously produced multiple production lots, preferably the initial lot or the immediately preceding lot.

The reference data may be an average value of measurement data of multiple reference lots selected from previously produced multiple production lots. The multiple reference lots may be randomly selected from the previously produced multiple lots, may be multiple lots continuing from the immediately preceding lot backward (e.g., the last one to five lots including the immediately preceding lot), or may be all the previously produced lots. When the average value of measurement data of multiple lots is used as the reference data, it is preferable to employ, as the reference lots, multiple lots continuing from the immediately preceding lot backward or all the previously produced lots.

The method of acquiring reference data from the one or multiple reference lots is, for example, a method having the following steps A0, B0, C0, and X0.

Step A0: a step of forming a resist film on a substrate using a part of the one or multiple reference lots.

Step B0: a step of exposing the resist film formed in the step A0.

Step C0: a step of bringing the second developer into contact with the resist film exposed in the step B0.

Step X0: a step of acquiring, according to the measurement data acquired in the step X1, at least one reference data selected from the group consisting of a line width of a resist pattern formed in the step C0, the number of defects of the resist pattern formed in the step C0, and a rate at which the exposed resist film is dissolved by the second developer, the rate being measured in the step C0.

The steps A0, B0, C0, and X0 may be performed similarly to the steps A1, B1, C1, and X1, respectively, and are preferably performed in the same manner as the steps A1, B1, C1, and X1, respectively, in terms of higher inspection accuracy. Thus, the steps A0, B0, C0, and X0 will not be elaborated here.

The method of setting the allowable range based on the reference data is not particularly limited. The allowable range is appropriately set according to the type of the measurement data, the desired performance of the resist composition, etc. Examples of the allowable range include a range whose difference from the reference data is within a predetermined range and a range whose ratio to the reference data is within a predetermined range. The ratio to the reference data set as the allowable range can be appropriately set according to, for example, the composition and intended use of the resist composition. The allowable range is, for example, a range within 1% to 50% (preferably within 1% to 10%) of the reference data, but is not limited to this range. When an average value of measurement data acquired from multiple reference lots is used as the reference data, the allowable range may be set on the basis of a standard deviation obtained from multiple measurement data. The allowable range in this case is, for example, a range whose difference from the average value, which is the reference data, is within the standard deviation or within a predetermined multiple of the standard deviation, but is not limited to this range.

The allowable range is based on the type of the measurement data, the desired performance of the resist composition, etc. and may be a range set on the basis of the type of the measurement data, the desired performance of the resist composition, etc. without referring to previous measurement data.

For example, for the allowable range to be compared with the line width of a resist pattern acquired as the measurement data in the step X1a, a line width used as the reference data is preset, and, furthermore, a range whose ratio to the set line width is within a predetermined range can be preset as the allowable range.

The line width used as the reference data in this case is preferably 5 to 200 nm, more preferably 10 to 100 nm, still more preferably 12 to 50 nm when EUV exposure is performed in the step B1, preferably 20 to 400 nm, more preferably 40 to 200 nm, still more preferably 60 to 150 nm when KrF exposure is performed, preferably 15 to 300 nm, more preferably 30 to 150 nm, still more preferably 40 to 120 nm when ArF exposure is performed, and preferably 5 to 200 nm, more preferably 10 to 150 nm, still more preferably 12 to 100 nm when EB exposure is performed. The ratio to the line width used as the reference data is preferably within 1% to 50%, more preferably within 1% to 10% (e.g., within 5%).

As the allowable range to be compared with the number of defects of the resist pattern acquired as the measurement data in the step X1b, a predetermined range of the number of defects can be preset.

The allowable range in this case is, for example, preferably 0.0001 to 10/cm² or less, more preferably 0.0005 to 5/cm² or less, still more preferably 0.001 to 1/cm² or less, relative to the area of the resist pattern formed on a wafer.

The step Y1 of determining whether the measurement data falls within the allowable range is performed with, for example, a processing apparatus configured using hardware such as a computer. An exemplary configuration of a processing apparatus that performs the determination in the step Y1 will be described below, but the step Y1 is not necessarily performed with the following processing apparatus.

The processing apparatus has an input unit, a processing unit, a storage unit, and an output unit. Memory has a memory that can store external data and a read-only memory (ROM).

The processing apparatus may be configured with a computer in which each part functions upon execution of a program stored in ROM or may be a dedicated apparatus in which each part is configured with a dedicated circuit. The program is provided in the form of, for example, computer software.

The input unit is a part having a function to input the measurement data acquired in the step X1, and may be, for example, an input device such as a mouse or a keyboard or may be a measuring device that executes the step X1.

The processing unit is a part that performs the determination in the step Y1. More specifically, the processing unit receives the measurement data acquired in the step X1 from the input unit and also reads the allowable range stored in the storage unit, and compares the measurement data with the allowable range to determine whether the measurement data falls within the allowable range. The processing unit, in accordance with a preset program, performs a predetermined control on the output unit according to the determination result. The processing unit stores the measurement data input from the input unit in the storage unit. In some cases, the processing unit, on the basis of data selected from the group consisting of the measurement data input from the input unit and past measurement data stored in the storage unit, calculates new reference data and a new allowable range and stores them in the storage unit.

The output unit is a part having a function to output the determination result in the step Y1; examples include a display device such as a display configured to display the determination result, a device such as a printer configured to display the determination result on an output medium, a sound output device configured to output an alarm, and communication means configured to notify the user of the determination result.

In the step Y1, when the measurement data acquired in the step X1 does not fall within the allowable range (when the determination result is unacceptable), the processing unit may control the output unit to perform an action selected from the group consisting of showing that the determination result is unacceptable (e.g., a display on the display device or a display on the output medium) and giving the user a warning (e.g., an alarm or a notification). This can notify the user that the measurement data acquired in the step X1 does not fall within the allowable range and prompt the user to actions such as suspension of the production of the resist composition and disposal or purification of the resist composition of the same lot as the resist composition whose measurement data has been acquired.

When the measurement data acquired in the step X1 falls within the allowable range (when the determination result is acceptable), the processing unit may control the output unit to perform an action selected from the group consisting of showing that the determination result is acceptable (e.g., a display on the display device or a display on the output medium) and giving the user a notification.

The processing apparatus may have a production unit (production device) configured to produce the resist composition, and the processing unit may be connected to the production unit through an electric circuit. For example, when the measurement data acquired in the step X1 is determined not to fall within the allowable range in the step Y1 (when the determination result is unacceptable), the processing unit may control the production unit to stop the production of the resist composition. When the measurement data acquired in the step X1 falls within the allowable range (when the determination result is acceptable), the processing unit may control the production unit to continue the production of the resist composition.

The production unit may have any configuration as long as it can produce the resist composition, and a known production device can be appropriately used.

### Second Embodiment

A method for inspecting a resist composition according to a second embodiment of the present invention (hereinafter also referred to as “the inspection method according to this embodiment”) is a method for inspecting a resist composition with which a resist pattern can be formed by performing an exposure treatment and a development treatment using a first developer and has the following steps.

Step A2: a step of forming a resist film on a substrate using the resist composition.

Step C2: a step of bringing a second developer different from the first developer into contact with the resist film formed in the step A2.

Step X2: a step of acquiring at least one measurement data selected from the group consisting of the number of defects on a surface of the substrate from which the resist film has been removed as a result of the step C2 and a rate at which the resist film is dissolved by the second developer, the rate being measured in the step C2.

Step Y2: a step of determining whether the measurement data acquired in the step X2 falls within a preset allowable range.

In the method for inspecting a resist composition according to this embodiment, the rate at which the resist film formed using the resist composition is dissolved by the second developer is higher than a rate at which the resist film formed using the resist composition is dissolved by the first developer.

The feature of the inspection method according to this embodiment and the advantage in that the significantly excellent effect of the present invention is produced by using the second developer are the same as in the first embodiment and will not be elaborated here.

Various materials such as the resist composition, the first developer, the second developer, and the substrate used in the inspection method according to this embodiment are the same as in the first embodiment and thus will not be elaborated here.

Hereinafter, the steps in the inspection method according to this embodiment will be described.

### Step A2

In the inspection method according to this embodiment, the step A2 of forming a resist film on a substrate using the resist composition is performed. The step A2 is the same as the step A1 in the first embodiment.

### Step C2

The step C2 is a step of bringing a second developer different from the first developer into contact with the resist film formed in the step A2.

The specific procedure of the step C2 is the same as that of the step C1 in the first embodiment except that the object with which the second developer is brought into contact is the resist film formed on the substrate using the resist composition in the step A2. Thus, the step C2 can be performed according to the method described in Procedure of Step C1 above. Step X2

In the step X2, at least one measurement data selected from the group consisting of the number of defects on a surface of the substrate from which the resist film has been removed as a result of the step C2 and a rate at which the resist film is dissolved by the second developer, the rate being measured in the step C2 is acquired.

Hereinafter, the step X2 will be described as a “step X2a”, which is a step of acquiring, as measurement data, the number of defects on a surface of the substrate from which the resist film has been removed as a result of the step C2, and a “step X2b”, which is a step of acquiring, as measurement data, a rate at which the resist film is dissolved by the second developer, the rate being measured in the step C2.

### Step X2a

The step X2a is a step of measuring, after the resist film formed in the step A2 is dissolved in the step C2, the number of defects present on a substrate surface from which the resist film has been removed and acquiring the number as measurement data.

The defects measured in the step X2a may be of any type but are preferably defects having a size of 19 nm or more.

The defect inspection in the step X2a can be performed using a defect inspection apparatus (e.g., defect inspection apparatus KLA2925 manufactured by KLA-Tencor Corporation).

The number of defects acquired as measurement data in the step X2a preferably does not include the number of defects existing on the substrate before the step A2 (the number of defects derived from the substrate). That is, the step X2a preferably has a step of calculating the number of defects derived from the resist composition by subtracting the number of defects derived from the substrate from a measured value of the number of defects measured with the defect inspection apparatus. This enables the number of defects derived from the resist composition to be inspected with higher accuracy.

When the number of defects derived from the substrate is already known from a description in a catalog or the like, this nominal value can be used.

### Step X2b

The step X2b is a step of measuring a rate at which the resist film is dissolved by the second developer, the rate being measured in the step C2, and acquiring the rate as measurement data.

The rate at which the resist film is dissolved by the second developer in the step X2b can be measured according to the method of measuring the first dissolution rate described above.

### Step Y2

In the step Y2, whether the measurement data acquired in the step X2 falls within a preset allowable range is determined.

The allowable range is preset before the step Y2 on the basis of the type of the measurement data acquired in the step X2, the desired performance of the resist composition, etc. Using this allowable range, when the measurement data acquired in the step X2 falls within the allowable range, it is determined as “acceptable”, and when the measurement data does not fall within the allowable range, it is determined as “unacceptable”.

The step Y2 can be performed according to the same procedure as that of the step Y1 in the first embodiment.

The allowable range compared with the measurement data in the step Y2 is based on the type of the measurement data, the desired performance of the resist composition, etc. and may be a range set on the basis of the type of the measurement data, the desired performance of the resist composition, etc. without referring to previous measurement data.

For example, for the allowable range to be compared with the number of defects present on a substrate surface acquired as the measurement data in the step X2a, a predetermined range of the number of defects can be preset. The allowable range in this case is, for example, 0.0001 to 10/cm² or less, preferably 0.0005 to 5/cm² or less, more preferably 0.001 to 1/cm² or less, relative to the area of the substrate surface from which the resist film has been removed.

The method for inspecting a resist composition according to the first embodiment and the method for inspecting a resist composition according to the second embodiment described above (hereinafter also referred to collectively as “the inspection method according to the present invention” or “the present inspection method”) can be used for the quality control of a composition produced. For example, a resist composition whose measurement data has been determined to fall within the allowable range as a result of inspection by the present inspection method can be brought into the market as an acceptable product. For a resist composition whose measurement data does not fall within the allowable range, the necessity of actions such as disposal, purification, and component addition can be detected.

### Resist Composition

Hereinafter, the resist composition used in the inspection method according to the present invention (hereinafter also referred to simply as “the resist composition”) will be described in detail.

The resist composition is not particularly limited as long as it is a resist composition with which a resist pattern can be formed through an exposure treatment and a development treatment using the first developer. The resist composition may be a positive-type resist composition or a negative-type resist composition. The resist composition may be a resist composition for alkali development or a resist composition for organic-solvent development.

The resist composition may be a chemically amplified resist composition or a non-chemically amplified resist composition. The resist composition is typically a chemically amplified resist composition.

The exposure treatment preferably includes EUV exposure, KrF exposure, ArF exposure, or EB exposure, and is more preferably EUV exposure.

Hereinafter, various components included in the resist composition will be described in detail.

### Acid-Decomposable Resin

The resist composition includes, for example, an acid-decomposable resin (hereinafter also referred to as a “resin (A)”).

The resin (A) typically includes a group that decomposes under the action of acid to become more polar (hereinafter also referred to as an “acid-decomposable group”), preferably includes a repeating unit having an acid-decomposable group.

When the resin (A) includes an acid-decomposable group, in the pattern forming method in the present specification, typically, a positive-type pattern is suitably formed if an alkali developer is employed as a developer, and a negative-type pattern is suitably formed if an organic-based developer is employed as a developer.

The repeating unit having an acid-decomposable group is preferably not only a repeating unit having an acid-decomposable group described below but also a repeating unit having an acid-decomposable group including an unsaturated bond.

### Repeating Unit (A-a) Having Acid-Decomposable Group

The resin (A) preferably has a repeating unit (A-a) having an acid-decomposable group (hereinafter also referred to as a “repeating unit (A-a)”).

The acid-decomposable group is a group that decomposes under the action of acid to yield a polar group, and preferably has a structure in which the polar group is protected by a leaving group that leaves under the action of acid. That is, the resin (A) preferably has a repeating unit (A-a) having a group that decomposes under the action of acid to yield a polar group. A resin having the repeating unit (A-a) becomes more polar under the action of acid to be more soluble in alkali developers and less soluble in organic solvents.

The polar group is preferably an alkali-soluble group; examples include alcoholic hydroxyl groups and acidic groups such as a carboxyl group, phenolic hydroxyl groups, fluoroalcohol groups, a sulfonic group, a sulfonamide group, a sulfonylimide group, (alkylsulfonyl)(alkylcarbonyl)methylene groups, (alkylsulfonyl)(alkylcarbonyl)imide groups, bis(alkylcarbonyl)methylene groups, bis(alkylcarbonyl)imide groups, bis(alkylsulfonyl)methylene groups, bis(alkylsulfonyl)imide groups, tris(alkylcarbonyl)methylene groups, and tris(alkylsulfonyl)methylene groups.

In particular, the polar group is preferably a carboxyl group, a phenolic hydroxyl group, a fluoroalcohol group (preferably a hexafluoroisopropanol group), or a sulfonic group.

Examples of the leaving group that leaves under the action of acid include groups represented by formulae (Y1) to (Y4).

—C(Rx₁)(Rx₂)(Rx₃) Formula (Y1):

—C(═O)OC(Rx₁)(Rx₂)(Rx₃) Formula (Y2):

—C(R₃₆)(R₃₇)(OR₃₈) Formula (Y3):

—C(Rn)(H)(Ar) Formula (Y4):

In formula (Y1) and formula (Y2), Rx₁ to Rx₃ each independently represent an alkyl group (linear or branched), a cycloalkyl group (monocyclic or polycyclic), an alkenyl group (linear or branched), or an aryl group (monocyclic or polycyclic). When Rx₁ to Rx₃ are all alkyl groups (linear or branched), at least two of Rx₁ to Rx₃ are preferably methyl groups.

In particular, Rx₁ to Rx₃ preferably each independently represent a linear or branched alkyl group, and Rx₁ to Rx₃ more preferably each independently represent a linear alkyl group.

Two of Rx₁ to Rx₃ may be bonded to each other to form a monocyclic or polycyclic ring.

The alkyl group represented by Rx₁ to Rx₃ is preferably an alkyl group having 1 to 5 carbon atoms, such as a methyl group, an ethyl group, a n-propyl group, an isopropyl group, a n-butyl group, an isobutyl group, or a t-butyl group.

The cycloalkyl group represented by Rx₁ to Rx₃ is preferably a monocyclic cycloalkyl group such as a cyclopentyl group or a cyclohexyl group or a polycyclic cycloalkyl group such as a norbornyl group, a tetracyclodecanyl group, a tetracyclododecanyl group, or an adamantyl group.

The aryl group represented by Rx₁ to Rx₃ is preferably an aryl group having 6 to 10 carbon atoms; examples include a phenyl group, a naphthyl group, and an anthryl group.

The alkenyl group represented by Rx₁ to Rx₃ is preferably a vinyl group.

The ring formed through the bonding of two of Rx₁ to Rx₃ is preferably a cycloalkyl group. The cycloalkyl group formed through the bonding of two of Rx₁ to Rx₃ is preferably a monocyclic cycloalkyl group such as a cyclopentyl group or a cyclohexyl group or a polycyclic cycloalkyl group such as a norbornyl group, a tetracyclodecanyl group, a tetracyclododecanyl group, or an adamantyl group, more preferably a monocyclic cycloalkyl group having 5 or 6 carbon atoms.

In the cycloalkyl group formed through the bonding of two of Rx₁ to Rx₃, for example, one of methylene groups forming the ring may be replaced by a heteroatom such as an oxygen atom, a group having a heteroatom, such as a carbonyl group, or a vinylidene group. In the cycloalkyl group, one or more ethylene groups forming the cycloalkane ring may be replaced by vinylene groups.

The group represented by formula (Y1) or formula (Y2) preferably has a form, for example, in which Rx₁ is a methyl group or an ethyl group and Rx₂ and Rx₃ are bonded to each other to form the cycloalkyl group.

When the resist composition is, for example, a resist composition for EUV exposure, the alkyl group, the cycloalkyl group, the alkenyl group, and the aryl group represented by Rx₁ to Rx₃ and the ring formed through the bonding of two of Rx₁ to Rx₃ also preferably further have a fluorine atom or an iodine atom as a substituent.

In formula (Y3), R₃₆ to R₃₈ each independently represent a hydrogen atom or a monovalent organic group. R₃₇ and R₃₈ may be bonded to each other to form a ring. The monovalent organic group is, for example, an alkyl group, a cycloalkyl group, an aryl group, an aralkyl group, or an alkenyl group. R₃₆ is also preferably a hydrogen atom.

In the alkyl group, the cycloalkyl group, the aryl group, and the aralkyl group, a heteroatom such as an oxygen atom and/or a group having a heteroatom, such as a carbonyl group, may be included. For example, in the alkyl group, the cycloalkyl group, the aryl group, and the aralkyl group, for example, one or more methylene groups may each be replaced by a heteroatom such as an oxygen atom and/or a group having a heteroatom, such as a carbonyl group.

In the repeating unit having an acid-decomposable group described later, R₃₈ and another substituent on the main chain of the repeating unit may be bonded to each other to form a ring. The group formed through the bonding of R₃₈ and another substituent on the main chain of the repeating unit to each other is preferably an alkylene group such as a methylene group.

When the resist composition is, for example, a resist composition for EUV exposure, the monovalent organic group represented by R₃₆ to R₃₈ and the ring formed through the bonding of R₃₇ and R₃₈ to each other also preferably further have a fluorine atom or an iodine atom as a substituent.

Formula (Y3) is preferably a group represented by formula (Y3-1) below.

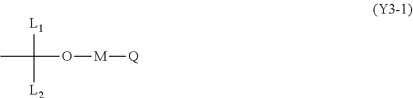

L₁ and L₂ each independently represent a hydrogen atom, an alkyl group, a cycloalkyl group, an aryl group, or a combination thereof (e.g., a combination of an alkyl group and an aryl group).
M represents a single bond or a divalent linking group.
Q represents an alkyl group that optionally includes a heteroatom, a cycloalkyl group that optionally includes a heteroatom, an aryl group that optionally includes a heteroatom, an amino group, an ammonium group, a mercapto group, a cyano group, an aldehyde group, or a combination thereof (e.g., a combination of an alkyl group and a cycloalkyl group).

In the alkyl group and the cycloalkyl group, for example, one methylene group may be replaced by a heteroatom such as an oxygen atom or a group having a heteroatom, such as a carbonyl group.

Preferably, one of L₁ and L₂ is a hydrogen atom, and the other is an alkyl group, a cycloalkyl group, an aryl group, or a combination of an alkylene group and an aryl group.

At least two of Q, M, and L₁ may be bonded to each other to form a ring (preferably, a five-membered or six-membered ring).

From the viewpoint of forming a finer pattern, L₂ is preferably a secondary or tertiary alkyl group, more preferably a tertiary alkyl group. The secondary alkyl group is, for example, an isopropyl group, a cyclohexyl group, or a norbornyl group, and the tertiary alkyl group is, for example, a tert-butyl group or an adamantane group. In the case of such a form, the repeating unit having an acid-decomposable group described later increases the glass transition temperature (Tg) and activation energy of the resin (A), so that film hardness can be ensured, and in addition fogging can be suppressed.

When the resist composition is, for example, a resist composition for EUV exposure, the alkyl group, the cycloalkyl group, the aryl group, and the combination thereof represented by L₁ and L₂ also preferably further have a fluorine atom or an iodine atom as a substituent. The alkyl group, the cycloalkyl group, the aryl group, and the aralkyl group also preferably include, in addition to the fluorine atom or the iodine atom, a heteroatom such as an oxygen atom (i.e., in the alkyl group, the cycloalkyl group, the aryl group, and the aralkyl group, for example, one methylene group is replaced by a heteroatom such as an oxygen atom or a group having a heteroatom, such as a carbonyl group).

When the resist composition is, for example, a resist composition for EUV exposure, in the alkyl group that optionally includes a heteroatom, the cycloalkyl group that optionally includes a heteroatom, the aryl group that optionally includes a heteroatom, the amino group, the ammonium group, the mercapto group, the cyano group, the aldehyde group, or the combination thereof represented by Q, the heteroatom is also preferably a heteroatom selected from the group consisting of a fluorine atom, an iodine atom, and an oxygen atom.

In formula (Y4), Ar represents an aromatic ring group. Rn represents an alkyl group, a cycloalkyl group, or an aryl group. Rn and Ar may be bonded to each other to form a non-aromatic ring. Ar is more preferably an aryl group.

When the resist composition is, for example, a resist composition for EUV exposure, the aromatic ring group represented by Ar and the alkyl group, the cycloalkyl group, or the aryl group represented by Rn also preferably have a fluorine atom and an iodine atom as substituents.

From the viewpoint of higher acid decomposability, when a non-aromatic ring is directly bonded to the polar group (or its residue) in the leaving group protecting the polar group, a ring-member atom in the non-aromatic ring adjacent to a ring-member atom directly bonded to the polar group (or its residue) also preferably does not have a halogen atom such as a fluorine atom as a substituent.

The leaving group that leaves under the action of acid may alternatively be a 2-cyclopentenyl group having a substituent (e.g., an alkyl group), such as a 3-methyl-2-cyclopentenyl group, or a cyclohexyl group having a substituent (e.g., an alkyl group), such as a 1,1,4,4-tetramethylcyclohexyl group.

The repeating unit (A-a) is also preferably a repeating unit represented by formula (A).

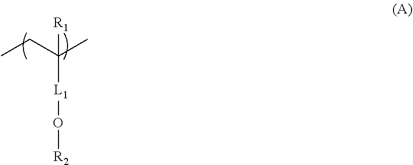

L₁ represents a divalent linking group that optionally has a fluorine atom or an iodine atom, R₁ represents an alkyl group that optionally has a hydrogen atom, a fluorine atom, an iodine atom, a fluorine atom, or an iodine atom or an aryl group that optionally has a fluorine atom or an iodine atom, and R₂ represents a leaving group that leaves under the action of acid and optionally has a fluorine atom or an iodine atom.

As a preferred form of the repeating unit represented by formula (A), at least one of L₁, R₁, or R₂ may have a fluorine atom or an iodine atom.

L₁ represents a divalent linking group that optionally has a fluorine atom or an iodine atom. Examples of the divalent linking group that optionally has a fluorine atom or an iodine atom include —CO—, —O—, —S—, —SO—, —SO₂—, a hydrocarbon group (e.g., an alkylene group, a cycloalkylene group, an alkenylene group, or an arylene group) that optionally has a fluorine atom or an iodine atom, and a linking group derived from linkage of two or more thereof. In particular, L₁ is preferably —CO—, an arylene group, or -arylene-alkylene that optionally has fluorine or iodine-, more preferably —CO—, an arylene group, or -arylene-alkylene that optionally has fluorine or iodine-.

The arylene group is preferably a phenylene group.

The alkylene group may be linear or branched. The number of carbon atoms of the alkylene group is not particularly limited, but is preferably 1 to 10, more preferably 1 to 3.

When the alkylene group has a fluorine atom or an iodine atom, the total number of fluorine atoms and iodine atoms included in the alkylene group is not particularly limited, but is preferably 2 or more, more preferably 2 to 10, still more preferably 3 to 6.

R₁ represents a hydrogen atom, a fluorine atom, an iodine atom, an alkyl group that optionally has a fluorine atom or an iodine atom, or an aryl group that optionally has a fluorine atom or an iodine atom.

The alkyl group may be linear or branched. The number of carbon atoms of the alkyl group is not particularly limited, but is preferably 1 to 10, more preferably 1 to 3.

The total number of fluorine atoms and iodine atoms included in the alkyl group having a fluorine atom or an iodine atom is not particularly limited, but is preferably 1 or more, more preferably 1 to 5, still more preferably 1 to 3.

The alkyl group may include a heteroatom other than halogen atoms, such as an oxygen atom.

R₂ represents a leaving group that leaves under the action of acid and optionally has a fluorine atom or an iodine atom. Examples of the leaving group that optionally has a fluorine atom or an iodine atom include the leaving groups represented by formulae (Y1) to (Y4) above and having a fluorine atom or an iodine atom, and preferred forms thereof are also the same.

The repeating unit (A-a) is also preferably a repeating unit represented by general formula (AI).

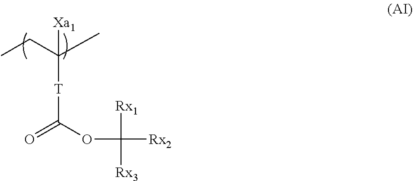

In general formula (AI),
Xa₁ represents a hydrogen atom or an optionally substituted alkyl group.

T represents a single bond or a divalent linking group.

Rx₁ to Rx₃ each independently represent an alkyl group (linear or branched), a cycloalkyl group (monocyclic or polycyclic), an aryl group, or an alkenyl group. When Rx₁ to Rx₃ are all alkyl groups (linear or branched), at least two of Rx₁ to Rx₃ are preferably methyl groups.

Two of Rx₁ to Rx₃ may be bonded to each other to form a cycloalkyl group (monocyclic or polycyclic).

The optionally substituted alkyl group represented by Xa₁ is, for example, a methyl group or a group represented as —CH₂—R₁₁. R₁₁ represents a halogen atom (e.g., a fluorine atom), a hydroxyl group, or a monovalent organic group, such as an alkyl group having 5 or less carbon atoms and optionally substituted with a halogen atom, an acyl group having 5 or less carbon atoms and optionally substituted with a halogen atom, or an alkoxy group having 5 or less carbon atoms and optionally substituted with a halogen atom, and is preferably an alkyl group having 3 or less carbon atoms, more preferably a methyl group. Xa₁ is preferably a hydrogen atom, a methyl group, a trifluoromethyl group, or a hydroxymethyl group.

Examples of the divalent linking group represented by T include alkylene groups, aromatic ring groups, —COO-Rt- groups, and —O-Rt- groups. In the formula, Rt represents an alkylene group or a cycloalkylene group.

T is preferably a single bond or —COO-Rt-. When T represents —COO-Rt-, Rt is preferably an alkylene group having 1 to 5 carbon atoms, more preferably —CH₂—, —(CH₂)₂—, or —(CH₂)₃—.

The alkyl group represented by Rx₁ to Rx₃ is preferably an alkyl group having 1 to 4 carbon atoms, such as a methyl group, an ethyl group, a n-propyl group, an isopropyl group, a n-butyl group, an isobutyl group, or a t-butyl group.

The cycloalkyl group represented by Rx₁ to Rx₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

The cycloalkyl group formed through the bonding of two of Rx₁ to Rx₃ is preferably a monocyclic cycloalkyl group such as a cyclopentyl group or a cyclohexyl group, and is also preferably a polycyclic cycloalkyl group such as a norbornyl group, a tetracyclodecanyl group, a tetracyclododecanyl group, or an adamantyl group. In particular, a monocyclic cycloalkyl group having 5 or 6 carbon atoms is preferred.

In the cycloalkyl group formed through the bonding of two of Rx₁ to Rx₃, for example, one methylene group forming the ring may be replaced by a heteroatom such as an oxygen atom or a group having a heteroatom, such as a carbonyl group.

The alkenyl group represented by Rx₁ to Rx₃ is, for example, a vinyl group.

The aryl group represented by Rx₁ to Rx₃ is, for example, a phenyl group.

The repeating unit represented by general formula (AI) preferably has a form, for example, in which Rx₁ is a methyl group or an ethyl group and Rx₂ and Rx₃ are bonded to each other to form the cycloalkyl group.

When the above-described groups each have a substituent, the substituent is, for example, an alkyl group (having 1 to 4 carbon atoms), a halogen atom, a hydroxyl group, an alkoxy group (having 1 to 4 carbon atoms), a carboxyl group, or an alkoxycarbonyl group (having 2 to 6 carbon atoms). The number of carbon atoms of the substituent is preferably 8 or less.

The repeating unit represented by general formula (AI) is preferably an acid-decomposable (meth)acrylic acid tertiary alkyl ester-based repeating unit (a repeating unit where Xa₁ represents a hydrogen atom or a methyl group and T represents a single bond).

The resin (A) may have one single type of repeating unit (A-a) or two or more types of repeating units (A-a).

The content of the repeating unit (A-a) (in the case where two or more repeating units (A-a) are present, the total content thereof is preferably 15 to 80 mol %, more preferably 20 to 70 mol %, relative to all the repeating units in the resin (A).

The resin (A) preferably has, as the repeating unit (A-a), at least one repeating unit selected from the group consisting of repeating units represented by general formulae (A-VIII) to (A-XII) below.

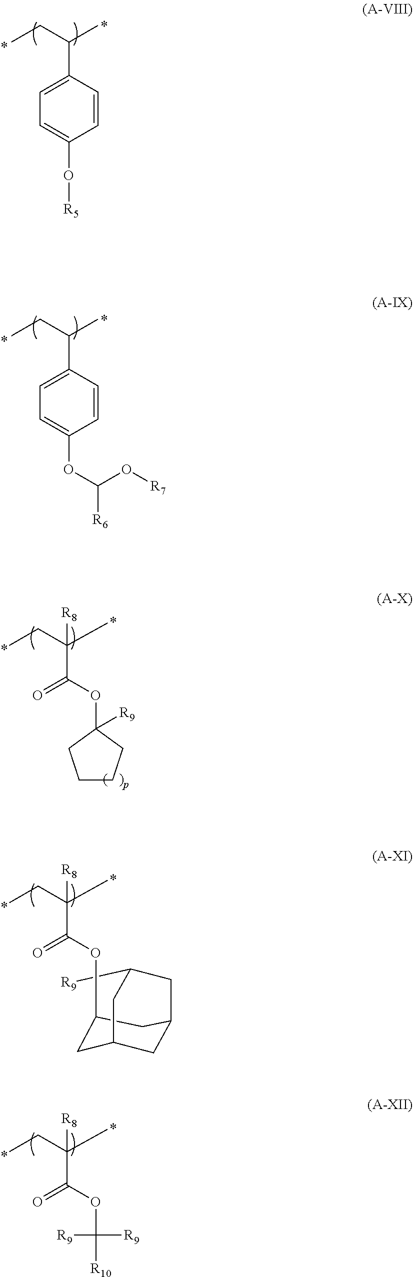

In general formula (A-VIII), R₅ represents a tert-butyl group or a —CO—O-(tert-butyl) group.

In general formula (A-IX), R₆ and R₇ each independently represent a monovalent organic group. The monovalent organic group is, for example, an alkyl group, a cycloalkyl group, an aryl group, an aralkyl group, or an alkenyl group.

In general formula (A-X), p represents 1 or 2.

In general formulae (A-X) to (A-XII), R₈ represents a hydrogen atom or an alkyl group having 1 to 3 carbon atoms, and R₉ represents an alkyl group having 1 to 3 carbon atoms.

In general formula (A-XII), R₁₀ represents an alkyl group having 1 to 3 carbon atoms or an adamantyl group.

### Repeating Unit (A-1) Having Acid Group

The resin (A) may have a repeating unit (A-1) having an acid group.

The acid group is preferably an acid group having a pKa of 13 or less. The acid dissociation constant of the acid group is preferably 13 or less, more preferably 3 to 13, still more preferably 5 to 10.

When the resin (A) has an acid group having a pKa of 13 or less, the content of the acid group in the resin (A) is not particularly limited but is often 0.2 to 6.0 mmol/g. In particular, the content of the acid group in the resin (A) is preferably 0.8 to 6.0 mmol/g, more preferably 1.2 to 5.0 mmol/g, still more preferably 1.6 to 4.0 mmol/g. When the content of the acid group is within this range, development proceeds well to form a pattern having a better shape and also having higher resolution.

The acid group is preferably, for example, a carboxyl group, a hydroxyl group, a phenolic hydroxyl group, a fluoroalcohol group (preferably a hexafluoroisopropanol group), a sulfonic group, a sulfonamide group, or an isopropanol group.

In the hexafluoroisopropanol group, one or more (preferably one or two) fluorine atoms may be substituted with groups other than fluorine atoms (e.g., alkoxycarbonyl groups). —C(CF₃)(OH)—CF₂— formed in this manner is also preferred as the acid group. One or more fluorine atoms may be substituted with groups other than fluorine atoms to form a ring including —C(CF₃)(OH)—CF₂—.

The repeating unit (A-1) having an acid group is preferably a repeating unit different from the above-described repeating unit having a structure in which a polar group is protected by a leaving group that leaves under the action of acid and a repeating unit (A-2) having a lactone group, a sultone group, or a carbonate group, which will be described later.

The repeating unit having an acid group may have a fluorine atom or an iodine atom.

As the repeating unit having an acid group, for example, a repeating unit having a phenolic hydroxyl group described in paragraphs 0089 to 0100 of JP2018-189758A is suitable for use.

When the resin (A) includes the repeating unit (A-1) having an acid group, a resist composition including this resin (A) is preferred for KrF exposure, EB exposure, or EUV exposure. In the case of such a form, the content of the repeating unit having an acid group in the resin (A) is preferably 30 to 100 mol %, more preferably 40 to 100 mol %, still more preferably 50 to 100 mol %, relative to all the repeating units in the resin (A). Repeating Unit (A-2) Having At Least One Selected from Group Consisting of Lactone Structure, Sultone Structure, Carbonate Structure, and Hydroxyadamantane Structure

The resin (A) may have a repeating unit (A-2) having at least one selected from the group consisting of a lactone structure, a carbonate structure, a sultone structure, and a hydroxyadamantane structure.

In a repeating unit having a lactone structure or a sultone structure, the lactone structure or the sultone structure is not particularly limited, but is preferably a five- to seven-membered lactone structure or a five- to seven-membered sultone structure, more preferably a five- to seven-membered lactone structure to which another ring structure is fused so as to form a bicyclo structure or a spiro structure or a five- to seven-membered sultone structure to which another ring structure is fused so as to form a bicyclo structure or a spiro structure.

Examples of the repeating unit having a lactone structure or a sultone structure include repeating units described in paragraphs 0094 to 0107 of WO2016/136354A.

The resin (A) may have a repeating unit having a carbonate structure. The carbonate structure is preferably a cyclic carbonate ester structure.

Examples of the repeating unit having a carbonate structure include repeating units described in paragraphs 0106 to 0108 of WO2019/054311A.

The resin (A) may have a repeating unit having a hydroxyadamantane structure. The repeating unit having a hydroxyadamantane structure is, for example, a repeating unit represented by general formula (AIIa) below.

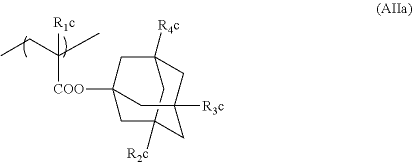

In general formula (AIIa), R₁c represents a hydrogen atom, a methyl group, a trifluoromethyl group, or a hydroxymethyl group. R₂c to R₄c each independently represent a hydrogen atom or a hydroxyl group. At least one of R₂c to R₄c represents a hydroxyl group. Preferably, one or two of R₂c to R₄c are hydroxyl groups, and the rest is a hydrogen atom.

### Repeating Unit Having Fluorine Atom or Iodine Atom

The resin (A) may have a repeating unit having a fluorine atom or an iodine atom.

Examples of the repeating unit having a fluorine atom or an iodine atom include repeating units described in paragraphs 0080 and 0081 of JP2019-045864A.

### Repeating Unit Having Photoacid Generating Group

The resin (A) may have, as a repeating unit other than the foregoing, a repeating unit having a group that generates an acid upon exposure to radiation.

Examples of the repeating unit having a group that generates an acid upon irradiation with a radiation include repeating units described in paragraphs 0092 to 0096 of JP2019-045864A.

### Repeating Unit Having Alkali-Soluble Group

The resin (A) may have a repeating unit having an alkali-soluble group.

The alkali-soluble group is, for example, a carboxyl group, a sulfonamide group, a sulfonylimide group, a bissulfonylimide group, or an aliphatic alcohol group substituted with an electron-withdrawing group at the α-position (e.g., a hexafluoroisopropanol group), preferably a carboxyl group. When the resin (A) has a repeating unit having an alkali-soluble group, higher resolution is provided in contact hole applications.

The repeating unit having an alkali-soluble group is, for example, a repeating unit in which an alkali-soluble group is directly bonded to the main chain of a resin, such as a repeating unit derived from acrylic acid or methacrylic acid, or a repeating unit in which an alkali-soluble group is bonded to the main chain of a resin through a linking group. The linking group may have a monocyclic or polycyclic hydrocarbon structure.

The repeating unit having an alkali-soluble group is preferably a repeating unit derived from acrylic acid or methacrylic acid.

### Repeating Unit Having Neither Acid-Decomposable Group Nor Polar Group

The resin (A) may further have a repeating unit having neither an acid-decomposable group nor a polar group. The repeating unit having neither an acid-decomposable group nor a polar group preferably has an alicyclic hydrocarbon structure.

Examples of the repeating unit having neither an acid-decomposable group nor a polar group include repeating units described in paragraphs 0236 and 0237 of US2016/0026083A and repeating units described in paragraph 0433 of US2016/0070167A.

The resin (A) may have, in addition to the foregoing repeating structural units, various repeating structural units for the purpose of adjusting, for example, dry etching resistance, standard developer suitability, substrate adhesiveness, resist profile, resolving power, heat resistance, and sensitivity.

### Properties of Resin (A)

In the resin (A), all the repeating units are preferably constituted by repeating units derived from (meth)acrylate monomers. In this case, any of resins in which all the repeating units are derived from methacrylate monomers, resins in which all the repeating units are derived from acrylate monomers, and resins in which all the repeating units are derived from methacrylate monomers and acrylate monomers can be used. The content of repeating units derived from acrylate monomers is preferably 50 mol % or less relative to all the repeating units in the resin (A).

When the resist composition is used for argon fluoride (ArF) exposure, the resin (A) preferably has substantially no aromatic groups from the viewpoint of ArF light transmittance. More specifically, the content of repeating units having aromatic groups is preferably 5 mol % or less, more preferably 3 mol % or less, ideally 0 mol %, relative to all the repeating units in the resin (A). That is, the resin (A) still more preferably has no repeating units having aromatic groups.

When the resist composition is used for ArF exposure, the resin (A) preferably has a monocyclic or polycyclic alicyclic hydrocarbon structure and preferably includes neither a fluorine atom nor a silicon atom.

When the resist composition is used for krypton fluoride (KrF) exposure, EB exposure, or EUV exposure, the resin (A) preferably has a repeating unit having an aromatic hydrocarbon group, more preferably has a repeating unit having a phenolic hydroxyl group.

Examples of the repeating unit having a phenolic hydroxyl group include the foregoing repeating units given as examples of the repeating unit (A-1) having an acid group and repeating units derived from hydroxystyrene (meth)acrylate.

When the resist composition is used for KrF exposure, EB exposure, or EUV exposure, the resin (A) also preferably has a repeating unit having a structure in which a hydrogen atom of a phenolic hydroxyl group is protected by a group (leaving group) that decomposes and leaves under the action of acid.

When the resist composition is used for KrF exposure, EB exposure, or EUV exposure, the content of the repeating unit having an aromatic hydrocarbon group in the resin (A) is preferably 30 to 100 mol %, more preferably 40 to 100 mol %, still more preferably 50 to 100 mol %, relative to all the repeating units in the resin (A).

The resin (A) can be synthesized according to a conventional method (e.g., radical polymerization).

The weight-average molecular weight (Mw) of the resin (A) is preferably 1,000 to 200,000, more preferably 3,000 to 20,000, still more preferably 5,000 to 15,000. When the weight-average molecular weight (Mw) of the resin (A) is 1,000 to 200,000, decreases in heat resistance and dry etching resistance can be prevented, and furthermore a decrease in developability and a decrease in film formability due to an increase in viscosity can be prevented. The weight-average molecular weight (Mw) of the resin (A) is a polystyrene equivalent value determined by GPC described above.

The dispersity (molecular weight distribution) of the resin (A) is typically 1 to 5, preferably 1 to 3, more preferably 1.1 to 2.0. Smaller dispersities provide higher resolutions and better resist profiles, and further provide patterns with smoother side walls and higher roughness performance.

In the resist composition, the content of the resin (A) is preferably 50 to 99.9 mass %, more preferably 60 to 99.0 mass %, relative to the total solid contents of the resist composition.

One resin (A) may be used alone, or two or more resins (A) may be used in combination.

In the present specification, the term “solid contents” means components that can constitute a resist film, excluding solvents. Even if the components are in the form of liquid, the components are regarded solid contents.

### Photoacid Generator (P)

The resist composition includes a photoacid generator (P). The photoacid generator (P) is not particularly limited as long as it is a compound that generates an acid upon exposure to radiation.

The photoacid generator (P) may be in the form of a low-molecular-weight compound or in the form of being incorporated into a part of a polymer. The form of a low-molecular-weight compound and the form of being incorporated into a part of a polymer may coexist.

When the photoacid generator (P) are in the form of a low-molecular-weight compound, its weight-average molecular weight (Mw) is preferably 3000 or less, more preferably 2000 or less, still more preferably 1000 or less.

When the photoacid generator (P) is in the form of being incorporated into a part of a polymer, it may be incorporated into a part of the resin (A) or incorporated into a resin different from the resin (A).

In the present invention, the photoacid generator (P) is preferably in the form of a low-molecular-weight compound.

The photoacid generator (P) is not particularly limited as long as it is a known photoacid generator, but is preferably a compound that generates organic acid upon exposure to radiation, more preferably a photoacid generator having, in its molecule, a fluorine atom or an iodine atom.

Examples of the organic acid includes sulfonic acids (e.g., aliphatic sulfonic acids, aromatic sulfonic acids, and camphorsulfonic acid), carboxylic acids (e.g., aliphatic carboxylic acids, aromatic carboxylic acids, and aralkyl carboxylic acids), carbonylsulfonylimidic acid, bis(alkylsulfonyl)imidic acids, and tris(alkylsulfonyl)methide acids.

The volume of an acid generated from the photoacid generator (P) is not particularly limited, but from the viewpoint of suppressing the diffusion of acid generated upon exposure to non-exposed portions to provide good resolution, it is preferably 240 Å3 or more, more preferably 305 Å3 or more, still more preferably 350 Å³ or more, particularly preferably 400 Å³ or more. From the viewpoint of sensitivity or solubility in applied solvent, the volume of an acid generated from the photoacid generator (P) is preferably 1500 Å3 or less, more preferably 1000 Å³ or less, still more preferably 700 Å³ or less.

The value of the volume is determined using “WinMOPAC” manufactured by Fujitsu Limited. In calculating the value of the volume, the chemical structure of each acid given as an example is first input; next, with this structure as an initial structure, the most stable conformation of each acid is determined by molecular force field calculation using Molecular Mechanics (MM) 3; and then molecular orbital calculation using Parameterized Model number (PM) 3 is performed on the most stable conformations, whereby the “accessible volume” of each acid can be calculated.

The structure of an acid generated from the photoacid generator (P) is not particularly limited, but from the viewpoint of suppressing the diffusion of the acid to provide good resolution, the interaction between the acid generated from the photoacid generator (P) and the resin (A) is preferably strong. From this viewpoint, when the acid generated from the photoacid generator (P) is an organic acid, the organic acid preferably further has a polar group in addition to organic acid groups such as a sulfonic group, a carboxylic group, a carbonylsulfonylimide acid group, a bissulfonylimide acid group, and a trissulfonylmethide acid group.

Examples of the polar group include an ether group, an ester group, an amide group, an acyl group, a sulfo group, a sulfonyloxy group, a sulfonamide group, a thioether group, a thioester group, a urea group, a carbonate group, a carbamate group, a hydroxyl group, and a mercapto group.

The number of polar groups of the acid generated is not particularly limited, preferably 1 or more, more preferably 2 or more. From the viewpoint of suppressing excessive development, the number of polar groups is preferably less than 6, more preferably less than 4.

In particular, for the effect of the present invention to be better produced, the photoacid generator (P) is preferably a photoacid generator constituted by an anionic moiety and a cationic moiety.

Examples of the photoacid generator (P) include photoacid generators described in paragraphs 0144 to 0173 of JP2019-045864A.

The content of the photoacid generator (P) is not particularly limited, but for the effect of the present invention to be better produced, it is preferably 5 to 50 mass %, more preferably 5 to 40 mass %, still more preferably 5 to 35 mass %, relative to the total solid contents of the resist composition.

One photoacid generator (P) may be used alone, or two or more photoacid generators (P) may be used in combination. When two or more photoacid generators (P) are used in combination, their total content is preferably within the above range.

### Acid Diffusion Control Agent (Q)

The resist composition may include an acid diffusion control agent (Q).

The acid diffusion control agent (Q) acts as a quencher that traps an acid generated from, for example, the photoacid generator (P) during exposure to suppress excessive acid generation that might cause the reaction of the acid-decomposable resin in unexposed portions. The acid diffusion control agent (Q) may be, for example, a basic compound (DA), a basic compound (DB) that becomes less basic or loses its basicity upon exposure to radiation, an onium salt (DC) that makes a relatively weak acid compared to the photoacid generator (P), a low-molecular-weight compound (DD) having a nitrogen atom and having a group that leaves under the action of acid, or an onium salt compound (DE) having a nitrogen atom in a cationic moiety.

In the resist composition, a known acid diffusion control agent can be appropriately used. For example, known compounds disclosed in paragraphs [0627] to [0664] of US2016/0070167A, paragraphs [0095] to [0187] of US2015/0004544A, paragraphs [0403] to [0423] of US2016/0237190A, and paragraphs [0259] to [0328] of US2016/0274458A are suitable for use as the acid diffusion control agent (Q).

Examples of the basic compound (DA) include repeating units described in paragraphs 0188 to 0208 of JP2019-045864A.

In the resist composition, the onium salt (DC) that makes a relatively weak acid compared to the photoacid generator (P) can be used as the acid diffusion control agent (Q).

When the photoacid generator (P) and the onium salt that generates a relatively weak acid compared to the acid generated from the photoacid generator (P) are used as a mixture, the acid generated from the photoacid generator (P) upon exposure to actinic rays or radiation collide with the onium salt having an unreacted weak-acid anion to cause salt exchange, which results in the release of the weak acid and the formation of an onium salt having a strong-acid anion. Since the strong acid is exchanged with the weak acid having a lower catalytic ability in this process, the acid is apparently deactivated, so that acid diffusion can be controlled.

Examples of the onium salt that makes a relatively weak acid compared to the photoacid generator (P) include onium salts described in paragraphs 0226 to 0233 of JP2019-070676A.

When the acid diffusion control agent (Q) is included in the resist composition, the content of the acid diffusion control agent (Q) (in the case of a plurality of acid diffusion control agents (Q), the total content thereof is preferably 0.1 to 10.0 mass %, more preferably 0.1 to 5.0 mass %, relative to the total solid contents of the resist composition.

In the resist composition, one acid diffusion control agent (Q) may be used alone, or two or more acid diffusion control agents (Q) may be used in combination.

### Hydrophobic Resin (E)

The resist composition may include, as a hydrophobic resin (E), a hydrophobic resin different from the resin (A).

The hydrophobic resin (E) is preferably designed so as to be localized on the surface of the resist film, but unlike surfactants, the hydrophobic resin (E) need not necessarily have, in its molecule, a hydrophilic group and need not contribute to homogeneously mixing a polar substance and a non-polar substance.

Adding the hydrophobic resin (E) has advantages such as control of static and dynamic contact angles at the surface of the resist film with respect to water and suppression of outgassing.

From the viewpoint of localization in the surface layer of the film, the hydrophobic resin (E) preferably has one or more, more preferably has two or more, of “a fluorine atom”, “a silicon atom”, and “a CH₃ partial structure included in a side chain moiety of the resin”. The hydrophobic resin (E) preferably has a hydrocarbon group having 5 or more carbon atoms. Such a group may be present in the main chain of the resin or may be present as a substituent in a side chain of the resin.

When the hydrophobic resin (E) includes a fluorine atom and/or a silicon atom, the fluorine atom and/or the silicon atom in the hydrophobic resin may be included in the main chain or a side chain of the resin.

When the hydrophobic resin (E) has a fluorine atom, the partial structure having a fluorine atom is preferably an alkyl group having a fluorine atom, a cycloalkyl group having a fluorine atom, or an aryl group having a fluorine atom.

The alkyl group having a fluorine atom (preferably having 1 to 10 carbon atoms, more preferably having 1 to 4 carbon atoms) is a linear or branched alkyl group in which at least one hydrogen atom is substituted with a fluorine atom, and may further have a substituent other than the fluorine atom.

The cycloalkyl group having a fluorine atom is a monocyclic or polycyclic cycloalkyl group in which at least one hydrogen atom is substituted with a fluorine atom, and may further have a substituent other than the fluorine atom.

The aryl group having a fluorine atom is, for example, a group derived by substituting at least one hydrogen atom of an aryl group such as a phenyl group or a naphthyl group with a fluorine atom, and may further have a substituent other than the fluorine atom.

Examples of the repeating unit having a fluorine atom or a silicon atom include those given as examples in paragraph 0519 of US2012/0251948A.

As described above, the hydrophobic resin (E) also preferably has a CH₃ partial structure in a side chain moiety.

Here, the CH₃ partial structure in a side chain moiety in the hydrophobic resin includes CH₃ moieties having an ethyl group, a propyl group, or the like.

On the other hand, methyl groups directly bonded to the main chain of the hydrophobic resin (E) (e.g., an α-methyl group of a repeating unit having a methacrylic acid structure) contributes little to the surface localization of the hydrophobic resin (E) under the influence of the main chain, and thus shall not be included in the CH₃ partial structure in the present invention.

For the hydrophobic resin (E), the description in paragraphs [0348] to [0415] of JP2014-010245A can be referred to, and the contents thereof are incorporated herein.

As the hydrophobic resin (E), resins described in JP2011-248019A, JP2010-175859A, and JP2012-032544A are also suitable for use.

When the resist composition includes the hydrophobic resin (E), the content of the hydrophobic resin (E) is preferably 0.01 to 20 mass %, more preferably 0.1 to 15 mass %, relative to the total solid contents of the resist composition.

### Solvent (F)

The resist composition may include a solvent (F).

When the resist composition is a radiation-sensitive resin composition for EUV, the solvent (F) preferably includes at least one of (M1) a propylene glycol monoalkyl ether carboxylate or (M2) at least one selected from the group consisting of propylene glycol monoalkyl ethers, lactates, acetates, alkoxypropionates, chain ketones, cyclic ketones, lactones, and alkylene carbonates. The solvent in this case may further include a component other than the components (M1) and (M2).

Combined use of the solvent including the component (M1) or (M2) and the resin (A) described above is preferred because the coating properties of the resist composition improves and a pattern with a smaller number of development defects can be formed.

When the resist composition is a radiation-sensitive resin composition for ArF, examples of the solvent (F) include organic solvents such as alkylene glycol monoalkyl ether carboxylates, alkylene glycol monoalkyl ethers, alkyl lactates, alkyl alkoxypropionates, cyclic lactones (preferably having 4 to 10 carbon atoms), monoketone compounds (preferably having 4 to 10 carbon atoms) optionally including a ring, alkylene carbonates, alkyl alkoxyacetates, and alkyl pyruvates.

The content of the solvent (F) in the resist composition is preferably determined such that the concentration of solid contents is 0.5 to 40 mass %.

In one embodiment of the resist composition, the concentration of solid contents is also preferably 10 mass % or more.

### Surfactant (H)

The resist composition may include a surfactant (H). The presence of the surfactant (H) enables formation of a pattern having higher adhesiveness and less development defects.

The surfactant (H) is preferably a fluorine-based and/or silicon-based surfactant.

Examples of the fluorine-based and/or silicon-based surfactant include surfactants described in paragraph [0276] of US2008/0248425A. Alternatively, EFTOP EF301 or EF303 (manufactured by Shin-Akita Kasei Co., Ltd.); FLUORAD FC430, 431, or 4430 (manufactured by Sumitomo 3M Limited); MEGAFACE F171, F173, F176, F189, F113, F110, F177, F120, or R08 (manufacturer by DIC Corporation); Surflon S-382, SC101, 102, 103, 104, 105, or 106 (manufacturer by AGC Inc.); Troysol S-366 (manufactured by Troy Chemical Industries, Inc.); GF-300 or GF-150 (manufactured by TOAGOSEI Co., Ltd.); SURFLON S-393 (manufactured by Seimi Chemical Co., Ltd.); EFTOP EF121, EF122A, EF122B, RF122C, EF125M, EF135M, EF351, EF352, EF801, EF802, or EF601 (manufactured by JEMCO); PF636, PF656, PF6320, or PF6520 (manufactured by OMNOVA Solutions Inc.); KH-20 (manufactured by Asahi Kasei Corporation); or FTX-204G, 208G, 218G, 230G, 204D, 208D, 212D, 218D, or 222D (manufactured by NEOS COMPANY LIMITED) may be used. A polysiloxane polymer KP-341 (manufactured by Shin-Etsu Chemical Co., Ltd.) can also be used as the silicon-based surfactant.

Instead of using a known surfactant as described above, the surfactant (H) may be synthesized using a fluoroaliphatic compound produced by telomerization (also referred to as a telomer method) or oligomerization (also referred to as an oligomer method). Specifically, a polymer including a fluoroaliphatic group derived from the fluoroaliphatic compound may be used as the surfactant (H). The fluoroaliphatic compound can be synthesized by, for example, a method described in JP2002-90991A.

The polymer having a fluoroaliphatic group is preferably a copolymer of a monomer having a fluoroaliphatic group and a (poly(oxyalkylene)) acrylate and/or a (poly(oxyalkylene)) methacrylate, and the copolymer may be a random copolymer or a block copolymer. The poly(oxyalkylene) group is, for example, a poly(oxyethylene) group, a poly(oxypropylene) group, or a poly(oxybutylene) group, and may be a unit having alkylenes with different chain lengths in one chain, such as a poly(oxyethylene/oxypropylene/oxyethylene block linkage) or a poly(oxyethylene/oxypropylene block linkage). Furthermore, the copolymer of a monomer having a fluoroaliphatic group and a (poly(oxyalkylene)) acrylate (or methacrylate) may not only be a binary copolymer but also be a ternary or higher copolymer resulting from simultaneous copolymerization of two or more different monomers having a fluoroaliphatic group, two or more different (poly(oxyalkylene)) acrylates (or methacrylates), etc.

Examples of commercially available surfactants include MEGAFACE F178, F-470, F-473, F-475, F-476, and F-472 (manufactured by DIC Corporation), copolymers of an acrylate (or methacrylate) having a C₆F₁₃ group and a (poly(oxyalkylene)) acrylate (or methacrylate), and copolymers of an acrylate (or methacrylate) having a C₃F₇ group, a (poly(oxyethylene)) acrylate (or methacrylate), and a (poly(oxypropylene)) acrylate (or methacrylate).

Surfactants other than fluorine-based and/or silicon-based surfactants described in paragraph [0280] of US2008/0248425A may also be used.

These surfactants (H) may be used alone or in combination of two or more.

The content of the surfactant (H) is preferably 0.0001 to 2 mass %, more preferably 0.0005 to 1 mass %, relative to the total solid contents of the resist composition.

### Other Additives

The resist composition may further include a crosslinking agent, an alkali-soluble resin, a dissolution-inhibiting compound, a dye, a plasticizer, a photosensitizer, a light absorbent, and/or a compound that enhances solubility in a developer.

### Method for Producing Resist Composition

A method for producing a resist composition according to the present invention will be described.

The method for producing a resist composition according to the present invention is not particularly limited as long as it has an inspection step of inspecting a resist composition according to the present inspection method.

The resist composition used in the inspection step may be prepared by any method, and may be, for example, a composition prepared by a composition preparation step described below or a composition obtained by transfer or the like.

The method for producing a resist composition preferably has a composition preparation step of preparing a resist composition and an inspection step of inspecting the resist composition prepared in the composition preparation step according to the present inspection method.

The present inspection method is as previously described, and preferred forms thereof are also the same.

The composition preparation step is not particularly limited as long as it is a step by which a resist composition for use in the inspection step can be produced.

The composition preparation step has, for example, a step of mixing various components such as an acid-decomposable resin and a photoacid generator, and preferably has a step of dissolving the components in a solvent and then filtering the solution through a filter. In this filter filtration, it is preferable to use a plurality of filters made of different materials (cycle filtration may also be used). More specifically, the filtration is preferably performed with a polyethylene filter with a pore size of 50 nm, a nylon filter with a pore size of 10 nm, and a polyethylene filter with a pore size of 3 to 5 nm connected in series. It is also preferable to perform cycle filtration twice or more. The filtration step can also reduce the content of metal atoms in the resist composition. The pressure difference between the filters is preferably as small as possible, and is preferably 0.1 MPa or less, more preferably 0.05 MPa or less, still more preferably 0.01 MPa or less.

When cycle filtration is performed using a filter in the production of the resist composition, for example, it is also preferable to perform cycle filtration twice or more using a polytetrafluoroethylene filter with a pore size of 50 nm.

The method for producing a resist composition according to the present invention can produce a composition that has been determined as “acceptable” in the inspection step. In other words, the production method according to the present invention can provide a resist composition that has been determined as “acceptable” in the inspection step and that exhibits high LWR performance after being stored for a predetermined period of time.

### Applications of Resist Composition

The resist composition inspected by the present inspection method is used for, for example, the formation of a resist film and the formation of a resist pattern. One non-limiting example of a method of forming a resist film using the resist composition is a method having a step of forming a resist film on a substrate using the resist composition.

The procedure of the method of forming a resist pattern using the resist composition is not particularly limited, but the method preferably has the following steps.
Step 1: a step of applying a resist composition onto a substrate to form a resist film
Step 2: a step of exposing the resist film
Step 3: a step of developing the exposed resist film using a first developer to form a pattern

Hereinafter, the procedure of each step will be described in detail.

### Step 1: Resist Film Formation Step

The step 1 is a step of applying a resist composition onto a substrate to form a resist film. The resist composition is as previously described.

The procedure of the step 1 and a resist film formed through the step 1, including preferred forms thereof, are the same as those of the step A1 of the above-described inspection method, and thus will not be elaborated here.

A topcoat may be formed on the resist film using a topcoat composition.

Preferably, the topcoat composition does not mix with the resist film and further can be uniformly applied on the resist film.

The thickness of the topcoat is preferably 10 to 200 nm, more preferably 20 to 100 nm.

The topcoat is not particularly limited, and a topcoat known in the art can be formed by a method known in the art. For example, the topcoat can be formed on the basis of the descriptions in paragraphs 0072 to 0082 of JP2014-059543A.

### Step 2: Exposure Step

The step 2 is a step of exposing the resist film formed in the step 1.

The exposure may be performed by, for example, irradiating the formed resist film with a radiation through a predetermined mask.

The step 2, including preferred formed thereof, is the same as the step B1 of the above-described inspection method, and thus will not be elaborated here.

### Step 3: Development Step

The step 3 is a step of developing the exposed resist film using a first developer to form a pattern.

Examples of methods of the development include immersing the substrate in a tank filled with the first developer for a certain period of time (dipping method), forming a puddle of the first developer on the surface of the substrate by the action of surface tension and leaving them to stand for a certain period of time to achieve development (puddling method), spraying the first developer onto the surface of the substrate (spraying method), and continuously ejecting the first developer, while scanning a jetting nozzle at a constant rate, onto the substrate rotating at a constant rate (dynamic dispensing method).

After the development step, a step of stopping the development while performing replacement with another solvent may be performed.

The developing time is not particularly limited as long as non-exposed portions or exposed portions to be dissolved are sufficiently dissolved, and is preferably 10 to 300 seconds, more preferably 20 to 120 seconds.

The temperature of the first developer is preferably 0° C. to 50° C., more preferably 15° C. to 35° C.

The first developer is as previously described.

### Other Steps

The pattern forming method preferably includes, after the step 3, a step of performing washing using a rinsing liquid.

The rinsing liquid for use in the rinsing step after the development step using a developer is, for example, pure water. An appropriate amount of surfactant may be added to the pure water.

An appropriate amount of surfactant may be added to the rinsing liquid.

The pattern formed may be used as a mask to perform etching treatment on the substrate. Specifically, the pattern formed in the step 3 may be used as a mask to process the substrate (or an underlayer film and the substrate), thereby forming a pattern on the substrate.

The method of processing the substrate (or an underlayer film and the substrate) is not particularly limited, but a preferred method is to perform dry etching on the substrate (or an underlayer film and the substrate) using the pattern formed in the step 3 as a mask, thereby forming a pattern on the substrate.

The dry etching may be single-step etching or multi-step etching. When the etching is performed in multiple steps, the etching treatment in each step may be the same or different.

The etching can be performed by any known method, and various conditions and the like are appropriately determined depending on, for example, the type or intended use of the substrate. For example, the etching can be performed in accordance with, for example, Proceedings of International Society for Optics and Photonics (Proc. of SPIE), Vol. 6924, 692420 (2008) and JP2009-267112A. The etching can also be performed in accordance with a method described in “Chapter 4, Etching” of “Semiconductor Process Textbook, 4th edition, issued in 2007, publisher: SEMI Japan”.

In particular, the dry etching is preferably oxygen plasma etching.

Various materials used in the formation of the resist pattern (e.g., solvents, developers, rinsing liquids, compositions for antireflection film formation, and compositions for topcoat formation) are preferably free of impurities such as metal. The content of impurities included in these materials is preferably 1 mass ppm or less, more preferably 10 mass ppb or less, still more preferably 100 mass ppt or less, particularly preferably 10 mass ppt or less, most preferably 1 mass ppt or less. Examples of metal impurities include Na, K, Ca, Fe, Cu, Mn, Mg, Al, Li, Cr, Ni, Sn, Ag, As, Au, Ba, Cd, Co, Mo, Zr, Pb, Ti, V, W, and Zn.

An example of a method of removing impurities such as metal from the various materials is filtration using a filter. The pore size of the filter is preferably 0.20 m or less, more preferably 0.05 m or less, still more preferably 0.01 m or less.

The material of the filter is preferably a fluorocarbon resin such as polytetrafluoroethylene (PTFE) or perfluoroalkoxyalkane (PFA), a polyolefin resin such as polypropylene or polyethylene, or a polyamide resin such as nylon 6 or nylon 66. The filter for use may be washed in advance with an organic solvent. In the filter filtration step, a plurality of filters or a plurality of types of filters may be used while being connected in series or in parallel. When a plurality of types of filters are used, filters having different pore sizes and/or made of different materials may be used in combination. The various materials may be filtered more than once, and the step of performing filtration more than once may be a cycle filtration step. The cycle filtration step is preferably performed by, for example, a method as disclosed in JP2002-062667A.

The filter is preferably a filter as disclosed in JP2016-201426A from which substances leach out in fewer amounts.

Instead of filter filtration, an adsorbent may be used to remove impurities, or filter filtration and an adsorbent may be used in combination. The adsorbent may be a known adsorbent, and, for example, an inorganic adsorbent such as silica gel or zeolite or an organic adsorbent such as activated carbon can be used. Examples of metal absorbents include those disclosed in JP2016-206500A.

Examples of methods of reducing the amount of impurities such as metal included in the various materials include selecting raw materials with low metal contents as raw materials constituting the various materials, performing filter filtration on raw materials constituting the various materials, and performing distillation under conditions where contamination is minimized by, for example, lining or coating the inside of an apparatus with a fluorocarbon resin or the like. Preferred conditions for the filter filtration performed on the raw materials constituting the various materials are the same as the conditions described above.

To prevent contamination by impurities, the various materials are preferably stored in containers described in, for example, US2015/0227049A, JP2015-123351A, and JP2017-013804A.

The various materials may be diluted, before use, with a solvent used in the resist composition.

### Electronic Device

The resist film and the resist pattern formed using the resist composition may be used to produce an electronic device.

Examples of the electronic device include, but are not limited to, electronic devices mounted on electric or electronic equipment (e.g., household appliances, office automation (OA), media-related equipment, optical equipment, and communication equipment).

### EXAMPLES

The present invention will now be described in more detail with reference to Examples. The materials, amounts, proportions, treatments, treatment sequences, etc. given in the following Examples may be changed as appropriate without departing from the spirit of the present invention. Thus, the scope of the present invention should not be construed as being limited by the Examples given below.

### First Example

### Various Components of Resist Composition

### Resin

The structure of resin P-1 shown in Table 1 is shown below.

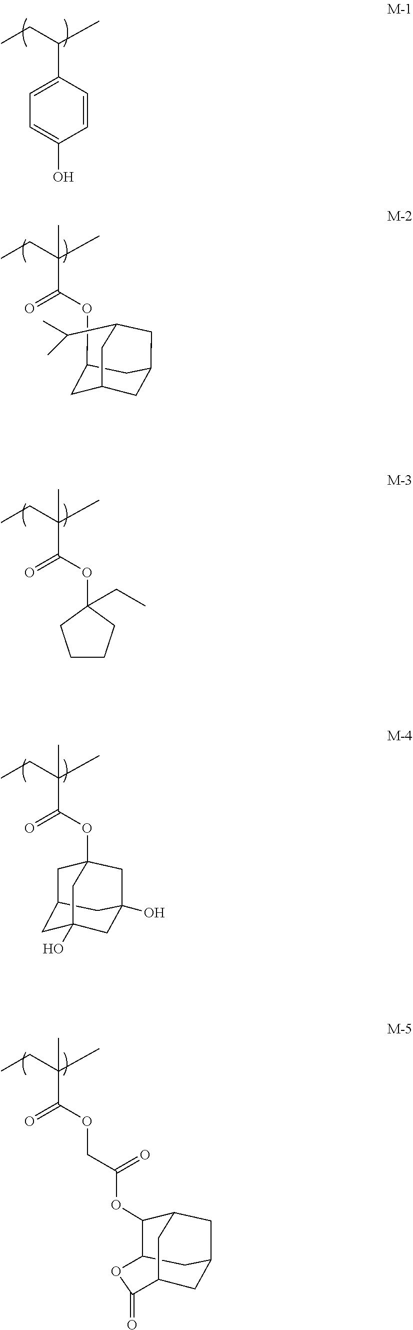

The weight-average molecular weight (Mw) and dispersity (Mw/Mn) of resin P-1 were measured by GPC (carrier: tetrahydrofuran (THF)) in terms of standard polystyrene amount. The compositional ratio (by mol %) of the resin was measured by ¹³C-NMR (nuclear magnetic resonance).

### Synthesis Example 1: Synthesis of Resin P-1

Under a stream of nitrogen, 194.3 g of cyclohexanone was placed in a three-necked flask and heated to 80° C. A solution of monomer M-1 (7.6 g), monomer M-2 (23.8 g), monomer M-3 (8.6 g), monomer M-4 (1.9 g), and monomer M-5 (8.3 g) corresponding to repeating units of resin P-1 above and a polymerization initiator V-601 (manufactured by FUJIFILM Wako Pure Chemical Corporation, 3.17 g) in cyclohexanone (105 g) was added dropwise into the three-necked flask over 6 hours. After completion of the dropwise addition, the solution was further allowed to react at 80° C. for 2 hours. After the reaction solution was allowed to cool, the reaction solution was added dropwise into a mixed solution of methanol:water over 20 minutes. Subsequently, powder precipitated as a result of the dropwise addition was separated by filtration and dried to obtain resin P-1 (31.6 g). The compositional ratio (molar ratio) of the repeating units determined by nuclear magnetic resonance (NMR) was 25/40/20/3/12. Resin P-1 obtained had a weight-average molecular weight (Mw) of 10,000 and a dispersity (Mw/Mn) of 1.6.

### Photoacid Generator

The structure of a photoacid generator (PAG-1) shown in Table 1 is shown below.

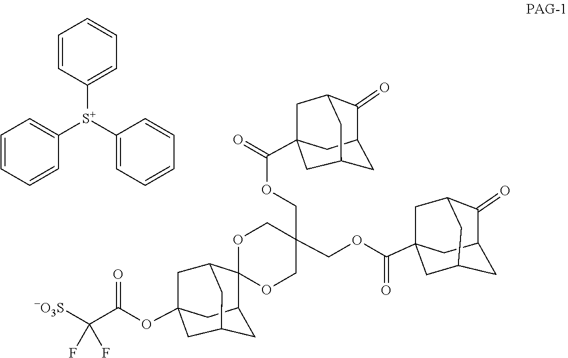

### Quencher

The structure of a quencher (Q-1) shown in Table 1 is shown below.

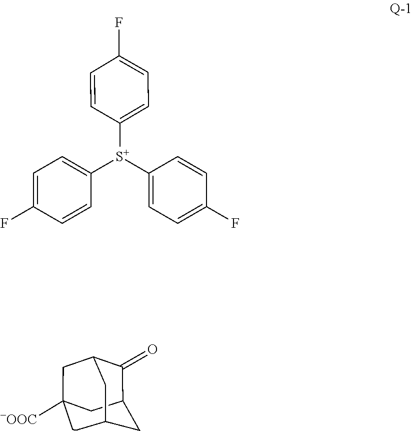

### Solvent

Solvents shown in Table 1 are shown below.
SL-1: propylene glycol monomethyl ether acetate (PGMEA)
SL-2: propylene glycol monomethyl ether (PGME)
SL-3: γ-butyrolactone

### Preparation of Resist Composition

Resin P-1, photoacid generator PAG-1, quencher Q-1, and solvents SL-1, SL-2, and SL-3 were mixed so as to give a composition shown in Table 1 below. The resulting mixed solution was then filtered through a polyethylene filter having a pore size of 0.03 m to prepare a resin composition (resist composition R1). Resist composition R1 thus obtained was used to perform the measurement and determination described later.

TABLE 1
Table 1

| | Resin | | | | Photoacid | | | | | |
|---|---|---|---|---|---|---|---|---|---|---|
| Resist | | Monomer type | | | generator | | Quencher | | Solid | Solvent |
| compo- | | (compositional | | Amount | | Amount | | Amount | contents | (mass |
| sition | Type | ratio (mol %)) | Mw | [%] | Type | [%] | Type | [%] | [%] | ratio (%)) |
| R1 | P-1 | M-1/M-2/M-3/ | 10,000 | 70 | PAG-1 | 25 | Q-1 | 5 | 1.9 | SL-1/SL-2/ |
| | | M-4/M-5 | | | | | | | | SL-3 |
| | | (25/40/20/3/12) | | | | | | | | (72/27/1) |

### Measurement of Resist Composition

Resist composition R1 was produced 12 times according to the production method described above, and lot numbers were given in the order of production. For each production lot, the LWR performance was measured by the following method using the following first developer one day and one month after the production of the resist. In addition, for each production lot, various inspections were performed using the following first developer and the following second developer to acquire measurement data.

The first developer and the second developer used were as follows.
First developer: mixed solution of butyl acetate and undecane (butyl acetate:undecane=90:10 (mass ratio))
Second developer: butyl acetate

### Measurement of LWR Performance Using First Developer

### Formation of Resist Pattern

A composition for underlayer film formation SHB-A940 (manufactured by Shin-Etsu Chemical Co., Ltd.) was applied onto a silicon wafer and baked at 205° C. for 60 seconds to form an underlayer film having a thickness of 20 nm. Resist composition R1 was applied onto the underlayer film and baked at 100° C. for 60 seconds to form a resist film having a thickness of 35 nm. Thus, a resist-film-carrying silicon wafer was produced.

In this Example, a silicon wafer having a diameter of 12 inches was used.

The resist-film-carrying silicon wafer obtained by the above procedure was subjected to pattern exposure using an EUV scanner NXE3300 (NA, 0.33; a, 0.9/0.7; dipole illumination) manufactured by ASML. As a reticle, a mask having a line width of 30 nm and a line-to-space ratio of 1:1 in terms of on-wafer dimensions was used. Thereafter, baking (post exposure baking; PEB) was performed at 110° C. for 60 seconds. The pattern-exposed resist-film-carrying silicon wafer was immersed in the first developer and subjected to puddle development for 30 seconds, and then the resist-film-carrying silicon wafer was taken out of the first developer and rotated at a rotation speed of 4000 rpm for 30 seconds, thereby obtaining a line-and-space pattern with a pitch of 60 nm.

### Measurement of Optimum Exposure Dose

In the above production of a line-and-space pattern using the first developer, the exposure dose in the pattern exposure was varied, and the line width of a pattern produced at each exposure dose was measured using a critical dimension scanning electron microscope (SEM: “CG-4100” manufactured by Hitachi High-Technologies Corporation). The exposure dose at which the measured line width was 30 nm was determined and employed as the optimum exposure dose (mJ/cm²).

### Measurement of LWR Performance

In the resist pattern with a line and space resolved at the optimum exposure dose, the line width was observed using an SEM at randomly selected 160 points, and the variation in measurement was evaluated by 36. Smaller values indicate better performance.

The measurement of LWR performance by the above method was performed on resist patterns formed using resist compositions R1 one day after the production and one month after the production. The measurement results are shown in Table 2 given later.

### Measurement of Pattern Line Width (Steps A1, B1, C1, and X1a)

### EUV Exposure

A composition for underlayer film formation SHB-A940 (manufactured by Shin-Etsu Chemical Co., Ltd.) was applied onto a silicon wafer and baked at 205° C. for 60 seconds to form an underlayer film having a thickness of 20 nm. Resist composition R1 was applied onto the underlayer film and baked at 100° C. for 60 seconds to form a resist film having a thickness of 35 nm.

The resist-film-carrying silicon wafer obtained by the above procedure was subjected to pattern exposure at an exposure dose of 30 mJ/cm² using an EUV scanner NXE3300 (NA, 0.33; σ, 0.9/0.7; dipole illumination) manufactured by ASML. As a reticle, a mask having a line width of 30 nm and a line-to-space ratio of 1:1 in terms of on-wafer dimensions was used. Thereafter, baking (PEB) was performed at 110° C. for 60 seconds.

The pattern-exposed resist-film-carrying silicon wafer was immersed in the first developer or the second developer and subjected to puddle development for 30 seconds, and then the resist-film-carrying silicon wafer was taken out of the developer and rotated at a rotation speed of 4000 rpm for 30 seconds, thereby obtaining a line-and-space pattern with a pitch of 60 nm.

The line width of the pattern obtained was measured using an SEM (“CG-4100” manufactured by Hitachi High-Technologies Corporation) to acquire measurement data.

### KrF Exposure

A composition for organic antireflection film formation DUV44 (manufactured by Brewer Science, Inc.) was applied onto a silicon wafer, and the coating film was baked at 205° C. for 60 seconds. Thus, an antireflection film having a thickness of 60 nm was formed on the silicon wafer. Resist composition R1 was applied onto the antireflection film and baked at 100° C. for 60 seconds to form a resist film having a thickness of 35 nm.

The resist-film-carrying silicon wafer obtained by the above procedure was subjected to pattern exposure at an exposure dose of 80 mJ/cm² using a KrF excimer laser scanner (manufactured by ASML, PAS5500/850) (NA, 0.80). As a reticle, a 6% halftone mask having a line width of 100 nm and a line-to-space ratio of 1:1 in terms of on-wafer dimensions was used. Thereafter, baking (PEB) was performed at 110° C. for 60 seconds.

The pattern-exposed resist-film-carrying silicon wafer was subjected to puddle development in the first developer or the second developer for 30 seconds, and then the resist-film-carrying silicon wafer was taken out of the developer and rotated at a rotation speed of 4000 rpm for 30 seconds, thereby obtaining a line-and-space pattern with a pitch of 200 nm.

The line width of the pattern obtained was measured using an SEM (“CG-4100” manufactured by Hitachi High-Technologies Corporation) to acquire measurement data.

### ArF Exposure

A composition for organic antireflection film formation ARC29SR (manufactured by Nissan Chemical Corporation) was applied onto a silicon wafer, and the coating film was baked at 205° C. for 60 seconds. Thus, an antireflection film having a thickness of 90 nm was formed on the silicon wafer. Resist composition R1 was applied onto the antireflection film and baked at 100° C. for 60 seconds to form a resist film having a thickness of 35 nm.

The resist-film-carrying silicon wafer obtained by the above procedure was subjected to pattern exposure at an exposure dose of 40 mJ/cm² using an ArF excimer laser liquid-immersion scanner (XT1700i manufactured by ASML; NA, 1.20; Dipole; outer sigma, 0.900; inner sigma, 0.700; Y deflection). As a reticle, a 6% halftone mask having a line width of 75 nm and a line-to-space ratio of 1:1 in terms of on-wafer dimensions was used.

Thereafter, baking (PEB) was performed at 110° C. for 60 seconds. The pattern-exposed resist-film-carrying silicon wafer was subjected to puddle development in the first developer or the second developer for 30 seconds, and then the resist-film-carrying silicon wafer was taken out of the developer and rotated at a rotation speed of 4000 rpm for 30 seconds, thereby obtaining a line-and-space pattern with a pitch of 150 nm.

The line width of the pattern obtained was measured using an SEM (“CG-4100” manufactured by Hitachi High-Technologies Corporation) to acquire measurement data.

### EB Exposure

Using an ACTM (manufactured by Tokyo Electron Ltd.), a composition for antireflection film formation DUV44 (manufactured by Brewer Science, Inc.) was applied onto a 152-mm square mask blank having a Cr outermost surface and baked at 205° C. for 60 seconds to form an underlayer film having a thickness of 60 nm. Resist composition R1 was applied onto the underlayer film and baked at 100° C. for 60 seconds to form a resist film having a thickness of 35 nm. Thus, a resist-film-carrying mask blank was formed.

The resist-film-carrying mask blank obtained by the above procedure was subjected to pattern exposure at an exposure dose of 100 μC/cm² using an electron beam exposure device (EBM-9000 manufactured by NuFlare Technology Inc.; acceleration voltage, 50 kV). As a reticle, a 6% halftone mask having a line width of 75 nm and a line-to-space ratio of 1:1 in terms of on-wafer dimensions was used. The patterning was performed so as to form a line and space having a line width of 50 nm and a ratio of 1:1 in terms of on-blank dimensions.

Thereafter, baking (PEB) was performed at 110° C. for 60 seconds. The pattern-exposed resist-film-carrying silicon wafer was subjected to puddle development in the first developer or the second developer for 30 seconds, and then the resist-film-carrying silicon wafer was taken out of the developer and rotated at a rotation speed of 4000 rpm for 30 seconds, thereby obtaining a line-and-space pattern with a pitch of 100 nm.

The line width of the pattern obtained was measured using an SEM (“CG-4100” manufactured by Hitachi High-Technologies Corporation) to acquire measurement data.

### Measurement of Pattern Defect (Steps A1, B1, C1, and X1b)

### EUV Exposure

According to the method described in “EUV Exposure” of “Measurement of Pattern Line Width” above, a line-and-space pattern with a pitch of 60 nm was formed on a silicon wafer using resist composition R1.

The pattern obtained was subjected to defect inspection using a defect inspection apparatus KLA2925 manufactured by KLA-Tencor Corporation to measure the number of defects (defect counts) present on the surface of the silicon wafer.

### KrF Exposure

According to the method described in “KrF Exposure” of “Measurement of Pattern Line Width” above, a line-and-space pattern with a pitch of 200 nm was formed on a silicon wafer using resist composition R1.

The pattern obtained was subjected to defect inspection using a defect inspection apparatus KLA2925 manufactured by KLA-Tencor Corporation to measure the number of defects (defect counts) present on the surface of the silicon wafer.

### ArF Exposure

According to the method described in “ArF Exposure” of “Measurement of Pattern Line Width” above, a line-and-space pattern with a pitch of 150 nm was formed on a silicon wafer using resist composition R1.

The pattern obtained was subjected to defect inspection using a defect inspection apparatus KLA2925 manufactured by KLA-Tencor Corporation to measure the number of defects (defect counts) present on the surface of the silicon wafer.

### Measurement of Minimum Resist Film Dissolution Rate (Rmin) (Steps A1, B1, C1, and X1c)

### EUV Exposure

A composition for underlayer film formation SHB-A940 (manufactured by Shin-Etsu Chemical Co., Ltd.) was applied onto a silicon wafer and baked at 205° C. for 60 seconds to form an underlayer film having a thickness of 20 nm. Resist composition R1 was applied onto the underlayer film and baked at 100° C. for 60 seconds to form a resist film having a thickness of 35 nm.

The resist-film-carrying silicon wafer obtained by the above procedure was subjected to open-frame exposure at an exposure dose of 30 mJ/cm² using an EUV scanner NXE3300 (NA, 0.33) manufactured by ASML. Thereafter, baking (PEB) was performed at 110° C. for 60 seconds, and a film thickness (FT1) of the post-PEB resist film was measured using an optical coherence-type film thickness meter (“VM-3200 (product name)”, manufactured by SCREEN Semiconductor Solutions Co., Ltd.).

Subsequently, the exposed resist-film-carrying silicon wafer was immersed in the first developer or the second developer and subjected to puddle development for 30 seconds, and then the resist-film-carrying silicon wafer was taken out of the developer and rotated at a rotation speed of 4000 rpm for 30 seconds. Using the optical coherence-type film thickness meter again, a film thickness (FT2) of the post-development resist film on the silicon wafer was measured. A minimum resist film dissolution rate (Rmin) was calculated from the film thicknesses FT1 and FT2 using the following formula to acquire measurement data.

Formula: R min=(FT1−FT2)/30 (nm/s)

### KrF Exposure

A composition for organic antireflection film formation DUV44 (manufactured by Brewer Science, Inc.) was applied onto a silicon wafer, and the coating film was baked at 205° C. for 60 seconds to form an underlayer film having a thickness of 60 nm. Resist composition R1 was applied onto the underlayer film and baked at 100° C. for 60 seconds to form a resist film having a thickness of 35 nm.

The resist-film-carrying silicon wafer obtained by the above procedure was subjected to open-frame exposure at an exposure dose of 100 mJ/cm² using a KrF excimer laser scanner (manufactured by ASML, PAS5500/850) (NA, 0.80). Thereafter, baking (PEB) was performed at 110° C. for 60 seconds, and a film thickness (FT1) of the post-PEB resist film was measured using an optical coherence-type film thickness meter.

Subsequently, the exposed resist-film-carrying silicon wafer was subjected to puddle development in the first developer or the second developer for 30 seconds, and then the resist-film-carrying silicon wafer was taken out of the developer and rotated at a rotation speed of 4000 rpm for 30 seconds. Using the optical coherence-type film thickness meter again, a film thickness (FT2) of the post-development resist film on the silicon wafer was measured.

A minimum resist film dissolution rate (Rmin) was calculated from the film thicknesses FT1 and FT2 using the following formula to acquire measurement data.

Formula: R min=(FT1−FT2)/30 (nm/s)

### ArF Exposure

A composition for organic antireflection film formation ARC29SR (manufactured by Nissan Chemical Corporation) was applied onto a silicon wafer, and the coating film was baked at 205° C. for 60 seconds. Thus, an underlayer film having a thickness of 90 nm was formed on the silicon wafer. Resist composition R1 was applied onto the underlayer film and baked at 100° C. for 60 seconds to form a resist film having a thickness of 35 nm. The resist-film-carrying silicon wafer obtained by the above procedure was subjected to open-frame exposure at an exposure dose of 40 mJ/cm² using an ArF excimer laser liquid-immersion scanner (XT1700i manufactured by ASML; NA, 1.20). Thereafter, baking (PEB) was performed at 110° C. for 60 seconds, and a film thickness (FT1) of the post-PEB resist film was measured using an optical coherence-type film thickness meter.

Subsequently, the exposed resist-film-carrying silicon wafer was subjected to puddle development in the first developer or the second developer for 30 seconds, and then the resist-film-carrying silicon wafer was taken out of the developer and rotated at a rotation speed of 4000 rpm for 30 seconds. Using the optical coherence-type film thickness meter again, a film thickness (FT2) of the post-development resist film on the silicon wafer was measured.

A minimum resist film dissolution rate (Rmin) was calculated from the film thicknesses FT1 and FT2 using the following formula to acquire measurement data.

Formula: R min=(FT1−FT2)/30 (nm/s)

Measurement of Defect on Substrate after Resist Film Removal (Steps A2, C2, and X2a)

Resist composition R1 was applied onto a silicon wafer and baked at 100° C. for 60 seconds to form a resist film having a thickness of 35 nm.

Subsequently, the first developer or the second developer was applied (ejected at a flow rate of 1 mL/S for 10 seconds) to the resist-film-carrying silicon wafer to remove the resist film.

The silicon wafer after the removal treatment was subjected to defect inspection using a dark-field defect inspection apparatus SP5 manufactured by KLA-Tencor Corporation to measure the number of defects (defect counts) having a size of 19 nm or more present on the surface of the silicon wafer.

### Measurement of Maximum Resist Film Dissolution Rate (Rmax) (Steps A2, C2, and X2b)

A maximum resist film dissolution rate (Rmax) was measured using the quartz crystal microbalance technique (QCM technique).

More specifically, resist composition R1 was applied onto a QCM electrode and baked at 100° C. for 60 seconds to form a resist film having a thickness of 35 nm. Thus, a resist-film-carrying QCM electrode was produced.

Subsequently, the resist-film-carrying QCM electrode was brought into contact with the first developer or the second developer to remove the resist film. During this period of time, the change in frequency of oscillation of a quartz oscillator was monitored to measure the time (T) required from the start of contact with the developer until the change in frequency of oscillation became constant.

The maximum resist film dissolution rate (Rmax) was calculated from the measured time (T) using the following formula to acquire measurement data.

Formula: R max=(35)/T (nm/s)

For all the twelve production lots, measurement data in the cases of the first developer and the second developer were acquired by the above method. The above-described measurement (the acquisition of various measurement data) was performed using a resist composition one day after the production. The measurement data acquired are shown in Table 2.

TABLE 2
Table 2

| | LWR | | | | | | | | | | | | | | |
|---|---|---|---|---|---|---|---|---|---|---|---|---|---|---|---|
| | performance | | | | | | | | | | | | | | |
| | in the case | | | | | | | | | | | | | Second embodiment | |
| | of first | | | First embodiment | | | | | | | | | | Number of | |
| | developer [nm] | | | | | | | Pattern defect | | | | | | defects on | |
| Lot | After | After 1 | Developer | Pattern line width [nm] | | | | [number/wafer] | | | Rmin [nm/s] | | | substrate | Rmax |
| No. | 1 day | month | used | EUV | KrF | ArF | EB | EUV | KrF | ArF | EUV | KrF | ArF | [number/wafer] | [nm/s] |
| 1 | 2.88 | 2.94 | second | 30.0 | 101.4 | 75.6 | 50.5 | 23 | 49 | 45 | 0.194 | 0.191 | 0.198 | 10 | 58.0 |
| | | | first | 31.8 | 105.2 | 80.8 | 52.8 | 16 | 33 | 30 | 0.123 | 0.130 | 0.130 | 12 | 20.1 |
| 2 | 2.98 | 2.98 | second | 30.6 | 102.3 | 75.2 | 49.8 | 12 | 39 | 9 | 0.190 | 0.190 | 0.196 | 48 | 61.4 |
| | | | first | 31.5 | 103.4 | 79.0 | 50.6 | 7 | 22 | 48 | 0.124 | 0.127 | 0.125 | 7 | 20.8 |
| 3 | 2.86 | 2.91 | second | 29.7 | 102.9 | 76.9 | 49.8 | 20 | 32 | 29 | 0.205 | 0.202 | 0.210 | 25 | 61.2 |
| | | | first | 30.7 | 108.5 | 79.6 | 52.2 | 6 | 20 | 37 | 0.124 | 0.126 | 0.126 | 23 | 20.2 |
| 4 | 2.91 | 2.97 | second | 30.1 | 98.3 | 77.0 | 50.1 | 42 | 22 | 37 | 0.192 | 0.189 | 0.199 | 23 | 61.8 |
| | | | first | 30.6 | 103.9 | 80.2 | 52.9 | 35 | 28 | 16 | 0.129 | 0.130 | 0.134 | 17 | 20.5 |
| 5 | 2.88 | 2.92 | second | 29.3 | 99.1 | 73.0 | 51.8 | 30 | 7 | 25 | 0.196 | 0.206 | 0.198 | 22 | 62.2 |
| | | | first | 30.3 | 107.2 | 78.8 | 50.5 | 11 | 34 | 13 | 0.124 | 0.126 | 0.129 | 20 | 20.8 |
| 6 | 2.99 | 2.96 | second | 30.4 | 96.7 | 72.8 | 50.2 | 46 | 46 | 40 | 0.194 | 0.207 | 0.208 | 18 | 58.6 |
| | | | first | 32.3 | 103.3 | 80.8 | 51.8 | 33 | 12 | 31 | 0.127 | 0.125 | 0.127 | 27 | 20.5 |
| 7 | 2.94 | 2.88 | second | 30.4 | 101.6 | 73.9 | 48.9 | 20 | 33 | 37 | 0.192 | 0.204 | 0.195 | 17 | 60.3 |
| | | | first | 31.0 | 102.8 | 77.4 | 52.5 | 20 | 34 | 33 | 0.129 | 0.131 | 0.131 | 16 | 19.4 |
| 8 | 2.95 | 2.92 | second | 29.8 | 102.1 | 72.7 | 51.0 | 10 | 5 | 18 | 0.194 | 0.193 | 0.209 | 31 | 60.3 |
| | | | first | 30.4 | 105.5 | 80.4 | 54.0 | 40 | 29 | 43 | 0.123 | 0.132 | 0.129 | 28 | 19.4 |
| 9 | 2.94 | 2.96 | second | 31.0 | 103.0 | 75.3 | 48.8 | 47 | 23 | 41 | 0.191 | 0.200 | 0.202 | 6 | 58.2 |
| | | | first | 31.0 | 103.8 | 80.7 | 51.8 | 43 | 19 | 48 | 0.127 | 0.124 | 0.134 | 12 | 20.1 |
| 10 | 2.87 | 2.99 | second | 30.0 | 101.4 | 73.2 | 50.1 | 33 | 29 | 12 | 0.201 | 0.199 | 0.201 | 9 | 60.2 |
| | | | first | 30.7 | 108.2 | 80.6 | 51.4 | 23 | 31 | 14 | 0.129 | 0.127 | 0.131 | 21 | 19.7 |
| 11 | 2.97 | 2.95 | second | 30.6 | 103.0 | 75.6 | 51.2 | 48 | 31 | 47 | 0.199 | 0.199 | 0.197 | 15 | 57.8 |
| | | | first | 30.9 | 107.5 | 79.1 | 52.6 | 44 | 48 | 15 | 0.129 | 0.126 | 0.135 | 48 | 19.6 |
| 12 | 2.99 | 3.56 | second | 28.4 | 95.2 | 70.3 | 47.4 | 102 | 105 | 110 | 0.222 | 0.223 | 0.224 | 105 | 66.0 |
| | | | first | 30.7 | 103.8 | 77.8 | 51.4 | 38 | 13 | 20 | 0.122 | 0.131 | 0.133 | 39 | 20.6 |

### Determination of Resist Composition (Step Y1 or Y2)

As shown in Table 2, for the production lot No. 11, the LWR performance in the case where the first developer was used was hardly changed after one month from the production, whereas for the production lot No. 12, the LWR performance in the case where the first developer was used lowered by 10% or more after one month from the production.

Thus, in Examples and Comparative Examples, the following determinations were made using measurement data acquired from the production lots No. 11 and No. 12 as determination target lots. When only the production lot No. 12 was determined as unacceptable, the determination method was evaluated as valid, and when the production lots No. 11 and No. 12 were determined as acceptable or when the production lots No. 11 and No. 12 were determined as unacceptable, the determination method was evaluated as invalid.

### Example 1 and Comparative Example 1: Determination Using Measurement Data of Pattern Line Width (EUV Exposure)

On the basis of the data shown in Table 2, the resist compositions of the lot No. 11 and the lot No. 12 to be determined were subjected to determinations by determination methods 1-1 to 1-3 using the measurement data of the pattern line width of the resist patterns formed by EUV exposure, and the validity of the determinations was evaluated.

As reference values, the measurement data of the initial lot (lot No. 1) was used in the determination method 1-1, the measurement data of the immediately preceding lot was used in the determination method 1-2, and the average value of the measurement data of the immediately preceding five lots (5-lot average) was used in the determination method 1-3. The allowable range in each determination method was defined as “the difference between the measurement data and the reference value is less than ±5% (<±5%) of the reference value”. The results are summarized in Table 3.

TABLE 3
Table 3

| | | | Example 1 | | Comparative Example 1 | |
|---|---|---|---|---|---|---|
| Resist composition | | | R1 | | R1 | |
| Determination target lot | | | 11 | 12 | 11 | 12 |
| LWR performance in the | | After 1 day | 2.97 | 2.99 | 2.97 | 2.99 |
| case of first developer (nm) | | After 1 month | 2.95 | 3.56 | 2.95 | 3.56 |
| Measurement data used | | | pattern line width (EUV exposure) | | | |
| Developer used | | | second developer | | first developer | |
| Determination | Reference | Initial lot | 30.0 | 30.0 | 31.8 | 31.8 |
| method 1-1 | value (nm) | | | | | |
| | Measurement data (nm) | | 30.6 | 28.4 | 30.9 | 30.7 |
| | Difference from | | 2.0% | −5.3% | −2.8% | −3.5% |
| | reference value (%) | | | | | |
| | Allowable range | | <±5% | <±5% | <±5% | <±5% |
| | Determination result | | acceptable | unacceptable | acceptable | acceptable |
| Determination | Reference | Immediately | 30.0 | 30.6 | 30.7 | 30.9 |
| method 1-2 | value (nm) | preceding lot | | | | |
| | Measurement data (nm) | | 30.6 | 28.4 | 30.9 | 30.7 |
| | Difference from | | 2.0% | −7.2% | 0.7% | −0.6% |
| | reference value (%) | | | | | |
| | Allowable range | | <±5% | <±5% | <±5% | <±5% |
| | Determination result | | acceptable | unacceptable | acceptable | acceptable |
| Determination | Reference | 5-lot average | 30.3 | 30.4 | 31.1 | 30.8 |
| method 1-3 | value (nm) | | | | | |

| | | | | |
|---|---|---|---|---|
| Measurement data (nm) | 30.6 | 28.4 | 30.9 | 30.7 |
| Difference from | 0.9% | −6.5% | −0.6% | −0.3% |
| reference value (%) | | | | |
| Allowable range | <±5% | <±5% | <±5% | <±5% |
| Determination result | acceptable | unacceptable | acceptable | acceptable |

| | | |
|---|---|---|
| Validity of determination methods | valid | invalid |

From the results shown in Table 3, it has been found that in Example 1 in which the determinations were performed using the measurement data acquired using the second developer, only the lot No. 12 one month after the production has been determined as unacceptable in each of the determination methods 1-1 to 1-3, and thus the determination methods are valid. On the other hand, it has been found that in Comparative Example 1 in which the determinations were performed using the measurement data acquired using the first developer, the lot No. 12 one month after the production has also been determined as acceptable in each of the determination methods 1-1 to 1-3, and thus the determination methods are invalid.

### Example 2 and Comparative Example 2: Determination Using Measurement Data of Pattern Line Width (KrF Exposure)

On the basis of the data shown in Table 2, the resist compositions of the lot No. 11 and the lot No. 12 to be determined were subjected to determinations by determination methods 2-1 to 2-3 using the measurement data of the pattern line width of the resist patterns formed by KrF exposure, and the validity of the determinations was evaluated.

As reference values, the measurement data of the initial lot (lot No. 1) was used in the determination method 2-1, the measurement data of the immediately preceding lot was used in the determination method 2-2, and the average value of the measurement data of the immediately preceding five lots (5-lot average) was used in the determination method 2-3. The allowable range in each determination method was defined as “the difference between the measurement data and the reference value is less than +500 (5) of the reference value”. The results are summarized in Table 4.

TABLE 4
Table 4

| | | | Example 2 | | Comparative Example 2 | |
|---|---|---|---|---|---|---|
| Resist composition | | | R1 | | R1 | |
| Determination target lot | | | 11 | 12 | 11 | 12 |
| LWR performance in the | | After 1 day | 2.97 | 2.99 | 2.97 | 2.99 |
| case of first developer (nm) | | After 1 month | 2.95 | 3.56 | 2.95 | 3.56 |
| Measurement data used | | | pattern line width (KrF exposure) | | | |
| Developer used | | | second developer | | first developer | |
| Determination | Reference | Initial lot | 101.4 | 101.4 | 105.2 | 105.2 |
| method 2-1 | value (nm) | | | | | |
| | Measurement data (nm) | | 103.0 | 95.2 | 107.5 | 103.8 |
| | Difference from | | 1.6% | −6.1% | 2.2% | −1.3% |
| | reference value (%) | | | | | |
| | Allowable range | | <±5% | <±5% | <±5% | <±5% |
| | Determination result | | acceptable | unacceptable | acceptable | acceptable |
| Determination | Reference | Immediately | 101.4 | 103.0 | 108.2 | 107.5 |
| method 2-2 | value (nm) | preceding lot | | | | |
| | Measurement data (nm) | | 103.0 | 95.2 | 107.5 | 103.8 |
| | Difference from | | 1.6% | −7.6% | −0.6% | −3.4% |
| | reference value (%) | | | | | |
| | Allowable range | | <±5% | <±5% | <±5% | <±5% |
| | Determination result | | acceptable | unacceptable | acceptable | acceptable |
| Determination | Reference | 5-lot average | 102.2 | 100.9 | 105.6 | 105.8 |
| method 2-3 | value (nm) | | | | | |

| | | | | |
|---|---|---|---|---|
| Measurement data (nm) | 103.0 | 95.2 | 107.5 | 103.8 |
| Difference from | 0.8% | −5.7% | 1.8% | −1.9% |
| reference value (%) | | | | |
| Allowable range | <±5% | <±5% | <±5% | <±5% |
| Determination result | acceptable | unacceptable | acceptable | acceptable |

| | | |
|---|---|---|
| Validity of determination methods | valid | invalid |

From the results shown in Table 4, it has been found that in Example 2 in which the determinations were performed using the measurement data acquired using the second developer, only the lot No. 12 one month after the production has been determined as unacceptable in each of the determination methods 2-1 to 2-3, and thus the determination methods are valid. On the other hand, it has been found that in Comparative Example 2 in which the determinations were performed using the measurement data acquired using the first developer, the lot No. 12 one month after the production has also been determined as acceptable in each of the determination methods 2-1 to 2-3, and thus the determination methods are invalid.

### Example 3 and Comparative Example 3: Determination Using Measurement Data of Pattern Line Width (ArF Exposure)

On the basis of the data shown in Table 2, the resist compositions of the lot No. 11 and the lot No. 12 to be determined were subjected to determinations by determination methods 3-1 to 3-3 using the measurement data of the pattern line width of the resist patterns formed by ArF exposure, and the validity of the determinations was evaluated.

As reference values, the measurement data of the initial lot (lot No. 1) was used in the determination method 3-1, the measurement data of the immediately preceding lot was used in the determination method 3-2, and the average value of the measurement data of the immediately preceding five lots (5-lot average) was used in the determination method 3-3. The allowable range in each determination method was defined as “the difference between the measurement data and the reference value is less than ±5% (<±5%) of the reference value”. The results are summarized in Table 5.

TABLE 5
Table 5

| | | | Example 3 | | Comparative Example 3 | |
|---|---|---|---|---|---|---|
| Resist composition | | | R1 | | R1 | |
| Determination target lot | | | 11 | 12 | 11 | 12 |
| LWR performance in the | | After 1 day | 2.97 | 2.99 | 2.97 | 2.99 |
| case of first developer (nm) | | After 1 month | 2.95 | 3.56 | 2.95 | 3.56 |
| Measurement data used | | | pattern line width (ArF exposure) | | | |
| Developer used | | | second developer | | first developer | |
| Determination | Reference | Initial lot | 75.6 | 75.6 | 80.8 | 80.8 |
| method 3-1 | value (nm) | | | | | |
| | Measurement data (nm) | | 75.6 | 70.3 | 79.1 | 77.8 |
| | Difference from | | 0.0% | −7.0% | −2.1% | −3.7% |
| | reference value (%) | | | | | |
| | Allowable range | | <±5% | <±5% | <±5% | <±5% |
| | Determination result | | acceptable | unacceptable | acceptable | acceptable |
| Determination | Reference | Immediately | 73.2 | 75.6 | 80.6 | 79.1 |
| method 3-2 | value (nm) | preceding lot | | | | |
| | Measurement data (nm) | | 75.6 | 70.3 | 79.1 | 77.8 |
| | Difference from | | 3.3% | −7.0% | −1.9% | −1.6% |
| | reference value (%) | | | | | |
| | Allowable range | | <±5% | <±5% | <±5% | <±5% |
| | Determination result | | acceptable | unacceptable | acceptable | acceptable |
| Determination | Reference | 5-lot average | 73.6 | 74.1 | 80.0 | 79.6 |
| method 3-3 | value (nm) | | | | | |

| | | | | |
|---|---|---|---|---|
| Measurement data (nm) | 75.6 | 70.3 | 79.1 | 77.8 |
| Difference from | 2.7% | −5.2% | −1.1% | −2.3% |
| reference value (%) | | | | |
| Allowable range | <±5% | <±5% | <±5% | <±5% |
| Determination result | acceptable | unacceptable | acceptable | acceptable |

| | | |
|---|---|---|
| Validity of determination methods | valid | invalid |

From the results shown in Table 5, it has been found that in Example 3 in which the determinations were performed using the measurement data acquired using the second developer, only the lot No. 12 one month after the production has been determined as unacceptable in each of the determination methods 3-1 to 3-3, and thus the determination methods are valid. On the other hand, it has been found that in Comparative Example 3 in which the determinations were performed using the measurement data acquired using the first developer, the lot No. 12 one month after the production has also been determined as acceptable in each of the determination methods 3-1 to 3-3, and thus the determination methods are invalid.

### Example 4 and Comparative Example 4: Determination Using Measurement Data of Pattern Line Width (EB Exposure)

On the basis of the data shown in Table 2, the resist compositions of the lot No. 11 and the lot No. 12 to be determined were subjected to determinations by determination methods 4-1 to 4-3 using the measurement data of the pattern line width of the resist patterns formed by EB exposure, and the validity of the determinations was evaluated.

As reference values, the measurement data of the initial lot (lot No. 1) was used in the determination method 4-1, the measurement data of the immediately preceding lot was used in the determination method 4-2, and the average value of the measurement data of the immediately preceding five lots (5-lot average) was used in the determination method 4-3. The allowable range in each determination method was defined as “the difference between the measurement data and the reference value is less than +500 (5) of the reference value”. The results are summarized in Table 6.

TABLE 6

| Table 6 | | | Example 4 | | Comparative Example 4 | |
|---|---|---|---|---|---|---|
| Resist composition | | | R1 | | R1 | |
| Determination target lot | | | 11 | 12 | 11 | 12 |
| LWR performance in the case of first | | After 1 day | 2.97 | 2.99 | 2.97 | 2.99 |
| developer (nm) | | After 1 month | 2.95 | 3.56 | 2.95 | 3.56 |
| Measurement data used | | | pattern line width (EB exposure) | | | |
| Developer used | | | second developer | | first developer | |
| Determination | Reference value | Initial lot | 50.5 | 50.5 | 52.8 | 52.8 |
| method 4-1 | (nm) | | | | | |
| | Measurement data (nm) | | 51.2 | 47.4 | 52.6 | 51.4 |
| | Difference from reference value (%) | | 1.4% | −6.1% | −0.4% | −2.7% |
| | Allowable range | | <±5% | <±5% | <±5% | <±5% |
| | Determination result | | acceptable | unacceptable | acceptable | acceptable |
| Determination | Reference value | Immediately | 50.1 | 51.2 | 51.4 | 52.6 |
| method 4-2 | (nm) | preceding lot | | | | |
| | Measurement data (nm) | | 51.2 | 47.4 | 52.6 | 51.4 |
| | Difference from reference value (%) | | 2.2% | −7.4% | 2.3% | −2.3% |
| | Allowable range | | <±5% | <±5% | <±5% | <±5% |
| | Determination result | | acceptable | unacceptable | acceptable | acceptable |
| Determination | Reference value | 5-lot average | 49.8 | 50.0 | 52.3 | 52.5 |
| method 4-3 | (nm) | | | | | |

| | | | | |
|---|---|---|---|---|
| Measurement data (nm) | 51.2 | 47.4 | 52.6 | 51.4 |
| Difference from reference value (%) | 2.8% | −5.2% | 0.6% | −2.0% |
| Allowable range | <±5% | <±5% | <±5% | <±5% |
| Determination result | acceptable | unacceptable | acceptable | acceptable |

| | | |
|---|---|---|
| Validity of determination methods | valid | invalid |

From the results shown in Table 6, it has been found that in Example 4 in which the determinations were performed using the measurement data acquired using the second developer, only the lot No. 12 one month after the production has been determined as unacceptable in each of the determination methods 4-1 to 4-3, and thus the determination methods are valid. On the other hand, it has been found that in Comparative Example 4 in which the determinations were performed using the measurement data acquired using the first developer, the lot No. 12 one month after the production has also been determined as acceptable in each of the determination methods 4-1 to 4-3, and thus the determination methods are invalid.

### Example 5 and Comparative Example 5: Determination Using Measurement Data of Pattern Defect (EUV Exposure)

On the basis of the data shown in Table 2, the resist compositions of the lot No. 11 and the lot No. 12 to be determined were subjected to a determination (determination method 5) using the measurement data of the pattern defect of the resist patterns formed by EUV exposure, and the validity of the determination was evaluated.

In the determination method 5, the allowable range was defined as “the number of defects per silicon wafer is less than 100 (<100)”. The results are summarized in Table 7.

TABLE 7
Table 7

| | | Example 5 | | Comparative Example 5 | |
|---|---|---|---|---|---|
| Resist composition | | R1 | | R1 | |
| Determination target lot | | 11 | 12 | 11 | 12 |
| LWR performance in the | After 1 day | 2.97 | 2.99 | 2.97 | 2.99 |
| case of first developer (nm) | After 1 month | 2.95 | 3.56 | 2.95 | 3.56 |
| Measurement data used | | pattern defect (EUV exposure) | | | |
| Developer used | | second developer | | first developer | |
| Determination | Measurement data | 48 | 102 | 44 | 38 |
| method 5 | (number/wafer) | | | | |
| | Allowable range | <100 | <100 | <100 | <100 |
| | (number/wafer) | | | | |
| | Determination result | acceptable | unacceptable | acceptable | acceptable |

| | | |
|---|---|---|
| Validity of determination method | valid | invalid |

From the results shown in Table 7, it has been found that in Example 5 in which the determination was performed using the measurement data acquired using the second developer, only the lot No. 12 one month after the production has been determined as unacceptable, and thus the determination method of Example 5 is valid. On the other hand, it has been found that in Comparative Example 5 in which the determination was performed using the measurement data acquired using the first developer, the lot No. 12 one month after the production has also been determined as acceptable, and thus the determination method of Comparative Example 5 is invalid.

### Example 6 and Comparative Example 6: Determination Using Measurement Data of Pattern Defect (ArF Exposure)

On the basis of the data shown in Table 2, the resist compositions of the lot No. 11 and the lot No. 12 to be determined were subjected to a determination (determination method 6) using the measurement data of the pattern defect of the resist patterns formed by ArF exposure, and the validity of the determination was evaluated.

In the determination method 6, the allowable range was defined as “the number of defects per silicon wafer is less than 100 (<100)”. The results are summarized in Table 8.

TABLE 8
Table 8

| | | Example 6 | | Comparative Example 6 | |
|---|---|---|---|---|---|
| Resist composition | | R1 | | R1 | |
| Determination target lot | | 11 | 12 | 11 | 12 |
| LWR performance in the | After 1 day | 2.97 | 2.99 | 2.97 | 2.99 |
| case of first developer (nm) | After 1 month | 2.95 | 3.56 | 2.95 | 3.56 |
| Measurement data used | | pattern defect (KrF exposure) | | | |
| Developer used | | second developer | | first developer | |
| Determination | Measurement data | 31 | 105 | 48 | 13 |
| method 6 | (number/wafer) | | | | |
| | Allowable range | <100 | <100 | <100 | <100 |
| | (number/wafer) | | | | |
| | Determination result | acceptable | unacceptable | acceptable | acceptable |

| | | |
|---|---|---|
| Validity of determination method | valid | invalid |

From the results shown in Table 8, it has been found that in Example 6 in which the determination was performed using the measurement data acquired using the second developer, only the lot No. 12 one month after the production has been determined as unacceptable, and thus the determination method of Example 6 is valid. On the other hand, it has been found that in Comparative Example 6 in which the determination was performed using the measurement data acquired using the first developer, the lot No. 12 one month after the production has also been determined as acceptable, and thus the determination method of Comparative Example 6 is invalid.

### Example 7 and Comparative Example 7: Determination Using Measurement Data of Pattern Defect (KrF Exposure)

On the basis of the data shown in Table 2, the resist compositions of the lot No. 11 and the lot No. 12 to be determined were subjected to a determination (determination method 7) using the measurement data of the pattern defect of the resist patterns formed by KrF exposure, and the validity of the determination was evaluated.

In the determination method 7, the allowable range was defined as “the number of defects per silicon wafer is less than 100 (<100)”. The results are summarized in Table 9.

TABLE 9
Table 9

| | | Example 7 | | Comparative Example 7 | |
|---|---|---|---|---|---|
| Resist composition | | R1 | | R1 | |
| Determination target lot | | 11 | 12 | 11 | 12 |
| LWR performance in the | After 1 day | 2.97 | 2.99 | 2.97 | 2.99 |
| case of first developer (nm) | After 1 month | 2.95 | 3.56 | 2.95 | 3.56 |
| Measurement data used | | pattern defect (ArF exposure) | | | |
| Developer used | | second developer | | first developer | |
| Determination | Measurement data | 47 | 110 | 15 | 20 |
| method 7 | (number/wafer) | | | | |
| | Allowable range | <100 | <100 | <100 | <100 |
| | (number/wafer) | | | | |
| | Determination result | acceptable | unacceptable | acceptable | acceptable |

| | | |
|---|---|---|
| Validity of determination method | valid | invalid |

From the results shown in Table 9, it has been found that in Example 7 in which the determination was performed using the measurement data acquired using the second developer, only the lot No. 12 one month after the production has been determined as unacceptable, and thus the determination method of Example 7 is valid. On the other hand, it has been found that in Comparative Example 7 in which the determination was performed using the measurement data acquired using the first developer, the lot No. 12 one month after the production has also been determined as acceptable, and thus the determination method of Comparative Example 7 is invalid.

### Example 8 and Comparative Example 8: Determination Using Measurement Data of Rmin (EUV Exposure)

On the basis of the data shown in Table 2, the resist compositions of the lot No. 11 and the lot No. 12 to be determined were subjected to determinations by determination methods 8-1 to 8-3 using the measurement data of the minimum dissolution rate (Rmin) of the resist films formed by EUV exposure, and the validity of the determinations was evaluated.

As reference values, the measurement data of the initial lot (lot No. 1) was used in the determination method 8-1, the measurement data of the immediately preceding lot was used in the determination method 8-2, and the average value of the measurement data of the immediately preceding five lots (5-lot average) was used in the determination method 8-3. The allowable range in each determination method was defined as “the difference between the measurement data and the reference value is less than ±10% (<±10%) of the reference value”. The results are summarized in Table 10.

TABLE 10

| Table 10 | | | Example 8 | | Comparative Example 8 | |
|---|---|---|---|---|---|---|
| Resist composition | | | R1 | | R1 | |
| Determination target lot | | | 11 | 12 | 11 | 12 |
| LWR performance in the case of first | | After 1 day | 2.97 | 2.99 | 2.97 | 2.99 |
| developer (nm) | | After 1 month | 2.95 | 3.56 | 2.95 | 3.56 |
| Measurement data used | | | minimum resist film dissolution rate (EUV exposure) | | | |
| Developer used | | | second developer | | first developer | |
| Determination | Reference value | Initial lot | 0.194 | 0.194 | 0.123 | 0.123 |
| method 8-1 | (nm/s) | | | | | |
| | Measurement data (nm/s) | | 0.199 | 0.222 | 0.129 | 0.122 |
| | Difference from reference value (%) | | 2.6% | 14.4% | 4.9% | −0.8% |
| | Allowable range | | <±10% | <±10% | <±10% | <±10% |
| | Determination result | | acceptable | unacceptable | acceptable | acceptable |
| Determination | Reference value | Immediately | 0.201 | 0.199 | 0.129 | 0.129 |
| method 8-2 | (nm/s) | preceding lot | | | | |
| | Measurement data (nm/s) | | 0.199 | 0.222 | 0.129 | 0.122 |
| | Difference from reference value (%) | | −1.0% | 11.6% | 0.0% | −5.4% |
| | Allowable range | | <±10% | <±10% | <±10% | <±10% |
| | Determination result | | acceptable | unacceptable | acceptable | acceptable |
| Determination | Reference value | 5-lot average | 0.194 | 0.195 | 0.127 | 0.127 |
| method 8-3 | (nm/s) | | | | | |

| | | | | |
|---|---|---|---|---|
| Measurement data (nm/s) | 0.199 | 0.222 | 0.129 | 0.122 |
| Difference from reference value (%) | 2.4% | 13.6% | 1.6% | −4.2% |
| Allowable range | <±10% | <±10% | <±10% | <±10% |
| Determination result | acceptable | unacceptable | acceptable | acceptable |

| | | |
|---|---|---|
| Validity of determination methods | valid | invalid |

From the results shown in Table 10, it has been found that in Example 8 in which the determinations were performed using the measurement data acquired using the second developer, only the lot No. 12 one month after the production has been determined as unacceptable in each of the determination methods 8-1 to 8-3, and thus the determination methods are valid. On the other hand, it has been found that in Comparative Example 8 in which the determinations were performed using the measurement data acquired using the first developer, the lot No. 12 one month after the production has also been determined as acceptable in each of the determination methods 8-1 to 8-3, and thus the determination methods are invalid.

### Example 9 and Comparative Example 9: Determination Using Measurement Data of Rmin (KrF Exposure)

On the basis of the data shown in Table 2, the resist compositions of the lot No. 11 and the lot No. 12 to be determined were subjected to determinations by determination methods 9-1 to 9-3 using the measurement data of the minimum dissolution rate (Rmin) of the resist films formed by KrF exposure, and the validity of the determinations was evaluated.

As reference values, the measurement data of the initial lot (lot No. 1) was used in the determination method 9-1, the measurement data of the immediately preceding lot was used in the determination method 9-2, and the average value of the measurement data of the immediately preceding five lots (5-lot average) was used in the determination method 9-3. The allowable range in each determination method was defined as “the difference between the measurement data and the reference value is less than ±10% (<±10%) of the reference value”. The results are summarized in Table 11.

TABLE 11

| Table 11 | | | Example 9 | | Comparative Example 9 | |
|---|---|---|---|---|---|---|
| Resist composition | | | R1 | | R1 | |
| Determination target lot | | | 11 | 12 | 11 | 12 |
| LWR performance in the | After 1 day | | 2.97 | 2.99 | 2.97 | 2.99 |
| case of first developer (nm) | After 1 month | | 2.95 | 3.56 | 2.95 | 3.56 |
| Measurement data used | | | minimum resist film dissolution rate (KrF exposure) | | | |
| Developer used | | | second developer | | first developer | |
| Determination | Reference | Initial lot | 0.191 | 0.191 | 0.130 | 0.130 |
| method 9-1 | value (nm/s) | | | | | |
| | Measurement data (nm/s) | | 0.199 | 0.223 | 0.126 | 0.131 |
| | Difference from reference | | 4.2% | 16.8% | −3.1% | 0.8% |
| | value (%) | | | | | |
| | Allowable range | | <±10% | <±10% | <±10% | <±10% |
| | Determination result | | acceptable | unacceptable | acceptable | acceptable |
| Determination | Reference | Immediately | 0.199 | 0.199 | 0.127 | 0.126 |
| method 9-2 | value (nm/s) | preceding lot | | | | |
| | Measurement data (nm/s) | | 0.199 | 0.223 | 0.126 | 0.131 |
| | Difference from reference | | 0.0% | 12.1% | −0.8% | 4.0% |
| | value (%) | | | | | |
| | Allowable range | | <±10% | <±10% | <±10% | <±10% |
| | Determination result | | acceptable | unacceptable | acceptable | acceptable |
| Determination | Reference | 5-lot average | 0.201 | 0.199 | 0.128 | 0.128 |
| method 9-3 | value (nm/s) | | | | | |

| | | | | |
|---|---|---|---|---|
| Measurement data (nm/s) | 0.199 | 0.223 | 0.126 | 0.131 |
| Difference from reference | −0.8% | 12.1% | −1.4% | 2.3% |
| value (%) | | | | |
| Allowable range | <±10% | <±10% | <±10% | <±10% |
| Determination result | acceptable | unacceptable | acceptable | acceptable |

| | | |
|---|---|---|
| Validity of determination methods | valid | invalid |

From the results shown in Table 11, it has been found that in Example 9 in which the determinations were performed using the measurement data acquired using the second developer, only the lot No. 12 one month after the production has been determined as unacceptable in each of the determination methods 9-1 to 9-3, and thus the determination methods are valid. On the other hand, it has been found that in Comparative Example 9 in which the determinations were performed using the measurement data acquired using the first developer, the lot No. 12 one month after the production has also been determined as acceptable in each of the determination methods 9-1 to 9-3, and thus the determination methods are invalid.

### Example 10 and Comparative Example 10: Determination Using Measurement Data of Rmin (ArF Exposure)

On the basis of the data shown in Table 2, the resist compositions of the lot No. 11 and the lot No. 12 to be determined were subjected to determinations by determination methods 10-1 to 10-3 using the measurement data of the minimum dissolution rate (Rmin) of the resist films formed by ArF exposure, and the validity of the determinations was evaluated.

As reference values, the measurement data of the initial lot (lot No. 1) was used in the determination method 10-1, the measurement data of the immediately preceding lot was used in the determination method 10-2, and the average value of the measurement data of the immediately preceding five lots (5-lot average) was used in the determination method 10-3. The allowable range in each determination method was defined as “the difference between the measurement data and the reference value is less than ±10% (<±10%) of the reference value”. The results are summarized in Table 12.

TABLE 12

| Table 12 | | | Example 10 | | Comparative Example 10 | |
|---|---|---|---|---|---|---|
| Resist composition | | | R1 | | R1 | |
| Determination target lot | | | 11 | 12 | 11 | 12 |
| LWR performance in the | | After 1 day | 2.97 | 2.99 | 2.97 | 2.99 |
| case of first developer (nm) | | After 1 month | 2.95 | 3.56 | 2.95 | 3.56 |
| Measurement data used | | | minimum resist film dissolution rate (ArF exposure) | | | |
| Developer used | | | second developer | | first developer | |
| Determination | Reference | Initial lot | 0.198 | 0.198 | 0.130 | 0.130 |
| method 10-1 | value (nm/s) | | | | | |
| | Measurement data (nm/s) | | 0.197 | 0.224 | 0.135 | 0.133 |
| | Difference from reference | | −0.5% | 13.1% | 3.8% | 2.3% |
| | value (%) | | | | | |
| | Allowable range | | <±10% | <±10% | <±10% | <±10% |
| | Determination result | | acceptable | unacceptable | acceptable | acceptable |
| Determination | Reference | Immediately | 0.201 | 0.197 | 0.131 | 0.135 |
| method 10-2 | value (nm/s) | preceding lot | | | | |
| | Measurement data (nm/s) | | 0.197 | 0.224 | 0.135 | 0.133 |
| | Difference from reference | | −2.0% | 13.7% | 3.1% | −1.5% |
| | value (%) | | | | | |
| | Allowable range | | <±10% | <±10% | <±10% | <±10% |
| | Determination result | | acceptable | unacceptable | acceptable | acceptable |
| Determination | Reference | 5-lot average | 0.203 | 0.201 | 0.130 | 0.132 |
| method 10-3 | value (nm/s) | | | | | |

| | | | | |
|---|---|---|---|---|
| Measurement data (nm/s) | 0.197 | 0.224 | 0.135 | 0.133 |
| Difference from reference | −3.0% | 11.6% | 3.5% | 0.8% |
| value (%) | | | | |
| Allowable range | <±10% | <±10% | <±10% | <±10% |
| Determination result | acceptable | unacceptable | acceptable | acceptable |

| | | |
|---|---|---|
| Validity of determination methods | valid | invalid |

From the results shown in Table 12, it has been found that in Example 10 in which the determinations were performed using the measurement data acquired using the second developer, only the lot No. 12 one month after the production has been determined as unacceptable in each of the determination methods 10-1 to 10-3, and thus the determination methods are valid. On the other hand, it has been found that in Comparative Example 10 in which the determinations were performed using the measurement data acquired using the first developer, the lot No. 12 one month after the production has also been determined as acceptable in each of the determination methods 10-1 to 10-3, and thus the determination methods are invalid.

### Example 11 and Comparative Example 11: Determination Using Measurement Data of Defect After Resist Film Removal

On the basis of the data shown in Table 2, the resist compositions of the lot No. 11 and the lot No. 12 to be determined were subjected to a determination (determination method 11) using the measurement data of the number of defects on the surface of a silicon wafer after resist film removal, and the validity of the determination was evaluated.

In the determination method 11, the allowable range was defined as “the number of defects per silicon wafer is less than 100 (<100)”. The results are summarized in Table 13.

TABLE 13
Table 13

| | | Example 11 | | Comparative Example 11 | |
|---|---|---|---|---|---|
| Resist composition | | R1 | | R1 | |
| Determination target lot | | 11 | 12 | 11 | 12 |
| LWR performance in the | After 1 day | 2.97 | 2.99 | 2.97 | 2.99 |
| case of first developer (nm) | After 1 month | 2.95 | 3.56 | 2.95 | 3.56 |
| Measurement data used | | defect after resist film removal | | | |
| Developer used | | second developer | | first developer | |
| Determination | Measurement data | 15 | 105 | 48 | 39 |
| method 11 | (number/wafer) | | | | |
| | Allowable range | <100 | <100 | <100 | <100 |
| | (number/wafer) | | | | |
| | Determination result | acceptable | unacceptable | acceptable | acceptable |

| | | |
|---|---|---|
| Validity of determination method | valid | invalid |

From the results shown in Table 13, it has been found that in Example 11 in which the determination was performed using the measurement data acquired using the second developer, only the lot No. 12 one month after the production has been determined as unacceptable, and thus the determination method of Example 11 is valid. On the other hand, it has been found that in Comparative Example 11 in which the determination was performed using the measurement data acquired using the first developer, the lot No. 12 one month after the production has also been determined as acceptable, and thus the determination method of Comparative Example 11 is invalid.

### Example 12 and Comparative Example 12: Determination Using Measurement Data of Rmax

On the basis of the data shown in Table 2, the resist compositions of the lot No. 11 and the lot No. 12 to be determined were subjected to determinations by determination methods 12-1 to 12-3 using the measurement data of the maximum dissolution rate (Rmax) of the resist films formed, and the validity of the determinations was evaluated.

As reference values, the measurement data of the initial lot (lot No. 1) was used in the determination method 12-1, the measurement data of the immediately preceding lot was used in the determination method 12-2, and the average value of the measurement data of the immediately preceding five lots (5-lot average) was used in the determination method 12-3. The allowable range in each determination method was defined as “the difference between the measurement data and the reference value is less than ±10% (<±10%) of the reference value”. The results are summarized in Table 14.

TABLE 14

| Table 14 | | | Example 12 | | Comparative Example 12 | |
|---|---|---|---|---|---|---|
| Resist composition | | | R1 | | R1 | |
| Determination target lot | | | 11 | 12 | 11 | 12 |
| LWR performance in the case of first | | After 1 day | 2.97 | 2.99 | 2.97 | 2.99 |
| developer (nm) | | After 1 month | 2.95 | 3.56 | 2.95 | 3.56 |
| Measurement data used | | | maximum resist film dissolution rate | | | |
| Developer used | | | second developer | | first developer | |
| Determination | Reference value | Initial lot | 58.0 | 58.0 | 20.1 | 20.1 |
| method 12-1 | (nm/s) | | | | | |
| | Measurement data (nm/s) | | 57.8 | 66.0 | 19.6 | 20.6 |
| | Difference from reference value (%) | | −0.3% | 13.8% | −2.5% | 2.5% |
| | Allowable range | | <±10% | <±10% | <±10% | <±10% |
| | Determination result | | acceptable | unacceptable | acceptable | acceptable |
| Determination | Reference value | Immediately | 60.2 | 57.8 | 19.7 | 19.6 |
| method 12-2 | (nm/s) | preceding lot | | | | |
| | Measurement data (nm/s) | | 57.8 | 66.0 | 19.6 | 20.6 |
| | Difference from reference value (%) | | −4.0% | 14.2% | −0.5% | 5.1% |
| | Allowable range | | <±10% | <±10% | <±10% | <±10% |
| | Determination result | | acceptable | unacceptable | acceptable | acceptable |
| Determination | Reference value | 5-lot average | 59.5 | 59.4 | 19.8 | 19.6 |
| method 12-3 | (nm/s) | | | | | |

| | | | | |
|---|---|---|---|---|
| Measurement data (nm/s) | 57.8 | 66.0 | 19.6 | 20.6 |
| Difference from reference value (%) | −2.9% | 11.2% | −1.1% | 4.9% |
| Allowable range | <±10% | <±10% | <±10% | <±10% |
| Determination result | acceptable | unacceptable | acceptable | acceptable |

| | | |
|---|---|---|
| Validity of determination methods | valid | invalid |

From the results shown in Table 14, it has been found that in Example 12 in which the determinations were performed using the measurement data acquired using the second developer, only the lot No. 12 one month after the production has been determined as unacceptable in each of the determination methods 12-1 to 12-3, and thus the determination methods are valid. On the other hand, it has been found that in Comparative Example 12 in which the determinations were performed using the measurement data acquired using the first developer, the lot No. 12 one month after the production has also been determined as acceptable in each of the determination methods 12-1 to 12-3, and thus the determination methods are invalid.

### Second Example

### Various Components of Resist Composition

### Resin

The structure of resin P-2 shown in Table 15 is shown below.

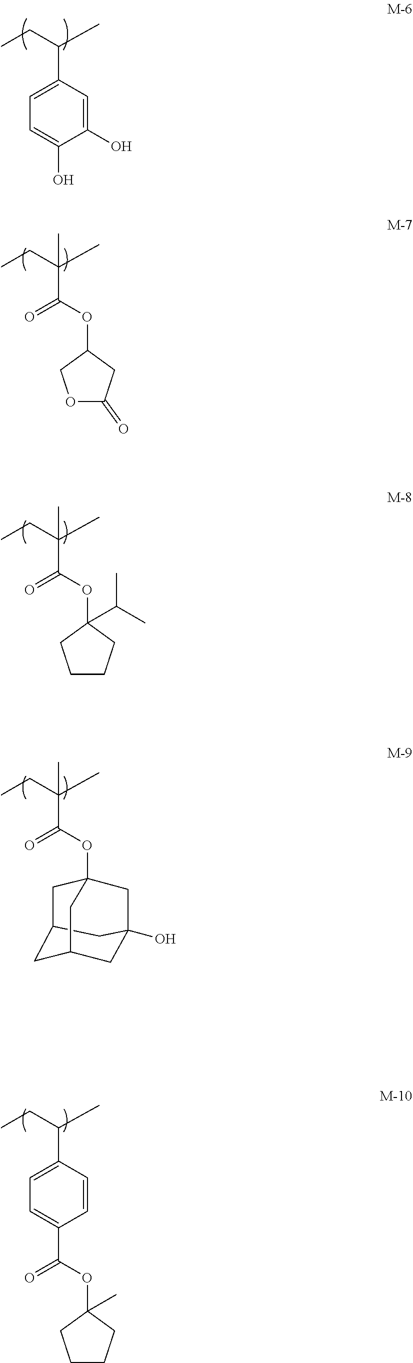

The weight-average molecular weight (Mw) and dispersity (Mw/Mn) of resin P-2 were measured by GPC (carrier: tetrahydrofuran (THF)) in terms of standard polystyrene amount. The compositional ratio (by mol %) of the resin was measured by ¹³C-NMR (nuclear magnetic resonance).

### Synthesis Example 2: Synthesis of Resin P-2

Under a stream of nitrogen, 194.3 g of cyclohexanone was placed in a three-necked flask and heated to 80° C. A solution of monomer M-6 (11.5 g), monomer M-7 (4.6 g), monomer M-8 (15.7 g), monomer M-9 (6.2 g), and monomer M-10 (12.0 g) corresponding to repeating units of resin P-2 above and a polymerization initiator V-601 (manufactured by FUJIFILM Wako Pure Chemical Corporation, 3.44 g) in cyclohexanone (105 g) was added dropwise into the three-necked flask over 6 hours. After completion of the dropwise addition, the solution was further allowed to react at 80° C. for 2 hours. After the reaction solution was allowed to cool, the reaction solution was added dropwise into a mixed solution of methanol:water over 20 minutes. Subsequently, powder precipitated as a result of the dropwise addition was separated by filtration and dried to obtain resin P-2 (32.6 g). The compositional ratio (molar ratio) of the repeating units determined by nuclear magnetic resonance (NMR) was 30/10/30/10/20. Resin P-2 obtained had a weight-average molecular weight (Mw) of 9,000 and a dispersity (Mw/Mn) of 1.6.

### Photoacid Generator

The structure of a photoacid generator (PAG-2) shown in Table 15 is shown below.

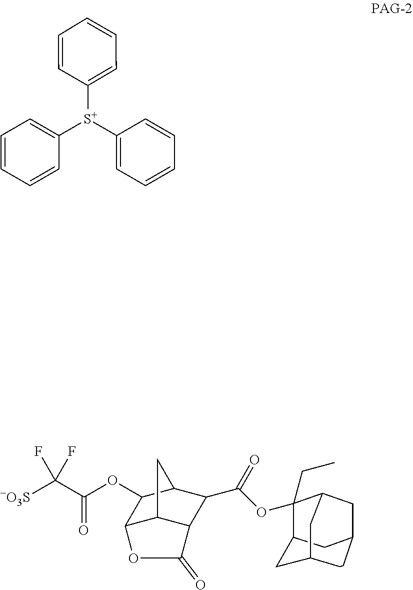

### Quencher

The structure of a quencher (Q-2) shown in Table 15 is shown below.

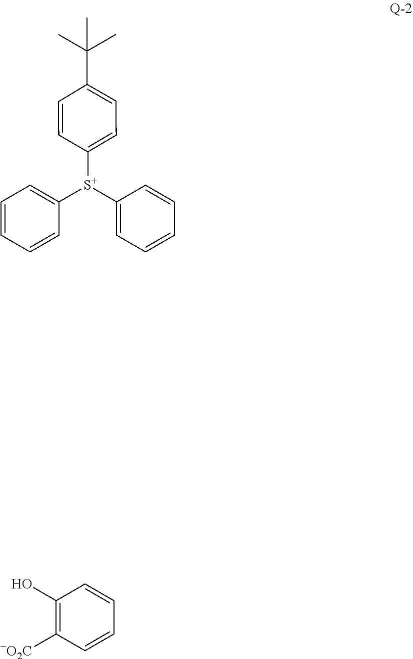

### Preparation of Resist Composition

Resin P-2, photoacid generator PAG-2, quencher Q-2, and solvents SL-1, SL-2, and SL-3 were mixed so as to give a composition shown in Table 15 below. Solvents SL-1, SL-2, and SL-3 are the same as the solvents included in resist composition R1.

The resulting mixed solution was then filtered through a polyethylene filter having a pore size of 0.03 m to prepare a resin composition (resist composition R2). Resist composition R2 thus obtained was used to perform the measurement and determination described later.

TABLE 15
Table 15

| | Resin | | | | Photoacid | | | | | |
|---|---|---|---|---|---|---|---|---|---|---|
| | | Monomer type | | | generator | | | | Solid | |
| Resist | | (compositional ratio | | Amount | | Amount | Quencher | | contents | Solvent |
| composition | Type | [mol %]) | Mw | [%] | Type | [%] | Type | Amount | [%] | (mass ratio [%]) |
| R2 | P−2 | M−6/M−7/M−8/M−9/M−10 | 9,000 | 75 | PAG-2 | 20 | Q-2 | 5 | 2.0 | SL-1/SL-2/SL−3 |
| | | (30/10/30/10/20) | | | | | | | | (75/20/5) |

### Measurement of Resist Composition

Resist composition R2 was produced 12 times according to the production method described above, and lot numbers were given in the order of production. For each production lot, the LWR performance was measured by the following method using the following first developer one day and one month after the production of the resist. In addition, for each production lot, various inspections were performed using the following first developer and the following second developer to acquire measurement data.

The first developer and the second developer used were as follows.
First developer: mixed solution of butyl acetate and decane (butyl acetate:decane=85:15 (mass ratio))
Second developer: butyl acetate

### Measurement of LWR Performance Using First Developer

### Formation of Resist Pattern

A composition for underlayer film formation SHB-A940 (manufactured by Shin-Etsu Chemical Co., Ltd.) was applied onto a silicon wafer having a diameter of 12 inches and baked at 205° C. for 60 seconds to form an underlayer film having a thickness of 20 nm. Resist composition R2 was applied onto the underlayer film and baked at 90° C. for 60 seconds to form a resist film having a thickness of 35 nm. Thus, a resist-film-carrying silicon wafer was produced.

The resist-film-carrying silicon wafer obtained by the above procedure was subjected to pattern exposure using an EUV scanner NXE3300 (NA, 0.33; a, 0.9/0.7; dipole illumination) manufactured by ASML. As a reticle, a mask having a line width of 30 nm and a line-to-space ratio of 1:1 in terms of on-wafer dimensions was used. Thereafter, baking (PEB) was performed at 120° C. for 60 seconds. The pattern-exposed resist-film-carrying silicon wafer was immersed in the first developer and subjected to puddle development for 30 seconds, and then the resist-film-carrying silicon wafer was taken out of the first developer and rotated at a rotation speed of 4000 rpm for 30 seconds, thereby obtaining a line-and-space pattern with a pitch of 60 nm.

### Measurement of Optimum Exposure Dose

In the above production of a line-and-space pattern using the first developer, the exposure dose in the pattern exposure was varied, and the line width of a pattern produced at each exposure dose was measured using an SEM (“CG-4100” manufactured by Hitachi High-Technologies Corporation). The exposure dose at which the measured line width was 30 nm was determined and employed as the optimum exposure dose (mJ/cm²).

### Measurement of LWR Performance

In the resist pattern with a line and space resolved at the optimum exposure dose, the line width was observed using an SEM at randomly selected 160 points, and the variation in measurement was evaluated by 36. Smaller values indicate better performance.

The measurement of LWR performance by the above method was performed on resist patterns formed using resist compositions R2 one day after the production and one month after the production. The measurement results are shown in Table 16 given later.

### Measurement of Pattern Line Width (Steps A1, B1, C1, and X1a)

### EUV Exposure

A composition for underlayer film formation SHB-A940 (manufactured by Shin-Etsu Chemical Co., Ltd.) was applied onto a silicon wafer and baked at 205° C. for 60 seconds to form an underlayer film having a thickness of 20 nm. Resist composition R2 was applied onto the underlayer film and baked at 90° C. for 60 seconds to form a resist film having a thickness of 35 nm.

The resist-film-carrying silicon wafer obtained by the above procedure was subjected to pattern exposure at an exposure dose of 35 mJ/cm² using an EUV scanner NXE3300 (NA, 0.33; a, 0.9/0.7; dipole illumination) manufactured by ASSML. As a reticle, a mask having a line width of 30 nm and a line-to-space ratio of 1:1 in terms of on-wafer dimensions was used. Thereafter, baking (PEB) was performed at 120° C. for 60 seconds.

The pattern-exposed resist-film-carrying silicon wafer was immersed in the first developer or the second developer and subjected to puddle development for 30 seconds, and then the resist-film-carrying silicon wafer was taken out of the developer and rotated at a rotation speed of 4000 rpm for 30 seconds, thereby obtaining a line-and-space pattern with a pitch of 60 nm.

The line width of the pattern obtained was measured using an SEM (“CG-4100” manufactured by Hitachi High-Technologies Corporation) to acquire measurement data.

### KrF Exposure

A composition for organic antireflection film formation DUV44 (manufactured by Brewer Science, Inc.) was applied onto a silicon wafer, and the coating film was baked at 205° C. for 60 seconds. Thus, an antireflection film having a thickness of 60 nm was formed on the silicon wafer. Resist composition R2 was applied onto the antireflection film and baked at 90° C. for 60 seconds to form a resist film having a thickness of 35 nm.

The resist-film-carrying silicon wafer obtained by the above procedure was subjected to pattern exposure at an exposure dose of 90 mJ/cm² using a KrF excimer laser scanner (manufactured by ASML, PAS5500/850) (NA, 0.80). As a reticle, a 6% halftone mask having a line width of 100 nm and a line-to-space ratio of 1:1 in terms of on-wafer dimensions was used. Thereafter, baking (PEB) was performed at 120° C. for 60 seconds.

The pattern-exposed resist-film-carrying silicon wafer was subjected to puddle development in the first developer or the second developer for 30 seconds, and then the resist-film-carrying silicon wafer was taken out of the developer and rotated at a rotation speed of 4000 rpm for 30 seconds, thereby obtaining a line-and-space pattern with a pitch of 200 nm.

The line width of the pattern obtained was measured using an SEM (“CG-4100” manufactured by Hitachi High-Technologies Corporation) to acquire measurement data.

### ArF Exposure

A composition for organic antireflection film formation ARC29SR (manufactured by Nissan Chemical Corporation) was applied onto a silicon wafer, and the coating film was baked at 205° C. for 60 seconds. Thus, an antireflection film having a thickness of 90 nm was formed on the silicon wafer. Resist composition R2 was applied onto the antireflection film and baked at 90° C. for 60 seconds to form a resist film having a thickness of 35 nm.

The resist-film-carrying silicon wafer obtained by the above procedure was subjected to pattern exposure at an exposure dose of 45 mJ/cm² using an ArF excimer laser liquid-immersion scanner (XT1700i manufactured by ASML; NA, 1.20; Dipole; outer sigma, 0.900; inner sigma, 0.700; Y deflection). As a reticle, a 6% halftone mask having a line width of 75 nm and a line-to-space ratio of 1:1 in terms of on-wafer dimensions was used.

Thereafter, baking (PEB) was performed at 120° C. for 60 seconds. The pattern-exposed resist-film-carrying silicon wafer was subjected to puddle development in the first developer or the second developer for 30 seconds, and then the resist-film-carrying silicon wafer was taken out of the developer and rotated at a rotation speed of 4000 rpm for 30 seconds, thereby obtaining a line-and-space pattern with a pitch of 150 nm.

The line width of the pattern obtained was measured using an SEM (“CG-4100” manufactured by Hitachi High-Technologies Corporation) to acquire measurement data.

### EB Exposure

Using an ACTM (manufactured by Tokyo Electron Ltd.), a composition for antireflection film formation DUV44 (manufactured by Brewer Science, Inc.) was applied onto a 152-mm square mask blank having a Cr outermost surface and baked at 205° C. for 60 seconds to form an underlayer film having a thickness of 60 nm. Resist composition R2 was applied onto the underlayer film and baked at 90° C. for 60 seconds to form a resist film having a thickness of 35 nm. Thus, a resist-film-carrying mask blank was formed.

The resist-film-carrying mask blank obtained by the above procedure was subjected to pattern exposure at an exposure dose of 110 μC/cm² using an electron beam exposure device (EBM-9000 manufactured by NuFlare Technology Inc.; acceleration voltage, 50 kV). As a reticle, a 6% halftone mask having a line width of 75 nm and a line-to-space ratio of 1:1 in terms of on-wafer dimensions was used. The patterning was performed so as to form a line and space having a line width of 50 nm and a ratio of 1:1 in terms of on-blank dimensions.

Thereafter, baking (PEB) was performed at 120° C. for 60 seconds. The pattern-exposed resist-film-carrying silicon wafer was subjected to puddle development in the first developer or the second developer for 30 seconds, and then the resist-film-carrying silicon wafer was taken out of the developer and rotated at a rotation speed of 4000 rpm for 30 seconds, thereby obtaining a line-and-space pattern with a pitch of 100 nm.

The line width of the pattern obtained was measured using an SEM (“CG-4100” manufactured by Hitachi High-Technologies Corporation) to acquire measurement data.

### Measurement of Pattern Defect (Steps A1, B1, C1, and X1b)

### EUV Exposure

According to the method described in “EUV Exposure” of “Measurement of Pattern Line Width” above, a line-and-space pattern with a pitch of 60 nm was formed on a silicon wafer using resist composition R2.

The pattern obtained was subjected to defect inspection using a defect inspection apparatus KLA2925 manufactured by KLA-Tencor Corporation to measure the number of defects (defect counts) present on the surface of the silicon wafer.

### KrF Exposure

According to the method described in “KrF Exposure” of “Measurement of Pattern Line Width” above, a line-and-space pattern with a pitch of 200 nm was formed on a silicon wafer using resist composition R2.

The pattern obtained was subjected to defect inspection using a defect inspection apparatus KLA2925 manufactured by KLA-Tencor Corporation to measure the number of defects (defect counts) present on the surface of the silicon wafer.

### ArF Exposure

According to the method described in “ArF Exposure” of “Measurement of Pattern Line Width” above, a line-and-space pattern with a pitch of 150 nm was formed on a silicon wafer using resist composition R2.

The pattern obtained was subjected to defect inspection using a defect inspection apparatus KLA2925 manufactured by KLA-Tencor Corporation to measure the number of defects (defect counts) present on the surface of the silicon wafer.

### Measurement of Minimum Resist Film Dissolution Rate (Rmin) (Steps A1, B1, C1, and X1c) EUV Exposure

A composition for underlayer film formation SHB-A940 (manufactured by Shin-Etsu Chemical Co., Ltd.) was applied onto a silicon wafer and baked at 205° C. for 60 seconds to form an underlayer film having a thickness of 20 nm. Resist composition R2 was applied onto the underlayer film and baked at 90° C. for 60 seconds to form a resist film having a thickness of 35 nm.

The resist-film-carrying silicon wafer obtained by the above procedure was subjected to open-frame exposure at an exposure dose of 35 mJ/cm² using an EUV scanner NXE3300 (NA, 0.33) manufactured by ASML. Thereafter, baking (PEB) was performed at 120° C. for 60 seconds, and a film thickness (FT1) of the post-PEB resist film was measured using an optical coherence-type film thickness meter (“VM-3200 (product name)”, manufactured by SCREEN Semiconductor Solutions Co., Ltd.).

Subsequently, the exposed resist-film-carrying silicon wafer was immersed in the first developer or the second developer and subjected to puddle development for 30 seconds, and then the resist-film-carrying silicon wafer was taken out of the developer and rotated at a rotation speed of 4000 rpm for 30 seconds. Using the optical coherence-type film thickness meter again, a film thickness (FT2) of the post-development resist film on the silicon wafer was measured.

A minimum resist film dissolution rate (Rmin) was calculated from the film thicknesses FT1 and FT2 using the following formula to acquire measurement data.

Formula: R min=(FT1−FT2)/30 (nm/s)

### KrF Exposure

A composition for organic antireflection film formation DUV44 (manufactured by Brewer Science, Inc.) was applied onto a silicon wafer, and the coating film was baked at 205° C. for 60 seconds to form an underlayer film having a thickness of 60 nm. Resist composition R2 was applied onto the underlayer film and baked at 90° C. for 60 seconds to form a resist film having a thickness of 35 nm.

The resist-film-carrying silicon wafer obtained by the above procedure was subjected to open-frame exposure at an exposure dose of 110 mJ/cm² using a KrF excimer laser scanner (manufactured by ASML, PAS5500/850) (NA, 0.80). Thereafter, baking (PEB) was performed at 120° C. for 60 seconds, and a film thickness (FT1) of the post-PEB resist film was measured using an optical coherence-type film thickness meter.

Subsequently, the exposed resist-film-carrying silicon wafer was subjected to puddle development in the first developer or the second developer for 30 seconds, and then the resist-film-carrying silicon wafer was taken out of the developer and rotated at a rotation speed of 4000 rpm for 30 seconds. Using the optical coherence-type film thickness meter again, a film thickness (FT2) of the post-development resist film on the silicon wafer was measured.

A minimum resist film dissolution rate (Rmin) was calculated from the film thicknesses FT1 and FT2 using the following formula to acquire measurement data.

Formula: R min=(FT1−FT2)/30 (nm/s)

### ArF Exposure

A composition for organic antireflection film formation ARC29SR (manufactured by Nissan Chemical Corporation) was applied onto a silicon wafer, and the coating film was baked at 205° C. for 60 seconds. Thus, an underlayer film having a thickness of 90 nm was formed on the silicon wafer. Resist composition R2 was applied onto the underlayer film and baked at 90° C. for 60 seconds to form a resist film having a thickness of 35 nm.

The resist-film-carrying silicon wafer obtained by the above procedure was subjected to open-frame exposure at an exposure dose of 45 mJ/cm² using an ArF excimer laser liquid-immersion scanner (XT1700i manufactured by ASML; NA, 1.20). Thereafter, baking (PEB) was performed at 120° C. for 60 seconds, and a film thickness (FT1) of the post-PEB resist film was measured using an optical coherence-type film thickness meter.

Subsequently, the exposed resist-film-carrying silicon wafer was subjected to puddle development in the first developer or the second developer for 30 seconds, and then the resist-film-carrying silicon wafer was taken out of the developer and rotated at a rotation speed of 4000 rpm for 30 seconds. Using the optical coherence-type film thickness meter again, a film thickness (FT2) of the post-development resist film on the silicon wafer was measured.

A minimum resist film dissolution rate (Rmin) was calculated from the film thicknesses FT1 and FT2 using the following formula to acquire measurement data.

Formula: R min=(FT1−FT2)/30 (nm/s)

Measurement of Defect on Substrate after Resist Film Removal (Steps A2, C2, and X2a)

Resist composition R2 was applied onto a silicon wafer and baked at 90° C. for 60 seconds to form a resist film having a thickness of 35 nm.

Subsequently, the first developer or the second developer was applied (ejected at a flow rate of 1 mL/S for 10 seconds) to the resist-film-carrying silicon wafer to remove the resist film.

The silicon wafer after the removal treatment was subjected to defect inspection using a dark-field defect inspection apparatus SP5 manufactured by KLA-Tencor Corporation to measure the number of defects (defect counts) having a size of 19 nm or more present on the surface of the silicon wafer.

### Measurement of Maximum Resist Film Dissolution Rate (Rmax) (Steps A2, C2, and X2b)

A maximum resist film dissolution rate (Rmax) was measured using the quartz crystal microbalance technique (QCM technique).

More specifically, resist composition R2 was applied onto a QCM electrode and baked at 90° C. for 60 seconds to form a resist film having a thickness of 35 nm. Thus, a resist-film-carrying QCM electrode was produced.

Subsequently, the resist-film-carrying QCM electrode was brought into contact with the first developer or the second developer to remove the resist film. During this period of time, the change in frequency of oscillation of a quartz oscillator was monitored to measure the time (T) required from the start of contact with the developer until the change in frequency of oscillation became constant.

The maximum resist film dissolution rate (Rmax) was calculated from the measured time (T) using the following formula to acquire measurement data.

Formula: R max=(35)/T (nm/s)

For all the twelve production lots, measurement data in the cases of the first developer and the second developer were acquired by the above method. The above-described measurement (the acquisition of various measurement data) was performed using a resist composition one day after the production. The measurement data acquired are shown in Table 16.

TABLE 16
Table 16

| | LWR | | | | | | | | | | | | | | |
|---|---|---|---|---|---|---|---|---|---|---|---|---|---|---|---|
| | performance | | | | | | | | | | | | | | |
| | in the case of | | | | | | | | | | | | | | |
| | first | | | | | | | | | | | | | Second embodiment | |
| | developer | | | First embodiment | | | | | | | | | | Number of | |
| | [nm] | | | Pattern line width | | | | Pattern defect | | | Rmin | | | defects on | |
| | After | After 1 | Developer | [nm] | | | | [number/wafer] | | | [nm/s] | | | substrate | Rmax |
| Lot No. | 1 day | month | used | EUV | KrF | ArF | EB | EUV | KrF | ArF | EUV | KrF | ArF | [number/wafer] | [nm/s] |
| 1 | 2.76 | 2.82 | second | 29.9 | 101.0 | 75.2 | 50.0 | 25 | 51 | 47 | 0.233 | 0.230 | 0.239 | 30 | 81.2 |
| | | | first | 31.2 | 104.9 | 81.1 | 52.2 | 18 | 35 | 32 | 0.152 | 0.156 | 0.156 | 15 | 20.2 |
| 2 | 2.83 | 2.83 | second | 30.1 | 98.3 | 76.2 | 50.1 | 44 | 24 | 39 | 0.230 | 0.227 | 0.239 | 25 | 84.3 |
| | | | first | 30.6 | 103.9 | 80.2 | 52.9 | 37 | 30 | 18 | 0.155 | 0.156 | 0.161 | 10 | 20.5 |
| 3 | 2.74 | 2.77 | second | 29.8 | 102.1 | 74.5 | 51.0 | 13 | 8 | 21 | 0.233 | 0.232 | 0.251 | 20 | 85.7 |
| | | | first | 30.4 | 105.5 | 80.4 | 54.0 | 43 | 32 | 46 | 0.148 | 0.158 | 0.155 | 25 | 21.0 |
| 4 | 2.76 | 2.82 | second | 30.6 | 103.0 | 75.6 | 51.2 | 48 | 31 | 47 | 0.239 | 0.239 | 0.236 | 25 | 80.9 |
| | | | first | 30.9 | 107.5 | 79.1 | 52.6 | 44 | 48 | 15 | 0.155 | 0.151 | 0.162 | 20 | 20.1 |
| 5 | 2.74 | 2.77 | second | 30.6 | 102.3 | 75.2 | 49.8 | 11 | 38 | 8 | 0.228 | 0.228 | 0.235 | 23 | 86.5 |
| | | | first | 31.5 | 103.4 | 79.0 | 50.6 | 6 | 21 | 47 | 0.149 | 0.152 | 0.150 | 20 | 21.2 |
| 6 | 2.84 | 2.81 | second | 30.4 | 98.2 | 72.8 | 50.2 | 49 | 49 | 43 | 0.233 | 0.248 | 0.250 | 19 | 84.4 |
| | | | first | 31.9 | 105.2 | 80.8 | 51.8 | 36 | 15 | 34 | 0.152 | 0.150 | 0.152 | 27 | 20.9 |
| 7 | 2.79 | 2.74 | second | 29.7 | 101.8 | 75.2 | 49.8 | 20 | 32 | 29 | 0.246 | 0.242 | 0.252 | 17 | 84.4 |
| | | | first | 31.2 | 108.5 | 79.6 | 52.2 | 6 | 20 | 37 | 0.149 | 0.151 | 0.151 | 16 | 21.0 |
| 8 | 2.72 | 2.76 | second | 29.3 | 99.1 | 73.0 | 50.2 | 33 | 10 | 28 | 0.235 | 0.247 | 0.238 | 42 | 87.1 |
| | | | first | 30.3 | 107.2 | 78.8 | 52.1 | 14 | 37 | 16 | 0.149 | 0.151 | 0.155 | 18 | 21.5 |
| 9 | 2.79 | 2.81 | second | 30.4 | 101.6 | 73.9 | 49.2 | 22 | 35 | 39 | 0.230 | 0.245 | 0.234 | 9 | 81.5 |
| | | | first | 31.0 | 104.2 | 79.2 | 52.5 | 22 | 36 | 35 | 0.155 | 0.157 | 0.157 | 14 | 20.0 |
| 10 | 2.83 | 2.83 | second | 31.0 | 103.0 | 75.3 | 48.8 | 49 | 25 | 43 | 0.229 | 0.240 | 0.242 | 10 | 81.5 |
| | | | first | 31.0 | 103.8 | 80.7 | 51.8 | 45 | 21 | 50 | 0.152 | 0.149 | 0.161 | 21 | 20.2 |
| 11 | 2.74 | 2.79 | second | 30.0 | 101.4 | 74.9 | 50.2 | 32 | 28 | 11 | 0.241 | 0.239 | 0.241 | 16 | 82.0 |
| | | | first | 30.7 | 106.5 | 80.6 | 51.4 | 22 | 30 | 13 | 0.155 | 0.152 | 0.157 | 48 | 20.3 |
| 12 | 2.84 | 3.40 | second | 28.3 | 95.4 | 70.2 | 46.8 | 101 | 104 | 109 | 0.271 | 0.272 | 0.273 | 102 | 93.1 |
| | | | first | 31.5 | 103.5 | 79.1 | 52.5 | 37 | 25 | 19 | 0.146 | 0.157 | 0.160 | 38 | 20.2 |

### Determination of Resist Composition (Step Y1 or Y2)

As shown in Table 16, for the production lot No. 11, the LWR performance in the case where the first developer was used was hardly changed after one month from the production, whereas for the production lot No. 12, the LWR performance in the case where the first developer was used lowered by 10% or more after one month from the production.

Thus, in Examples and Comparative Examples, the following determinations were made using measurement data acquired from the production lots No. 11 and No. 12 as determination target lots. When only the production lot No. 12 was determined as unacceptable, the determination method was evaluated as valid, and when the production lots No. 11 and No. 12 were determined as acceptable or when the production lots No. 11 and No. 12 were determined as unacceptable, the determination method was evaluated as invalid.

### Example 13 and Comparative Example 13: Determination Using Measurement Data of Pattern Line Width (EUV Exposure)

On the basis of the data shown in Table 16, the resist compositions of the lot No. 11 and the lot No. 12 to be determined were subjected to determinations by determination methods 1-1 to 1-3 using the measurement data of the pattern line width of the resist patterns formed by EUV exposure, and the validity of the determinations was evaluated.

As reference values, the measurement data of the initial lot (lot No. 1) was used in the determination method 1-1, the measurement data of the immediately preceding lot was used in the determination method 1-2, and the average value of the measurement data of the immediately preceding five lots (5-lot average) was used in the determination method 1-3. The allowable range in each determination method was defined as “the difference between the measurement data and the reference value is less than 5% (<±5%) of the reference value”. The results are summarized in Table 17.

TABLE 17

| Table 17 | | | Example 13 | | Comparative Example 13 | |
|---|---|---|---|---|---|---|
| Resist composition | | | R2 | | R2 | |
| Determination target lot | | | 11 | 12 | 11 | 12 |
| LWR performance in the | | After 1 day | 2.74 | 2.84 | 2.74 | 2.84 |
| case of first developer (nm) | | After 1 month | 2.79 | 3.40 | 2.79 | 3.40 |
| Measurement data used | | | pattern line width (EUV exposure) | | | |
| Developer used | | | second developer | | first developer | |
| Determination | Reference | Initial lot | 29.9 | 29.9 | 31.2 | 31.2 |
| method 1-1 | value (nm) | | | | | |
| | Measurement data (nm) | | 30.0 | 28.3 | 30.7 | 31.5 |
| | Difference from reference | | 0.3% | −5.7% | −1.6% | 1.0% |
| | value (%) | | | | | |
| | Allowable range | | <±5% | <±5% | <±5% | <±5% |
| | Determination result | | acceptable | unacceptable | acceptable | acceptable |
| Determination | Reference | Immediately | 31.0 | 30.0 | 31.0 | 30.7 |
| method 1-2 | value (nm) | preceding lot | | | | |
| | Measurement data (nm) | | 30.0 | 28.3 | 30.7 | 31.5 |
| | Difference from reference | | −3.3% | −6.0% | −1.0% | 2.5% |
| | value (%) | | | | | |
| | Allowable range | | <±5% | <±5% | <±5% | <±5% |
| | Determination result | | acceptable | unacceptable | acceptable | acceptable |
| Determination | Reference | 5-lot average | 30.2 | 30.1 | 31.1 | 30.8 |
| method 1-3 | value (nm) | | | | | |

| | | | | |
|---|---|---|---|---|
| Measurement data (nm) | 30.0 | 28.3 | 30.7 | 31.5 |
| Difference from reference | −0.5% | −6.3% | −1.2% | 2.1% |
| value (%) | | | | |
| Allowable range | <±5% | <±5% | <±5% | <±5% |
| Determination result | acceptable | unacceptable | acceptable | acceptable |

| | | |
|---|---|---|
| Validity of determination methods | valid | invalid |

From the results shown in Table 17, it has been found that in Example 13 in which the determinations were performed using the measurement data acquired using the second developer, only the lot No. 12 one month after the production has been determined as unacceptable in each of the determination methods 1-1 to 1-3, and thus the determination methods are valid. On the other hand, it has been found that in Comparative Example 13 in which the determinations were performed using the measurement data acquired using the first developer, the lot No. 12 one month after the production has also been determined as acceptable in each of the determination methods 1-1 to 1-3, and thus the determination methods are invalid.

### Example 14 and Comparative Example 14: Determination Using Measurement Data of Pattern Line Width (KrF Exposure)

On the basis of the data shown in Table 16, the resist compositions of the lot No. 11 and the lot No. 12 to be determined were subjected to determinations by determination methods 2-1 to 2-3 using the measurement data of the pattern line width of the resist patterns formed by KrF exposure, and the validity of the determinations was evaluated.

As reference values, the measurement data of the initial lot (lot No. 1) was used in the determination method 2-1, the measurement data of the immediately preceding lot was used in the determination method 2-2, and the average value of the measurement data of the immediately preceding five lots (5-lot average) was used in the determination method 2-3. The allowable range in each determination method was defined as “the difference between the measurement data and the reference value is less than 5% (<±5%) of the reference value”. The results are summarized in Table 18.

TABLE 18

| Table 18 | | | Example 14 | | Comparative Example 14 | |
|---|---|---|---|---|---|---|
| Resist composition | | | R2 | | R2 | |
| Determination target lot | | | 11 | 12 | 11 | 12 |
| LWR performance in the | | After 1 day | 2.74 | 2.84 | 2.74 | 2.84 |
| case of first developer (nm) | | After 1 month | 2.79 | 3.40 | 2.79 | 3.40 |
| Measurement data used | | | pattern line width (KrF exposure) | | | |
| Developer used | | | second developer | | first developer | |
| Determination | Reference | Initial lot | 101.0 | 101.0 | 104.9 | 104.9 |
| method 2-1 | value (nm) | | | | | |
| | Measurement data (nm) | | 101.4 | 95.4 | 106.5 | 103.5 |
| | Difference from reference | | 0.4% | −5.9% | 1.5% | −1.4% |
| | value (%) | | | | | |
| | Allowable range | | <±5% | <±5% | <±5% | <±5% |
| | Determination result | | acceptable | unacceptable | acceptable | acceptable |
| Determination | Reference | Immediately | 103.0 | 101.4 | 103.8 | 106.5 |
| method 2-2 | value (nm) | preceding lot | | | | |
| | Measurement data (nm) | | 101.4 | 95.4 | 106.5 | 103.5 |
| | Difference from reference | | −1.6% | −6.3% | 2.5% | −2.9% |
| | value (%) | | | | | |
| | Allowable range | | <±5% | <±5% | <±5% | <±5% |
| | Determination result | | acceptable | unacceptable | acceptable | acceptable |
| Determination | Reference | 5-lot average | 100.7 | 101.4 | 105.8 | 106.0 |
| method 2-3 | value (nm) | | | | | |

| | | | | |
|---|---|---|---|---|
| Measurement data (nm) | 101.4 | 95.4 | 106.5 | 103.5 |
| Difference from reference | 0.7% | −6.3% | 0.7% | −2.5% |
| value (%) | | | | |
| Allowable range | <±5% | <±5% | <±5% | <±5% |
| Determination result | acceptable | unacceptable | acceptable | acceptable |

| | | |
|---|---|---|
| Validity of determination methods | valid | invalid |

From the results shown in Table 18, it has been found that in Example 14 in which the determinations were performed using the measurement data acquired using the second developer, only the lot No. 12 one month after the production has been determined as unacceptable in each of the determination methods 2-1 to 2-3, and thus the determination methods are valid. On the other hand, it has been found that in Comparative Example 14 in which the determinations were performed using the measurement data acquired using the first developer, the lot No. 12 one month after the production has also been determined as acceptable in each of the determination methods 2-1 to 2-3, and thus the determination methods are invalid.

### Example 15 and Comparative Example 15: Determination Using Measurement Data of Pattern Line Width (ArF Exposure)

On the basis of the data shown in Table 16, the resist compositions of the lot No. 11 and the lot No. 12 to be determined were subjected to determinations by determination methods 3-1 to 3-3 using the measurement data of the pattern line width of the resist patterns formed by ArF exposure, and the validity of the determinations was evaluated.

As reference values, the measurement data of the initial lot (lot No. 1) was used in the determination method 3-1, the measurement data of the immediately preceding lot was used in the determination method 3-2, and the average value of the measurement data of the immediately preceding five lots (5-lot average) was used in the determination method 3-3. The allowable range in each determination method was defined as “the difference between the measurement data and the reference value is less than 5% (<±5%) of the reference value”. The results are summarized in Table 19.

TABLE 19

| Table 19 | | | Example 15 | | Comparative Example 15 | |
|---|---|---|---|---|---|---|
| Resist composition | | | R2 | | R2 | |
| Determination target lot | | | 11 | 12 | 11 | 12 |
| LWR performance in the | | After 1 day | 2.74 | 2.84 | 2.74 | 2.84 |
| case of first developer (nm) | | After 1 month | 2.79 | 3.40 | 2.79 | 3.40 |
| Measurement data used | | | pattern line width (ArF exposure) | | | |
| Developer used | | | second developer | | first developer | |
| Determination | Reference | Initial lot | 75.2 | 75.2 | 81.1 | 81.1 |
| method 3-1 | value (nm) | | | | | |
| | Measurement data (nm) | | 74.9 | 70.2 | 80.6 | 79.1 |
| | Difference from reference | | −0.4% | −7.1% | −0.6% | −2.5% |
| | value (%) | | | | | |
| | Allowable range | | <±5% | <±5% | <±5% | <±5% |
| | Determination result | | acceptable | unacceptable | acceptable | acceptable |
| Determination | Reference | Immediately | 75.3 | 74.9 | 80.7 | 80.6 |
| method 3-2 | value (nm) | preceding lot | | | | |
| | Measurement data (nm) | | 74.9 | 70.2 | 80.6 | 79.1 |
| | Difference from reference | | −0.5% | −6.7% | −0.1% | −1.9% |
| | value (%) | | | | | |
| | Allowable range | | <±5% | <±5% | <±5% | <±5% |
| | Determination result | | acceptable | unacceptable | acceptable | acceptable |
| Determination | Reference | 5-lot average | 74.0 | 74.5 | 79.8 | 79.8 |
| method 3-3 | value (nm) | | | | | |

| | | | | |
|---|---|---|---|---|
| Measurement data (nm) | 74.9 | 70.2 | 80.6 | 79.1 |
| Difference from reference | 1.1% | −6.1% | 1.0% | −0.9% |
| value (%) | | | | |
| Allowable range | <±5% | <±5% | <±5% | <±5% |
| Determination result | acceptable | unacceptable | acceptable | acceptable |

| | | |
|---|---|---|
| Validity of determination methods | valid | invalid |

From the results shown in Table 19, it has been found that in Example 15 in which the determinations were performed using the measurement data acquired using the second developer, only the lot No. 12 one month after the production has been determined as unacceptable in each of the determination methods 3-1 to 3-3, and thus the determination methods are valid. On the other hand, it has been found that in Comparative Example 15 in which the determinations were performed using the measurement data acquired using the first developer, the lot No. 12 one month after the production has also been determined as acceptable in each of the determination methods 3-1 to 3-3, and thus the determination methods are invalid.

### Example 16 and Comparative Example 16: Determination Using Measurement Data of Pattern Line Width (EB Exposure)

On the basis of the data shown in Table 16, the resist compositions of the lot No. 11 and the lot No. 12 to be determined were subjected to determinations by determination methods 4-1 to 4-3 using the measurement data of the pattern line width of the resist patterns formed by EB exposure, and the validity of the determinations was evaluated.

As reference values, the measurement data of the initial lot (lot No. 1) was used in the determination method 4-1, the measurement data of the immediately preceding lot was used in the determination method 4-2, and the average value of the measurement data of the immediately preceding five lots (5-lot average) was used in the determination method 4-3. The allowable range in each determination method was defined as “the difference between the measurement data and the reference value is less than 5% (<±5%) of the reference value”. The results are summarized in Table 20.

TABLE 20

| Table 20 | | | Example 16 | | Comparative Example 16 | |
|---|---|---|---|---|---|---|
| Resist composition | | | R2 | | R2 | |
| Determination target lot | | | 11 | 12 | 11 | 12 |
| LWR performance in the | | After 1 day | 2.74 | 2.84 | 2.74 | 2.84 |
| case of first developer (nm) | | After 1 month | 2.79 | 3.40 | 2.79 | 3.40 |
| Measurement data used | | | pattern line width (EB exposure) | | | |
| Developer used | | | second developer | | first developer | |
| Determination | Reference | Initial lot | 50.0 | 50.0 | 52.2 | |
| method 4−1 | value (nm) | | | | | |
| | Measurement data (nm) | | 50.2 | 46.8 | 51.4 | 52.5 |
| | Difference from reference | | 0.4% | −6.8% | −1.6% | 0.6% |
| | value (%) | | | | | |
| | Allowable range | | <±5% | <±5% | <±5% | <±5% |
| | Determination result | | acceptable | unacceptable | acceptable | acceptable |
| Determination | Reference | Immediately | 48.8 | 50.2 | 51.8 | 51.4 |
| method 4−2 | value (nm) | preceding lot | | | | |
| | Measurement data (nm) | | 50.2 | 46.8 | 51.4 | 52.5 |
| | Difference from reference | | 2.8% | −7.3% | −0.8% | 2.1% |
| | value (%) | | | | | |
| | Allowable range | | <±5% | <±5% | <±5% | <±5% |
| | Determination result | | acceptable | unacceptable | acceptable | acceptable |
| Determination | Reference | 5-lot average | 49.6 | 49.6 | 52.1 | 52.0 |
| method 4−3 | value (nm) | | | | | |

| | | | | |
|---|---|---|---|---|
| Measurement data (nm) | 50.2 | 46.8 | 51.4 | 52.5 |
| Difference from reference | 1.1% | −6.1% | −1.3% | 1.0% |
| value (%) | | | | |
| Allowable range | <±5% | <±5% | <±5% | <±5% |
| Determination result | acceptable | unacceptable | acceptable | acceptable |

| | | |
|---|---|---|
| Validity of determination methods | valid | invalid |

From the results shown in Table 20, it has been found that in Example 16 in which the determinations were performed using the measurement data acquired using the second developer, only the lot No. 12 one month after the production has been determined as unacceptable in each of the determination methods 4-1 to 4-3, and thus the determination methods are valid. On the other hand, it has been found that in Comparative Example 16 in which the determinations were performed using the measurement data acquired using the first developer, the lot No. 12 one month after the production has also been determined as acceptable in each of the determination methods 4-1 to 4-3, and thus the determination methods are invalid.

### Example 17 and Comparative Example 17: Determination Using Measurement Data of Pattern Defect (EUV Exposure)

On the basis of the data shown in Table 16, the resist compositions of the lot No. 11 and the lot No. 12 to be determined were subjected to a determination (determination method 5) using the measurement data of the pattern defect of the resist patterns formed by EUV exposure, and the validity of the determination was evaluated.

In the determination method 5, the allowable range was defined as “the number of defects per silicon wafer is less than 100 (<100)”. The results are summarized in Table 21.

TABLE 21
Table 21

| | | Example 17 | | Comparative Example 17 | |
|---|---|---|---|---|---|
| Resist composition | | R2 | | R2 | |
| Determination target lot | | 11 | 12 | 11 | 12 |
| LWR performance in the | After 1 day | 2.74 | 2.84 | 2.74 | 2.84 |
| case of first developer (nm) | After 1 month | 2.79 | 3.40 | 2.79 | 3.40 |
| Measurement data used | | pattern defect (EUV exposure) | | | |
| Developer used | | second developer | | first developer | |
| Determination | Measurement data | 32 | 101 | 22 | 37 |
| method 5 | (number/wafer) | | | | |
| | Allowable range | <100 | <100 | <100 | <100 |
| | (number/wafer) | | | | |
| | Determination result | acceptable | unacceptable | acceptable | acceptable |

| | | |
|---|---|---|
| Validity of determination method | valid | invalid |

From the results shown in Table 21, it has been found that in Example 17 in which the determination was performed using the measurement data acquired using the second developer, only the lot No. 12 one month after the production has been determined as unacceptable, and thus the determination method of Example 17 is valid. On the other hand, it has been found that in Comparative Example 17 in which the determination was performed using the measurement data acquired using the first developer, the lot No. 12 one month after the production has also been determined as acceptable, and thus the determination method of Comparative Example 17 is invalid.

### Example 18 and Comparative Example 18: Determination Using Measurement Data of Pattern Defect (ArF Exposure)

On the basis of the data shown in Table 16, the resist compositions of the lot No. 11 and the lot No. 12 to be determined were subjected to a determination (determination method 6) using the measurement data of the pattern defect of the resist patterns formed by ArF exposure, and the validity of the determination was evaluated.

In the determination method 6, the allowable range was defined as “the number of defects per silicon wafer is less than 100 (<100)”. The results are summarized in Table 22.

TABLE 22
Table 22

| | | Example 18 | | Comparative Example 18 | |
|---|---|---|---|---|---|
| Resist composition | | R2 | | R2 | |
| Determination target lot | | 11 | 12 | 11 | 12 |
| LWR performance in the | After 1 day | 2.74 | 2.84 | 2.74 | 2.84 |
| case of first developer (nm) | After 1 month | 2.79 | 3.40 | 2.79 | 3.40 |
| Measurement data used | | pattern defect (KrF exposure) | | | |
| Developer used | | second developer | | first developer | |
| Determination | Measurement data | 28 | 104 | 30 | 25 |
| method 6 | (number/wafer) | | | | |
| | Allowable range | <100 | <100 | <100 | <100 |
| | (number/wafer) | | | | |
| | Determination result | acceptable | unacceptable | acceptable | acceptable |

| | | |
|---|---|---|
| Validity of determination method | valid | invalid |

From the results shown in Table 22, it has been found that in Example 18 in which the determination was performed using the measurement data acquired using the second developer, only the lot No. 12 one month after the production has been determined as unacceptable, and thus the determination method of Example 18 is valid. On the other hand, it has been found that in Comparative Example 18 in which the determination was performed using the measurement data acquired using the first developer, the lot No. 12 one month after the production has also been determined as acceptable, and thus the determination method of Comparative Example 18 is invalid.

### Example 19 and Comparative Example 19: Determination Using Measurement Data of Pattern Defect (KrF Exposure)

On the basis of the data shown in Table 16, the resist compositions of the lot No. 11 and the lot No. 12 to be determined were subjected to a determination (determination method 7) using the measurement data of the pattern defect of the resist patterns formed by KrF exposure, and the validity of the determination was evaluated.

In the determination method 7, the allowable range was defined as “the number of defects per silicon wafer is less than 100 (<100)”. The results are summarized in Table 23.

TABLE 23
Table 23

| | | Example 19 | | Comparative Example 19 | |
|---|---|---|---|---|---|
| Resist composition | | R2 | | R2 | |
| Determination target lot | | 11 | 12 | 11 | 12 |
| LWR performance in the | After 1 day | 2.74 | 2.84 | 2.74 | 2.84 |
| case of first developer (nm) | After 1 month | 2.79 | 3.40 | 2.79 | 3.40 |
| Measurement data used | | pattern defect (ArF exposure) | | | |
| Developer used | | second developer | | first developer | |
| Determination | Measurement data | 11 | 109 | 13 | 19 |
| method 7 | (number/wafer) | | | | |
| | Allowable range | <100 | <100 | <100 | <100 |
| | (number/wafer) | | | | |
| | Determination result | acceptable | unacceptable | acceptable | acceptable |

| | | |
|---|---|---|
| Validity of determination method | valid | invalid |

From the results shown in Table 23, it has been found that in Example 19 in which the determination was performed using the measurement data acquired using the second developer, only the lot No. 12 one month after the production has been determined as unacceptable, and thus the determination method of Example 19 is valid. On the other hand, it has been found that in Comparative Example 19 in which the determination was performed using the measurement data acquired using the first developer, the lot No. 12 one month after the production has also been determined as acceptable, and thus the determination method of Comparative Example 19 is invalid.

### Example 20 and Comparative Example 20: Determination Using Measurement Data of Rmin (EUV Exposure)

On the basis of the data shown in Table 16, the resist compositions of the lot No. 11 and the lot No. 12 to be determined were subjected to determinations by determination methods 8-1 to 8-3 using the measurement data of the minimum dissolution rate (Rmin) of the resist films formed by EUV exposure, and the validity of the determinations was evaluated.

As reference values, the measurement data of the initial lot (lot No. 1) was used in the determination method 8-1, the measurement data of the immediately preceding lot was used in the determination method 8-2, and the average value of the measurement data of the immediately preceding five lots (5-lot average) was used in the determination method 8-3. The allowable range in each determination method was defined as “the difference between the measurement data and the reference value is less than ±10% (<±10%) of the reference value”. The results are summarized in Table 24.

TABLE 24

| Table 24 | | | Example 20 | | Comparative Example 20 | |
|---|---|---|---|---|---|---|
| Resist composition | | | R2 | | R2 | |
| Determination target lot | | | 11 | 12 | 11 | 12 |
| LWR performance in the | | After 1 day | 2.74 | 2.84 | 2.74 | 2.84 |
| case of first developer (nm) | | After 1 month | 2.79 | 3.40 | 2.79 | 3.40 |
| Measurement data used | | | minimum resist film dissolution rate (EUV | | | |
| Developer used | | | second developer | | first developer | |
| Determination | Reference | Initial lot | 0.233 | 0.233 | 0.152 | 0.152 |
| method 8-1 | value (nm/s) | | | | | |
| | Measurement data (nm/s) | | 0.241 | 0.271 | 0.155 | 0.146 |
| | Difference from reference | | 3.3% | 14.0% | 1.9% | −4.1% |
| | value (%) | | | | | |
| | Allowable range | | <±10% | <±10% | <±10% | <±10% |
| | Determination result | | acceptable | unacceptable | acceptable | acceptable |
| Determination | Reference | Immediately | 0.229 | 0.241 | 0.152 | 0.155 |
| method 8-2 | value (nm/s) | preceding lot | | | | |
| | Measurement data (nm/s) | | 0.241 | 0.271 | 0.155 | 0.146 |
| | Difference from reference | | 5.0% | 11.1% | 1.9% | −6.2% |
| | value (%) | | | | | |
| | Allowable range | | <±10% | <±10% | <±10% | <±10% |
| | Determination result | | acceptable | unacceptable | acceptable | acceptable |
| Determination | Reference | 5-lot average | 0.235 | 0.236 | 0.151 | 0.152 |
| method 8-3 | value (nm/s) | | | | | |

| | | | | |
|---|---|---|---|---|
| Measurement data (nm/s) | 0.241 | 0.271 | 0.155 | 0.146 |
| Difference from reference | 2.5% | 12.9% | 2.6% | −4.1% |
| value (%) | | | | |
| Allowable range | <±10% | <±10% | <±10% | <±10% |
| Determination result | acceptable | unacceptable | acceptable | acceptable |

| | | |
|---|---|---|
| Validity of determination methods | valid | invalid |

From the results shown in Table 24, it has been found that in Example 20 in which the determinations were performed using the measurement data acquired using the second developer, only the lot No. 12 one month after the production has been determined as unacceptable in each of the determination methods 8-1 to 8-3, and thus the determination methods are valid. On the other hand, it has been found that in Comparative Example 20 in which the determinations were performed using the measurement data acquired using the first developer, the lot No. 12 one month after the production has also been determined as acceptable in each of the determination methods 8-1 to 8-3, and thus the determination methods are invalid.

### Example 21 and Comparative Example 21: Determination Using Measurement Data of Rmin (KrF Exposure)

On the basis of the data shown in Table 16, the resist compositions of the lot No. 11 and the lot No. 12 to be determined were subjected to determinations by determination methods 9-1 to 9-3 using the measurement data of the minimum dissolution rate (Rmin) of the resist films formed by KrF exposure, and the validity of the determinations was evaluated.

As reference values, the measurement data of the initial lot (lot No. 1) was used in the determination method 9-1, the measurement data of the immediately preceding lot was used in the determination method 9-2, and the average value of the measurement data of the immediately preceding five lots (5-lot average) was used in the determination method 9-3. The allowable range in each determination method was defined as “the difference between the measurement data and the reference value is less than ±10% (<±10%) of the reference value”. The results are summarized in Table 25.

TABLE 25

| Table 25 | | | Example 21 | | Comparative Example 21 | |
|---|---|---|---|---|---|---|
| Resist composition | | | R2 | | R2 | |
| Determination target lot | | | 11 | 12 | 11 | 12 |
| LWR performance in the | | After 1 day | 2.74 | 2.84 | 2.74 | 2.84 |
| case of first developer (nm) | | After 1 month | 2.79 | 3.40 | 2.79 | 3.40 |
| Measurement data used | | | minimum resist film dissolution rate (KrF exposure) | | | |
| Developer used | | | second developer | | first developer | |
| Determination | Reference | Initial lot | 0.230 | 0.230 | 0.156 | 0.156 |
| method 9-1 | value (nm/s) | | | | | |
| | Measurement data (nm/s) | | 0.239 | 0.272 | 0.152 | 0.157 |
| | Difference from reference | | 3.8% | 15.4% | −2.6% | 0.6% |
| | value (%) | | | | | |
| | Allowable range | | <±10% | <±10% | <±10% | <±10% |
| | Determination result | | acceptable | unacceptable | acceptable | acceptable |
| Determination | Reference | Immediately | 0.240 | 0.239 | 0.149 | 0.152 |
| method 9-2 | value (nm/s) | preceding lot | | | | |
| | Measurement data (nm/s) | | 0.239 | 0.272 | 0.152 | 0.157 |
| | Difference from reference | | −0.4% | 12.1% | 2.0% | 3.2% |
| | value (%) | | | | | |
| | Allowable range | | <±10% | <±10% | <±10% | <±10% |
| | Determination result | | acceptable | unacceptable | acceptable | acceptable |
| Determination | Reference | 5-lot average | 0.245 | 0.243 | 0.158 | 0.152 |
| method 9-3 | value (nm/s) | | | | | |

| | | | | |
|---|---|---|---|---|
| Measurement data (nm/s) | 0.239 | 0.272 | 0.152 | 0.157 |
| Difference from reference | −2.5% | 10.7% | −4.1% | 3.2% |
| value (%) | | | | |
| Allowable range | <±10% | <±10% | <±10% | <±10% |
| Determination result | acceptable | unacceptable | acceptable | acceptable |

| | | |
|---|---|---|
| Validity of determination methods | valid | invalid |

From the results shown in Table 25, it has been found that in Example 21 in which the determinations were performed using the measurement data acquired using the second developer, only the lot No. 12 one month after the production has been determined as unacceptable in each of the determination methods 9-1 to 9-3, and thus the determination methods are valid. On the other hand, it has been found that in Comparative Example 21 in which the determinations were performed using the measurement data acquired using the first developer, the lot No. 12 one month after the production has also been determined as acceptable in each of the determination methods 9-1 to 9-3, and thus the determination methods are invalid.

### Example 22 and Comparative Example 22: Determination Using Measurement Data of Rmin (ArF Exposure)

On the basis of the data shown in Table 16, the resist compositions of the lot No. 11 and the lot No. 12 to be determined were subjected to determinations by determination methods 10-1 to 10-3 using the measurement data of the minimum dissolution rate (Rmin) of the resist films formed by ArF exposure, and the validity of the determinations was evaluated.

As reference values, the measurement data of the initial lot (lot No. 1) was used in the determination method 10-1, the measurement data of the immediately preceding lot was used in the determination method 10-2, and the average value of the measurement data of the immediately preceding five lots (5-lot average) was used in the determination method 10-3. The allowable range in each determination method was defined as “the difference between the measurement data and the reference value is less than ±10% (<±10%) of the reference value”. The results are summarized in Table 26.

TABLE 26

| Table 26 | | | Example 22 | | Comparative Example 22 | |
|---|---|---|---|---|---|---|
| Resist composition | | | R2 | | R2 | |
| Determination target lot | | | 11 | 12 | 11 | 12 |
| LWR performance in the | After 1 day | | 2.74 | 2.84 | 2.74 | 2.84 |
| case of first developer (nm) | After 1 month | | 2.79 | 3.40 | 2.79 | 3.40 |
| Measurement data used | | | minimum resist film dissolution rate (ArF exposure) | | | |
| Developer used | | | second developer | | first developer | |
| Determination | Reference | Initial lot | 0.239 | 0.239 | 0.156 | 0.156 |
| method 10-1 | value (nm/s) | | | | | |
| | Measurement data (nm/s) | | 0.241 | 0.273 | 0.157 | 0.160 |
| | Difference from reference | | 0.8% | 12.5% | 0.6% | 2.5% |
| | value (%) | | | | | |
| | Allowable range | | <±10% | <±10% | <±10% | <±10% |
| | Determination result | | acceptable | unacceptable | acceptable | acceptable |
| Determination | Reference | Immediately | 0.242 | 0.241 | 0.161 | 0.157 |
| method 10-2 | value (nm/s) | preceding lot | | | | |
| | Measurement data (nm/s) | | 0.241 | 0.273 | 0.157 | 0.160 |
| | Difference from reference | | −0.4% | 11.7% | −2.5% | 1.9% |
| | value (%) | | | | | |
| | Allowable range | | <±10% | <±10% | <±10% | <±10% |
| | Determination result | | acceptable | unacceptable | acceptable | acceptable |
| Determination | Reference | 5-lot average | 0.243 | 0.241 | 0.155 | 0.156 |
| method 10-3 | value (nm/s) | | | | | |

| | | | | |
|---|---|---|---|---|
| Measurement data (nm/s) | 0.241 | 0.273 | 0.157 | 0.160 |
| Difference from reference | −0.8% | 11.7% | 1.3% | 2.5% |
| value (%) | | | | |
| Allowable range | <±10% | <±10% | <±10% | <±10% |
| Determination result | acceptable | unacceptable | acceptable | acceptable |

| | | |
|---|---|---|
| Validity of determination methods | valid | invalid |

From the results shown in Table 26, it has been found that in Example 22 in which the determinations were performed using the measurement data acquired using the second developer, only the lot No. 12 one month after the production has been determined as unacceptable in each of the determination methods 10-1 to 10-3, and thus the determination methods are valid. On the other hand, it has been found that in Comparative Example 22 in which the determinations were performed using the measurement data acquired using the first developer, the lot No. 12 one month after the production has also been determined as acceptable in each of the determination methods 10-1 to 10-3, and thus the determination methods are invalid.

### Example 23 and Comparative Example 23: Determination Using Measurement Data of Defect after Resist Film Removal

On the basis of the data shown in Table 16, the resist compositions of the lot No. 11 and the lot No. 12 to be determined were subjected to a determination (determination method 11) using the measurement data of the number of defects on the surface of a silicon wafer after resist film removal, and the validity of the determination was evaluated.

In the determination method 11, the allowable range was defined as “the number of defects per silicon wafer is less than 100 (<100)”. The results are summarized in Table 27.

TABLE 27
Table 27

| | | Example 23 | | Comparative Example 23 | |
|---|---|---|---|---|---|
| Resist composition | | R2 | | R2 | |
| Determination target lot | | 11 | 12 | 11 | 12 |
| LWR performance in the | After 1 day | 2.74 | 2.84 | 2.74 | 2.84 |
| case of first developer (nm) | After 1 month | 2.79 | 3.40 | 2.79 | 3.40 |
| Measurement data used | | defect after resist film removal | | | |
| Developer used | | second developer | | first developer | |
| Determination | Measurement data | 16 | 102 | 48 | 38 |
| method 11 | (number/wafer) | | | | |
| | Allowable range | <100 | <100 | <100 | <100 |
| | (number/wafer) | | | | |
| | Determination result | acceptable | unacceptable | acceptable | acceptable |

| | | |
|---|---|---|
| Validity of determination method | valid | invalid |

From the results shown in Table 27, it has been found that in Example 23 in which the determination was performed using the measurement data acquired using the second developer, only the lot No. 12 one month after the production has been determined as unacceptable, and thus the determination method of Example 23 is valid. On the other hand, it has been found that in Comparative Example 23 in which the determination was performed using the measurement data acquired using the first developer, the lot No. 12 one month after the production has also been determined as acceptable, and thus the determination method of Comparative Example 23 is invalid.

### Example 24 and Comparative Example 24: Determination Using Measurement Data of Rmax

On the basis of the data shown in Table 16, the resist compositions of the lot No. 11 and the lot No. 12 to be determined were subjected to determinations by determination methods 12-1 to 12-3 using the measurement data of the maximum dissolution rate (Rmax) of the resist films formed, and the validity of the determinations was evaluated.

As reference values, the measurement data of the initial lot (lot No. 1) was used in the determination method 12-1, the measurement data of the immediately preceding lot was used in the determination method 12-2, and the average value of the measurement data of the immediately preceding five lots (5-lot average) was used in the determination method 12-3. The allowable range in each determination method was defined as “the difference between the measurement data and the reference value is less than ±100 (<±10%) of the reference value”. The results are summarized in Table 28.

TABLE 28

| Table 28 | | | Example 24 | | Comparative Example 24 | |
|---|---|---|---|---|---|---|
| Resist composition | | | R2 | | R2 | |
| Determination target lot | | | 11 | 12 | 11 | 12 |
| LWR performance in the case of | | After 1 day | 2.74 | 2.84 | 2.74 | 2.84 |
| first developer (nm) | | After 1 month | 2.79 | 3.40 | 2.79 | 3.40 |
| Measurement data used | | | maximum resist film dissolution rate | | | |
| Developer used | | | second developer | | first developer | |
| Determination | Reference value | Initial lot | 81.2 | 81.2 | 20.2 | 20.2 |
| method 12-1 | (nm/s) | | | | | |
| | Measurement data (nm/s) | | 82.0 | 93.1 | 20.3 | 20.2 |
| | Difference from reference value (%) | | 1.0% | 12.8% | 0.5% | 0.0% |
| | Allowable range | | <±10% | <±10% | <±10% | <±10% |
| | Determination result | | acceptable | unacceptable | acceptable | acceptable |
| Determination | Reference value | Immediately | 81.5 | 82.0 | 20.2 | 20.3 |
| method 12-2 | (nm/s) | preceding lot | | | | |
| | Measurement data (nm/s) | | 82.0 | 93.1 | 20.3 | 20.2 |
| | Difference from reference value (%) | | 0.6% | 11.9% | 0.5% | −0.5% |
| | Allowable range | | <±10% | <±10% | <±10% | <±10% |
| | Determination result | | acceptable | unacceptable | acceptable | acceptable |
| Determination | Reference value | 5-lot average | 83.8 | 83.3 | 20.7 | 20.6 |
| method 12-3 | (nm/s) | | | | | |

| | | | | |
|---|---|---|---|---|
| Measurement data (nm/s) | 82.0 | 93.1 | 20.3 | 20.2 |
| Difference from reference value (%) | −2.2% | 10.5% | −2.0% | −2.0% |
| Allowable range | <±10% | <±10% | <±10% | <±10% |
| Determination result | acceptable | unacceptable | acceptable | acceptable |

| | | |
|---|---|---|
| Validity of determination methods | valid | invalid |

From the results shown in Table 28, it has been found that in Example 24 in which the determinations were performed using the measurement data acquired using the second developer, only the lot No. 12 one month after the production has been determined as unacceptable in each of the determination methods 12-1 to 12-3, and thus the determination methods are valid. On the other hand, it has been found that in Comparative Example 24 in which the determinations were performed using the measurement data acquired using the first developer, the lot No. 12 one month after the production has also been determined as acceptable in each of the determination methods 12-1 to 12-3, and thus the determination methods are invalid.

The results of Examples and Comparative Examples described above have confirmed that the inspection method according to the present invention produces the effect of the present invention, that is, the LWR performance of a resist composition that has been stored for a predetermined period of time can be easily determined.

What is claimed is:

1. A method for inspecting a resist composition with which a resist pattern can be formed by performing an exposure treatment and a development treatment using a first developer, the method comprising:
a step A1 of forming a resist film on a substrate using the resist composition;
a step B1 of exposing the resist film formed in the step A1;
a step C1 of bringing a second developer different from the first developer into contact with the resist film exposed in the step B1;
a step X1 of acquiring at least one measurement data selected from the group consisting of a line width of a resist pattern formed in the step C1, a number of defects of the resist pattern formed in the step C1, and a rate at which the exposed resist film is dissolved by the second developer, the rate being measured in the step C1; and
a step Y1 of determining whether the measurement data acquired in the step X1 falls within a preset allowable range,
wherein the rate at which the resist film formed using the resist composition is dissolved by the second developer is higher than a rate at which the resist film formed using the resist composition is dissolved by the first developer.

2. The method for inspecting a resist composition according to claim 1, wherein the first developer includes butyl acetate and a hydrocarbon solvent.

3. The method for inspecting a resist composition according to claim 2, wherein the hydrocarbon solvent is undecane.

4. The method for inspecting a resist composition according to claim 1, wherein the second developer includes substantially only butyl acetate.

5. The method for inspecting a resist composition according to claim 1, wherein in the step B1, the resist film is exposed using at least one selected from the group consisting of EUV exposure, KrF exposure, ArF exposure, and EB exposure.

6. The method for inspecting a resist composition according to claim 1, wherein a ratio of the rate at which the resist film formed using the resist composition is dissolved by the second developer to the rate at which the resist film formed using the resist composition is dissolved by the first developer is more than 1.0 and 100 or less.

7. A method for inspecting a resist composition with which a resist pattern can be formed by performing an exposure treatment and a development treatment using a first developer, the method comprising:
a step A2 of forming a resist film on a substrate using the resist composition;
a step C2 of bringing a second developer different from the first developer into contact with the resist film formed in the step A2;
a step X2 of acquiring at least one measurement data selected from the group consisting of a number of defects on a surface of the substrate from which the resist film has been removed as a result of the step C2 and a rate at which the resist film is dissolved by the second developer, the rate being measured in the step C2; and
a step Y2 of determining whether the measurement data acquired in the step X2 falls within a preset allowable range,
wherein the rate at which the resist film formed using the resist composition is dissolved by the second developer is higher than a rate at which the resist film formed using the resist composition is dissolved by the first developer.

8. The method for inspecting a resist composition according to claim 7, wherein the first developer includes butyl acetate and a hydrocarbon solvent.

9. The method for inspecting a resist composition according to claim 8, wherein the hydrocarbon solvent is undecane.

10. The method for inspecting a resist composition according to claim 7, wherein the second developer includes substantially only butyl acetate.

11. The method for inspecting a resist composition according to claim 7, wherein a ratio of the rate at which the resist film formed using the resist composition is dissolved by the second developer to the rate at which the resist film formed using the resist composition is dissolved by the first developer is more than 1.0 and 100 or less.

12. The method for inspecting a resist composition according to claim 1, wherein the resist composition is a resist composition with which a resist pattern can be formed through an exposure treatment including EUV exposure and a development treatment using the first developer.

13. The method for inspecting a resist composition according to claim 1, wherein the resist composition includes a resin having a repeating unit having an aromatic hydrocarbon group.

14. A method for producing a resist composition, the method comprising:
a composition preparation step of preparing a resist composition; and
an inspection step of inspecting the resist composition prepared in the composition preparation step in accordance with the method according to claim 1.

15. A resist composition produced by a production method having an inspection step of performing inspection by the method according to claim 1.

16. The method for inspecting a resist composition according to claim 2, wherein the second developer includes substantially only butyl acetate.

17. The method for inspecting a resist composition according to claim 2, wherein in the step B1, the resist film is exposed using at least one selected from the group consisting of EUV exposure, KrF exposure, ArF exposure, and EB exposure.

18. The method for inspecting a resist composition according to claim 2, wherein a ratio of the rate at which the resist film formed using the resist composition is dissolved by the second developer to the rate at which the resist film formed using the resist composition is dissolved by the first developer is more than 1.0 and 100 or less.

19. The method for inspecting a resist composition according to claim 8, wherein the second developer includes substantially only butyl acetate.

20. The method for inspecting a resist composition according to claim 8, wherein a ratio of the rate at which the resist film formed using the resist composition is dissolved by the second developer to the rate at which the resist film formed using the resist composition is dissolved by the first developer is more than 1.0 and 100 or less.
